(19) United States
(12) Patent Application Publication
(10) Pub. No.: US 2021/0184035 A1
(43) Pub. Date: Jun. 17, 2021

(54) SEMICONDUCTOR DEVICE AND MANUFACTURING METHOD THEREOF

(71) Applicant: SOCIONEXT INC., Kanagawa (JP)

(72) Inventors: Hidetoshi TANAKA, Yokohama-shi (JP); Isaya SOBUE, Yokohama-shi (JP)

(21) Appl. No.: 17/187,179

(22) Filed: Feb. 26, 2021

Related U.S. Application Data
(63) Continuation of application No. PCT/JP2018/032469, filed on Aug. 31, 2018.

(51) Int. Cl. H01L 29/78; H01L 29/06; H01L 29/40; H01L 27/088; H01L 23/522; H01L 29/66

(52) U.S. Cl. CPC H01L 29/7827; H01L 29/0676; H01L 29/66666; H01L 27/088; H01L 23/5223; H01L 29/405

(57) ABSTRACT

A semiconductor device includes a semiconductor substrate and a resistance element provided above the semiconductor substrate, the resistance element includes a conductive pattern using a gate electrode film formed simultaneously with a gate electrode film arranged on a side surface of a semiconductor nanowire of a VNW transistor, and there is fabricated the semiconductor device that includes the VNW transistor having the semiconductor nanowire and the resistance element having sufficient electrical resistance.

### CROSS-REFERENCE TO RELATED APPLICATION

This application is a continuation application of International Application PCT/JP2018/032469 filed on Aug. 31, 2018 and designated the U.S., the entire contents of which are incorporated herein by reference.

### FIELD

The embodiments discussed herein are directed to a semiconductor device and a manufacturing method thereof.

### BACKGROUND

Recently, in order to deal with an increasing demand for microfabrication and downsizing of a semiconductor device, a VNW element using a projecting nanowire (Vertical Nano Wire: VNW) having a semiconductor material, which is provided in a standing manner in a vertical direction on a semiconductor substrate, has been devised. Examples of the VNW element include a VNW diode, a VNW transistor, a VNW resistance element, and so on.

Patent Document 1: Description of U.S. Pat. No. 9,177,924

Patent Document 2: Description of U.S. Pat. No. 9,559,095

Patent Document 3: Description of U.S. Pat. No. 9,646,973

As the VNW element, a resistance element has been proposed in addition to a diode and a transistor.

However, at present, the idea is limited to applying the technique of VNW elements to resistance elements, and the concrete structure, arrangement, and so on of the resistance elements have not yet been examined.

### SUMMARY

One aspect of the semiconductor device includes: a semiconductor substrate; a first projection that has a semiconductor material and is provided to project from the semiconductor substrate; a first insulating film that is provided on a side surface of the first projection; a first conductive pattern that is provided on the first insulating film; and a resistance element that is provided above the semiconductor substrate and comprises a second conductive pattern having the same material as that of the first conductive pattern.

One aspect of the manufacturing method of the semiconductor device includes: forming, on a semiconductor substrate, a first projection that has a semiconductor material and projects from the semiconductor substrate; forming, on a side surface of the first projection and the semiconductor substrate, an insulating film and a conductor film on the insulating film; and patterning the insulating film and the conductor film to form a gate insulating film and a gate electrode on the side surface of the first projection, and forming a conductive pattern of a resistance element above the semiconductor substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating a schematic configuration of a semiconductor device according to a first embodiment;

FIG. 2A is a schematic cross-sectional view illustrating a forming method of a gate electrode in order of processes;

FIG. 2B, which continues from FIG. 2A, is a schematic cross-sectional view illustrating the forming method of the gate electrode in order of processes;

FIG. 2C, which continues from FIG. 2B, is a schematic cross-sectional view illustrating the forming method of the gate electrode in order of processes;

FIG. 2D, which continues from FIG. 2C, is a schematic cross-sectional view illustrating the forming method of the gate electrode in order of processes;

FIG. 3A is a plan view illustrating a schematic configuration of a semiconductor device according to a second embodiment;

FIG. 3B is a plan view illustrating a schematic configuration of FIG. 3A excluding a configuration above VNW structures;

FIG. 3C is a plan view illustrating a schematic configuration of local wirings and wirings thereon in a partial region in FIG. 3A;

FIG. 4A is a cross-sectional view illustrating a cross section taken along I-I in FIG. 3A;

FIG. 4B is a simple cross-sectional view corresponding to FIG. 4A;

FIG. 5A is a plan view illustrating a schematic configuration of a semiconductor device according to a modified example in the second embodiment;

FIG. 5B is a simple cross-sectional view illustrating a cross section taken along I-I in FIG. 5A;

FIG. 6A is a plan view illustrating a schematic configuration of a semiconductor device according to a third embodiment;

FIG. 6B is a plan view illustrating a schematic configuration of FIG. 6A excluding a configuration above VNW structures;

FIG. 6C is a plan view illustrating a schematic configuration of local wirings and wirings thereon in a partial region in FIG. 6A;

FIG. 7A is a cross-sectional view illustrating a cross section taken along I-I in FIG. 6A;

FIG. 7B is a simple cross-sectional view corresponding to FIG. 7A;

FIG. 7C is a cross-sectional view illustrating a cross section taken along II-II in FIG. 6A;

FIG. 8 is an equivalent circuit diagram illustrating a connection state of the semiconductor device according to the third embodiment;

FIG. 9A a plan view illustrating a schematic configuration of a semiconductor device according to a fourth embodiment;

FIG. 9B is a plan view illustrating a schematic configuration of FIG. 9A excluding a configuration above VNW structures;

FIG. 9C is a plan view illustrating a schematic configuration of local wirings and wirings thereon in a partial region in FIG. 9A;

FIG. 10A is a cross-sectional view illustrating a cross section taken along I-I in FIG. 9A;

FIG. 10B is a simple cross-sectional view corresponding to FIG. 10A;

FIG. 11 is an equivalent circuit diagram illustrating how capacitive coupling is formed between a resistance element and a power supply line Vss;

FIG. 12A is a plan view illustrating a schematic configuration of a semiconductor device according to a fifth embodiment;

FIG. 12B is a plan view illustrating a schematic configuration of FIG. 12A excluding a configuration above VNW structures;

FIG. 12C is a plan view illustrating a schematic configuration of local wirings and wirings thereon in a partial region in FIG. 12A;

FIG. 13 is an equivalent circuit diagram illustrating a connection state of the semiconductor device according to the fifth embodiment;

FIG. 14A is a plan view illustrating a schematic configuration of a semiconductor device according to a sixth embodiment;

FIG. 14B is a plan view illustrating a schematic configuration of FIG. 14A excluding a configuration above VNW structures;

FIG. 14C is a plan view illustrating a schematic configuration of local wirings and wirings thereon in a partial region in FIG. 14A;

FIG. 15 is an equivalent circuit diagram illustrating a connection state of the semiconductor device according to the sixth embodiment;

FIG. 16A is a plan view illustrating a schematic configuration of a semiconductor device according to a modified example 1 in the sixth embodiment;

FIG. 16B is a plan view illustrating a schematic configuration of FIG. 16A excluding a configuration above VNW elements;

FIG. 16C is a plan view illustrating a schematic configuration of local wirings and wirings thereon in a partial region in FIG. 16A;

FIG. 17 is a simple cross-sectional view illustrating a cross section taken along I-I in FIG. 16A;

FIG. 18 is an equivalent circuit diagram of the semiconductor device according to the modified example 1 in the sixth embodiment;

FIG. 19A is a plan view illustrating a schematic configuration of a semiconductor device according to a modified example 2 in the sixth embodiment;

FIG. 19B is a plan view illustrating a schematic configuration of FIG. 19A excluding a configuration above VNW elements;

FIG. 19C is a plan view illustrating a schematic configuration of local wirings and wirings thereon in a partial region in FIG. 19A;

FIG. 20 is a simple cross-sectional view illustrating a cross section taken along I-I in FIG. 19A;

FIG. 21 is an equivalent circuit diagram of the semiconductor device according to the modified example 2 in the sixth embodiment;

FIG. 22 is a simple cross-sectional view of a modified example 3 in the sixth embodiment, which corresponds to the cross section taken along I-I in FIG. 19A in the modified example 2.

FIG. 23A is a simple cross-sectional view of a semiconductor device according to a first aspect in a seventh embodiment, which corresponds to FIG. 4B in the second embodiment;

FIG. 23B is an equivalent circuit diagram of a resistance element in the first aspect in the seventh embodiment;

FIG. 24A is a simple cross-sectional view of a semiconductor device according to a second aspect in the seventh embodiment, which corresponds to FIG. 4B in the second embodiment;

FIG. 24B is an equivalent circuit diagram of a resistance element in the second aspect in the seventh embodiment;

FIG. 25A is a plan view illustrating a schematic configuration of a semiconductor device according to an eighth embodiment;

FIG. 25B is a plan view illustrating a schematic configuration of FIG. 25A excluding a configuration above VNW structures;

FIG. 25C is a plan view illustrating a schematic configuration of local wirings and wirings thereon in a partial region in FIG. 25A;

FIG. 26 is a simple cross-sectional view illustrating a cross section taken along I-I in FIG. 25A;

FIG. 27 is an equivalent circuit diagram of a CR timer circuit according to the eighth embodiment;

FIG. 28A is a plan view illustrating a schematic configuration of a semiconductor device according to a modified example in the eighth embodiment;

FIG. 28B is a plan view illustrating a schematic configuration of FIG. 28A excluding a configuration above VNW structures;

FIG. 28C is a plan view illustrating a schematic configuration of local wirings and wirings thereon in a partial region in FIG. 28A;

FIG. 29 is a simple cross-sectional view illustrating a cross section taken along I-I in FIG. 28A;

FIG. 30 is an equivalent circuit diagram of a CR timer circuit according to a modified example in the eighth embodiment;

FIG. 31A is a plan view illustrating a schematic configuration of a semiconductor device according to a ninth embodiment;

FIG. 31B is a plan view illustrating a schematic configuration of FIG. 31A excluding a configuration above VNW structures;

FIG. 31C is a plan view illustrating a schematic configuration of local wirings and wirings thereon in a partial region in FIG. 31A;

FIG. 32 is a simple cross-sectional view illustrating a cross section taken along I-I in FIG. 31A; and

FIG. 33 is an equivalent circuit diagram of the semiconductor device according to the ninth embodiment.

### DESCRIPTION OF EMBODIMENTS

Various embodiments of a semiconductor device including a resistance element will be explained in detail below with reference to the drawings.

### First Embodiment

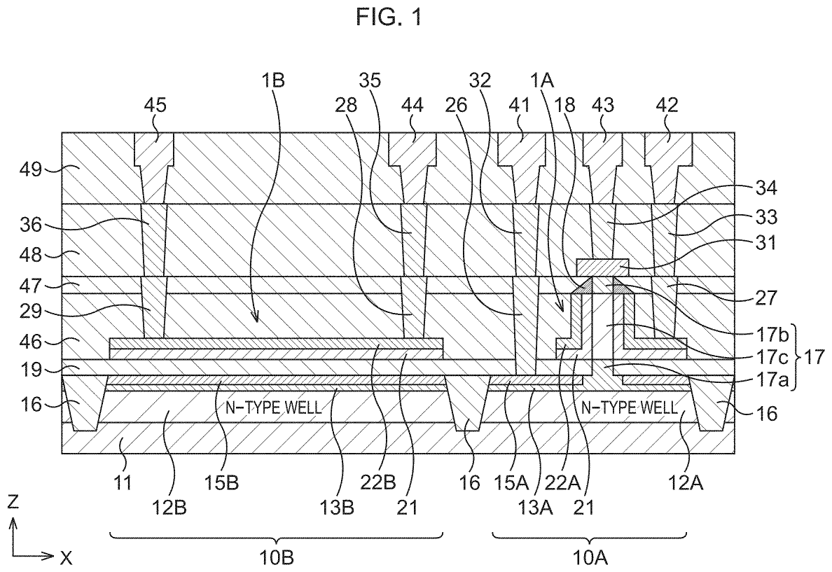

In this embodiment, there is disclosed a basic configuration of a semiconductor device including a resistance element to which the VNW technique is applied. FIG. 1 is a cross-sectional view illustrating a schematic configuration of a semiconductor device according to a first embodiment.

This semiconductor device includes a VNW transistor 1A and a resistance element 1B. The VNW transistor 1A is arranged in a VNW transistor arrangement region 10A. The resistance element 1B is arranged in a resistance element arrangement region 10B. Incidentally, as the VNW, a VNW diode may be used in place of the VNW transistor.

A substrate 11 is a substrate of a compound or an alloy of bulk Si, germanium (Ge), Si, or Ge, or a substrate of one kind selected from SiC, SiP, SiPC, GaAs, GaP, InP, InAs, In, Sb, SiGe, GaAcP, AlInAs, GaInAs, GaInP, and GaInAsP, a combination of these, or the like, for example. An SOI substrate can also be used.

The VNW transistor arrangement region 10A is demarcated by STI element isolation regions 16. The resistance element arrangement region 10B is demarcated by STI element isolation regions 16.

The STI element isolation region 16 is formed in a manner that an insulating material is filled in an opening formed in the substrate 11. As the insulating material, it is possible to use, for example, SiO, PSG (phosphorus silicate glass), BSG (boron silicate glass), BPSG (boron-phosphorus silicate glass), USG (undoped silicate glass), or a combination of these.

In the VNW transistor arrangement region 10A, a well 12A having an N-type conductivity, for example, is formed in the substrate 11. In the resistance element arrangement region 10B, a well 12B having an N-type conductivity, for example, is formed.

The wells 12A, 12B are formed in a manner that an N-type impurity is ion-implanted into the substrate 11. As the N-type impurity, one kind or plural kinds selected from As, P, Sb, and N are used.

An impurity region 13A having a conductivity type opposite to that of the well 12A, such as a P type, for example, is formed on the top of the well 12A in the substrate 11. On the surface of the semiconductor substrate 11, which is also the top of the impurity region 13A, a silicide layer 15A is formed.

An impurity region 13B having a conductivity type opposite to that of the well 12B, such as a P type, for example, is formed on the top of the well 12B in the substrate 11. On the surface of the semiconductor substrate 11, which is also the top of the impurity region 13B, a silicide layer 15B is formed.

The impurity regions 13A, 13B are formed in a manner that a P-type impurity is ion-implanted into the substrate 11. As the P-type impurity, one kind or plural kinds selected from B, BF₂, In, and N are used.

The silicide layers 15A, 15B are formed in a manner that a metal film is formed on the surfaces of the impurity regions 13A, 13B and is subjected to a heat treatment to turn the surfaces of the impurity regions 13A, 13B into silicide. As a material of the metal film, for example, Ni, Co, Mo, W, Pt, Ti, or the like is used.

In the VNW transistor arrangement region 10A, on the substrate 11, a plurality of projecting semiconductor nanowires 17 are formed vertically to the surface of the substrate 11. The semiconductor nanowire 17 has a lower end portion 17a, an upper end portion 17b, and a middle portion 17c between the lower end portion 17a and the upper end portion 17b. The lower end portion 17a has a P-type conductivity and is electrically connected to the impurity region 13A. The upper end portion 17b has a P-type conductivity. The middle portion 17c has an N-type conductivity or is non-doped and serves as a channel region of the transistor. One of the lower end portion 17a and the upper end portion 17b is a source electrode and the other is a drain electrode. On a side surface of the upper end portion 17b, a sidewall 18 of an insulating film is formed. Incidentally, the lower end portion 17a and the upper end portion 17b may have an N type and the middle portion 17c may have a P type or may be non-doped. Further, in the case of the substrate 11 being an N-type semiconductor substrate, the formations of the N-type wells 12A, 12B may be omitted. A planar shape of the semiconductor nanowire 17 may be, for example, a circular shape, an elliptical shape, a quadrangular shape, or a shape extending in one direction. Incidentally, the term “non-doped” in this application means a portion of the semiconductor nanowire 17 that is not subjected to an impurity implantation step.

On the surfaces of the silicide layers 15A, 15B and the STI element isolation regions 16, an interlayer insulating film 19 that covers the side surface of the lower end portion 17a of the semiconductor nanowire 17 is formed.

The semiconductor nanowire 17 is formed in a manner that a P-type impurity is ion-implanted into the lower end portion 17a and the upper end portion 17b, and an N-type impurity is ion-implanted into the middle portion 17c. As the P-type impurity, one kind or plural kinds selected from B, BF₂, In, and N are used. As the N-type impurity, one kind or plural kinds selected from As, P, Sb, and N are used.

The sidewall 18 is formed by using, as a material, an insulating material such as SiO₂, SiN, SiON, SiC, SiCN, or SiOCN.

The interlayer insulating film 19 is formed by using, as a material, an insulating material such as, for example, SiO₂, TEOS, PSG, BPSG, FSG, SiOC, SOG, SOP (Spin on Polymers), or SiC.

In the VNW transistor arrangement region 10A, a gate electrode 22A is formed on the side surface of the semiconductor nanowire 17 via a gate insulating film 21. In the resistance element arrangement region 10B, a conductive pattern 22B is formed on the gate insulating film 21. In this embodiment, the conductive pattern 22B of the resistance element 1B is formed by using a forming step of the gate electrode 22A of the VNW transistor 1A. Concretely, the gate electrode 22A of the VNW transistor 1A and the conductive pattern 22B of the resistance element 1B are formed by a single-layer conductor film being processed in the same step. Therefore, the gate electrode 22A and the conductive pattern 22B are made of the same material. However, they may have different materials.

The gate insulating film 21 is formed by using, as a material, an insulating material having a dielectric constant k of 7 or more, for example, such as SiN, Ta₂O₅, Al₂O₃, or HfO₂, for example. The gate electrode 22A and the conductive pattern 22B are formed by using, as a material, TiN, TaN, TiAl, TaAl, Ti-containing metal, Al-containing metal, W-containing metal, TiSi, NiSi, PtSi, polycrystalline silicon having silicide, or the like.

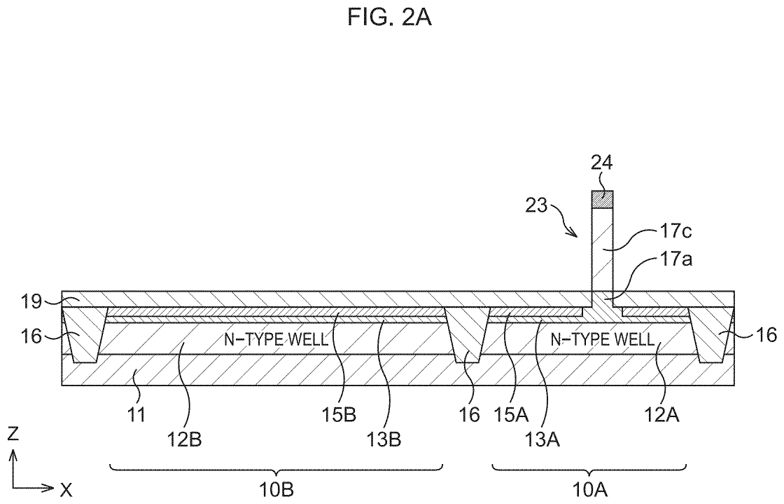

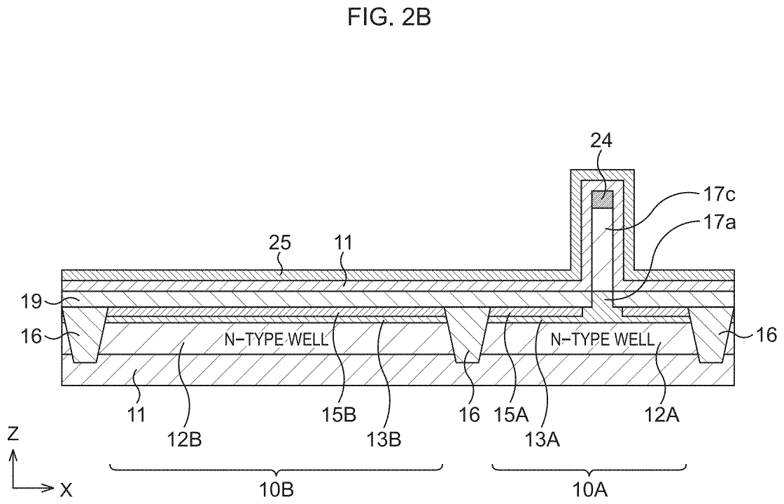

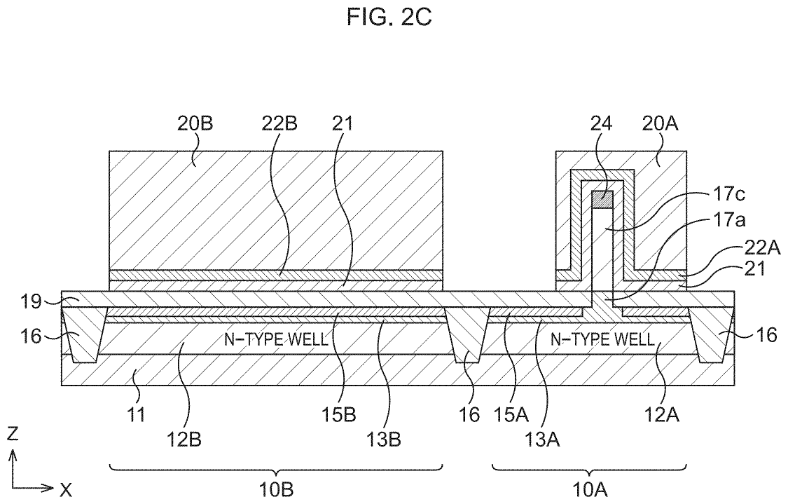

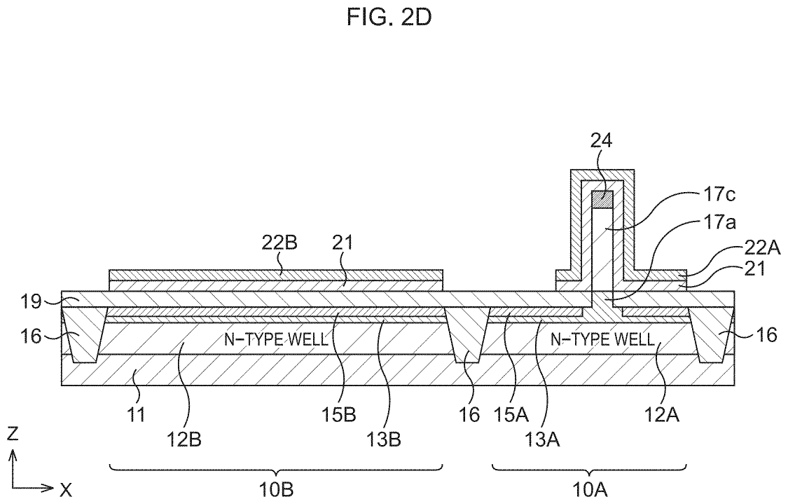

The gate electrode 22A and the conductive pattern 22B are formed as follows, for example. FIG. 2A to FIG. 2D are schematic cross-sectional views illustrating a forming method of the gate electrode 22A and the conductive pattern 22B in order of processes.

As illustrated in FIG. 2A, the interlayer insulating film 19 is formed above the substrate 11. In the VNW transistor arrangement region 10A, a projection 23 to be the semiconductor nanowire is formed. In the projection 23, the lower end portion 17a and the middle portion 17c are formed. The lower end portion 17a is electrically connected to the impurity region 13A. On the projection 23, a hard mask 24, which is used for forming this projection 23, is left.

Following the state of FIG. 2A, as illustrated in FIG. 2B, the gate insulating film 21 and a conductor film 25 are sequentially formed on the interlayer insulating film 19 so as to cover the projection 23 and the hard mask 24.

Then, as illustrated in FIG. 2C, a resist is applied to the entire surface of the conductor film 25 and is patterned by lithography to form resist masks 20A, 20B. The resist mask 20A is made of the resist remaining at a portion containing the projection 23 and the hard mask 24 on the conductor film 25 in the VNW transistor arrangement region 10A. The resist mask 20B is made of the resist remaining at a portion on the conductor film 25 in the resistance element arrangement region 10B.

The conductor film 25 and the gate insulating film 21 are etched (dry-etched or wet-etched) while using the resist masks 20A, 20B to leave the gate insulating film 21 and the conductor film 25 on the interlayer insulating film 19.

Then, as illustrated in FIG. 2D, the resist masks 20A, 20B are removed by ashing or wetting. Thereby, in the VNW transistor arrangement region 10A, the gate electrode 22A is formed on the interlayer insulating film 19 via the gate insulating film 21 so as to cover the projection 23 and the hard mask 24. The gate electrode 22A is a conductive pattern formed by the conductor film 25 being etched. In the resistance element arrangement region 10B, the conductive pattern 22B is formed on the interlayer insulating film 19 via the gate insulating film 21. The conductive pattern 22B is a conductive pattern formed by the conductor film 25 being etched. At this time, the gate insulating film 21 and the conductive pattern 22B may have the same shape in a plane view.

Thereafter, various steps such as formation of an interlayer insulating film, partial removal of the gate insulating film 21 and the gate electrode 22A, exposure and removal of the hard mask 24, and formation of the upper end portion 17b are performed.

In the VNW transistor arrangement region 10A, a plurality of contact plugs, for example, contact plugs 26, 27 are arranged. In the resistance element arrangement region 10B, a plurality of contact plugs, for example, contact plugs 28, 29 are arranged. The contact plug 26 is electrically connected to the silicide layer 15A. The contact plug 27 is electrically connected to the gate electrode 22A. The contact plug 28 is electrically connected to one end of the conductive pattern 22B. The contact plug 29 is electrically connected to the other end of the conductive pattern 22B.

The contact plugs 26 to 29 each are formed of a base film formed so as to cover an inner wall surface of each opening, and a conductive material that fills the inside of each of the openings through the base film. As a material of the base film, for example, Ti, TiN, Ta, TaN, or the like is used. As the conductive material, for example, Cu, a Cu alloy, W, Ag, Au, Ni, Al, Co, Ru, or the like is used. Incidentally, in the case where the conductive material is Co or Ru, the formation of the base film may be omitted.

A silicide layer 31 is formed on the VNW transistor 1A. The silicide layer 31 is electrically connected to the upper end portion 17b of the semiconductor nanowire 17. The silicide layer 31 is formed in a manner that a semiconductor material and a metal film are formed on the VNW transistor 1A and are subjected to a heat treatment to turn the semiconductor material into silicide. As a material of the metal film, for example, Ni, Co, Mo, W, Pt, Ti, or the like is used.

In the VNW transistor arrangement region 10A, a plurality of local wirings, for example, local wirings 32 to 34 are arranged. In the resistance element arrangement region 10B, a plurality of local wirings, for example, local wirings 35, 36 are arranged. The local wiring 32 is electrically connected to a top surface of the contact plug 26. The local wiring 33 is electrically connected to a Lop surface of the contact plug 27. The local wiring 34 is electrically connected to a top surface of the silicide layer 31. The local wiring 35 is electrically connected to a top surface of the contact plug 28. The local wiring 36 is electrically connected to a top surface of the contact plug 29.

The local wirings 32 to 36 each are formed of a base film formed so as to cover an inner wall surface of each opening, and a conductive material that fills the inside of each of the openings through the base film. As a material of the base film, for example, Ti, TiN, Ta, TaN, or the like is used. As the conductive material, for example, Cu, a Cu alloy, W, Ag, Au, Ni, Al, Co, Ru, or the like is used. Incidentally, in the case where the conductive material is Co or Ru, the formation of the base film may be omitted.

In the VNW transistor arrangement region 10A, a plurality of wirings, for example, M1-layer wirings 41 to 43 are arranged. The respective M1-layer wirings are arranged on the respective local wirings. In the resistance element arrangement region 10B, a plurality of wirings, for example, M1-layer wirings 44, 45 are arranged. The wiring 41 is electrically connected to a top surface of the local wiring 32. The wiring 42 is electrically connected to a top surface of the local wiring 33. The wiring 43 is electrically connected to a top surface of the local wiring 34. The wiring 44 is electrically connected to a top surface of the local wiring 35. The wiring 45 is electrically connected to a top surface of the local wiring 36.

The wirings 41 to 45 each have a dual damascene structure with a wiring portion being an upper portion and a via portion being a lower portion formed integrally. The via portion is in contact with the local wiring. The wirings 41 to 45 are formed in a manner that wiring grooves and via holes are filled with a conductive material by a plating method. As the conductive material, Cu, a Cu alloy, Co, Ru, or the like is used. Further, as a base film of the conductive material, for example, Ti, TiN, Ta, TaN, or the like is used. Incidentally, the wiring portion and the via portion may be formed separately to have a single damascene structure. In this case, the wiring portion and the via portion may be formed of materials different from each other. These are not limited to this embodiment, and the wirings may be formed to have a single damascene structure also in other embodiments and modified examples. Further, in the case where the conductive material of the wirings 41 to 45 is Co or Ru, the formation of the base film of the conductive material may be omitted.

On the interlayer insulating film 19, interlayer insulating films 46 to 49 are formed in layers.

The VNW transistor 1A, the resistance element 1B, and the contact plugs 27 to 29 are formed in the interlayer insulating films 46, 47. The contact plug 26 is formed in the interlayer insulating films 19, 46, and 47. The silicide layer 31 and the local wirings 32 to 36 are formed in the interlayer insulating film 48. The wirings 41 to 45 are formed in the interlayer insulating film 49. Incidentally, the formation of the silicide layer 31 may be omitted and the local wiring 34 and the top surface of the semiconductor nanowire 17 may be connected.

The interlayer insulating films 46 to 49 are formed by using, as a material, an insulating material such as SiO₂, TEOS, PSG, BPSG, FSG, SiOC, SOG, SOP (Spin on Polymers), or SiC.

In this embodiment, the gate electrode 22A of the VNW transistor 1A and the conductive pattern 22B of the resistance element 1B are formed by the single-layer conductor film 25 being processed. In the resistance element 1B, the conductive pattern 22B is used as an electrical resistance body. In the VNW transistor 1A, the conductor film 25 is used as the gate electrode 22A. The conductor film 25 is relatively thinner than the local wirings 32 to 36, and so on, for example. Concretely, for example, the film thickness of the conductor film 25 formed at a position different from the side surface of the semiconductor nanowire 17 (for example, in the resistance element arrangement region 10B) in the Z direction is smaller than the film thickness of the local wirings 32 to 36 in the Z direction. Therefore, a resistance value of the conductor film 25 is higher than that of the local wirings 32 to 36, and so on. This conductor film 25 is applied to the conductive pattern 22B, which is the conductive pattern of the resistance element 1B, as well as to the gate electrode 22A of the VNW transistor 1A. This makes it possible to reduce the manufacturing steps and obtain the conductive pattern 22B in the resistance element 1B together with the gate electrode 22A. Incidentally, the conductive pattern 22B of the resistance element 1B may also serve as the gate electrode of the transistor. The respective configurations, materials, and the like explained in this embodiment may be applied to other embodiments, modified examples, and so on.

### Second Embodiment

In this embodiment, there is disclosed a semiconductor device including a resistance element to which the VNW technique is applied, similarly to the first embodiment, but this embodiment is different from the first embodiment in that VNW structures are provided in the resistance element.

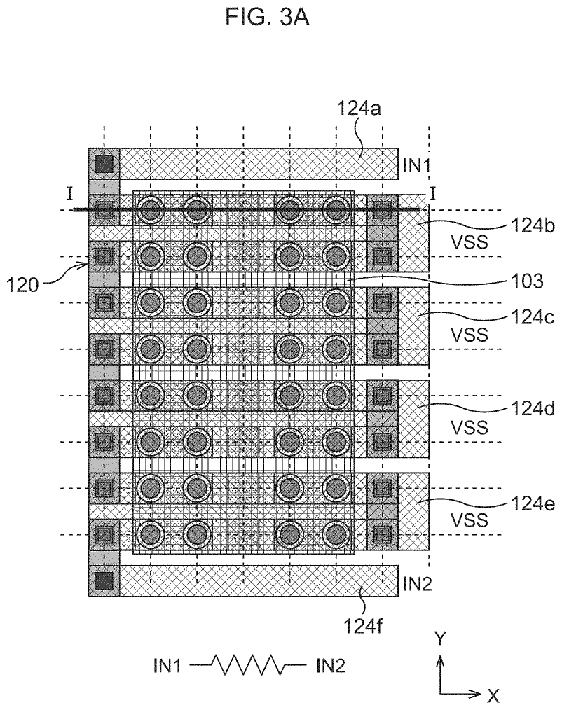

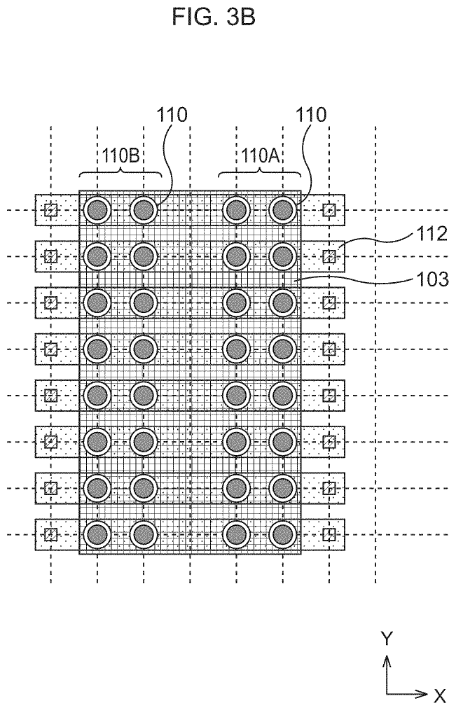

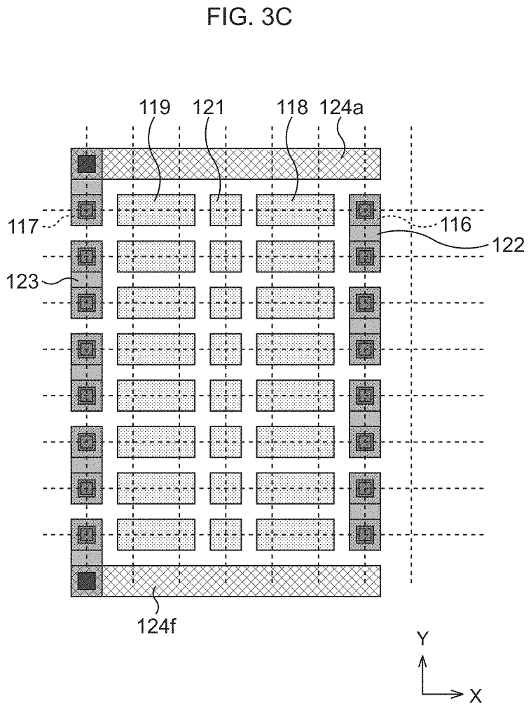

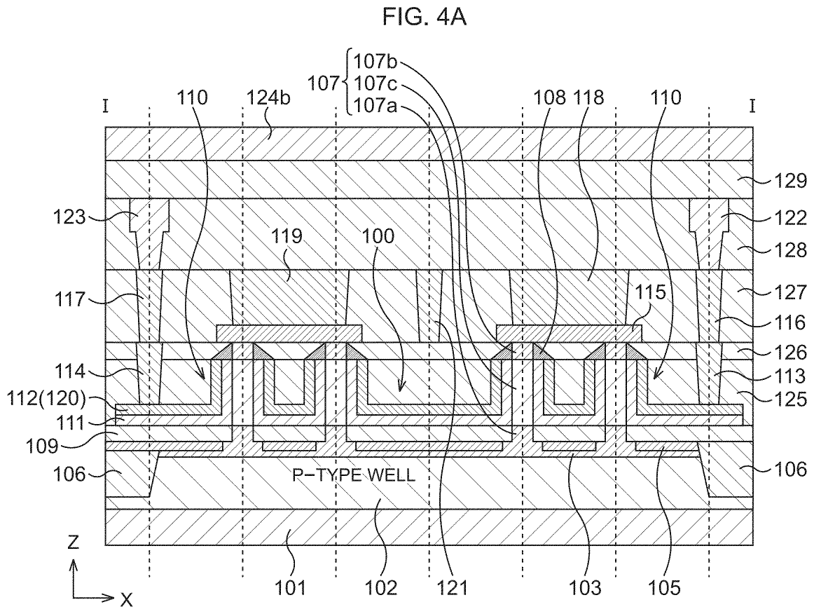

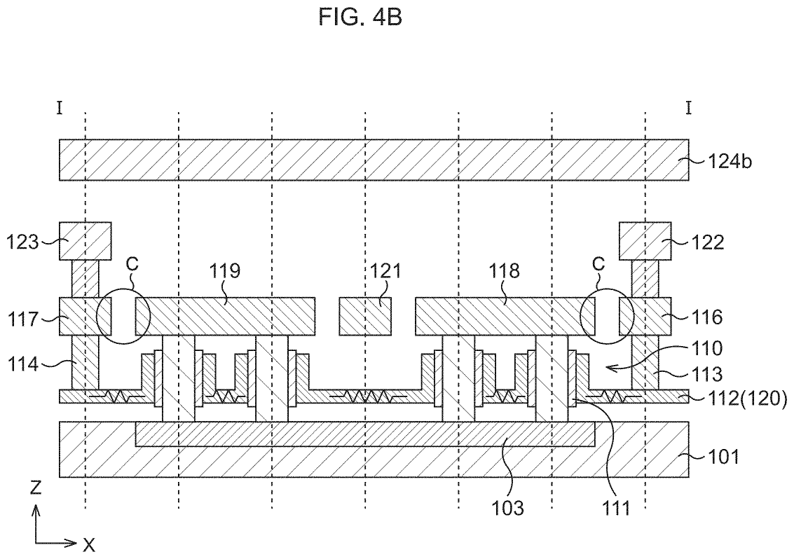

FIG. 3A is a plan view illustrating a schematic configuration of a semiconductor device according to a second embodiment. FIG. 3B is a plan view illustrating a schematic configuration of FIG. 3A excluding a configuration above VNW structures. FIG. 3C is a plan view illustrating a schematic configuration of local wirings and wirings thereon in a partial region in FIG. 3A. FIG. 4A is a cross-sectional view illustrating a cross section taken along I-I in FIG. 3A. FIG. 4B is a simple cross-sectional view corresponding to FIG. 4A. Incidentally, the illustrated layouts are one example. For example, VNW elements, gate electrodes, various wirings, and so on illustrated to be arranged in adjacent grids may be arranged apart by a plurality of grids. In that case, for example, a dummy structure of a VNW element, a gate electrode, various wirings, and so on (STI or the like in the case of an impurity region) may be provided in a distant region. This is also true for later-described embodiments and various modified examples.

This semiconductor device includes a resistance element 100 above a substrate 101. The resistance element 100 includes VNW structures 110 grouped and arranged in a matrix in a plane view, for example, as illustrated in FIG. 3B. In FIG. 3B, a first group 110A and a second group 110B, each of which includes a total of 16 VNW structures 110, for example, two in the X direction and eight in the Y direction, are arranged side by side at predetermined intervals. Incidentally, the number and the arrangement form of VNW structures 110 are not limited to those in FIG. 3B, and the VNW structures 110 may be arranged in a number and an arrangement form different from those in FIG. 3B.

The substrate 101 is a substrate of a compound or an alloy of bulk Si, germanium (Ge), Si, or Ge, or a substrate of one kind selected from SiC, SiP, SiPC, GaAs, GaP, InP, InAs, In, Sb, SiGe, GaAcP, AlInAs, GaInAs, GaInP, and GaInAsP, a combination of these, or the like, for example. An SOI substrate can also be used.

An arrangement region of the resistance element 100 is demarcated by STI element isolation regions 106.

The STI element isolation region 106 is formed in a manner that an insulating material is filled in an opening formed in the substrate 101. The insulating material may be SiO, PSG (phosphorus silicate glass), BSG (boron silicate glass), BPSG (boron-phosphorus silicate glass), USG (undoped silicate glass), or a combination of these, for example.

In the arrangement region of the resistance element 100, a well 102 having a P-type conductivity, for example, is formed in the substrate 101.

The well 102 is formed in a manner that a P-type impurity is ion-implanted into the substrate 101. As the P-type impurity, one kind or plural kinds selected from B, BF₂, In, and N are used.

An impurity region 103 having a conductivity type opposite to that of the well 102, such as an N type, for example, is formed on the top of the well 102 in the substrate 101. On the surface of the substrate 101, which is also the top of the impurity region 103, a silicide layer 105 is formed.

The impurity region 103 is formed in a manner that an N-type impurity is ion-implanted into the substrate 101. As the N-type impurity, one kind or plural kinds selected from As, P, Sb, and N are used.

The silicide layer 105 is formed in a manner that a metal film is formed on the surface of the impurity region 103 and is subjected to a heat treatment to turn the surface of the impurity region 103 into silicide. As a material of the metal film, for example, Ni, Co, Mo, W, Pt, Ti, or the like is used.

Above the well 102 in the substrate 101, a plurality of projecting semiconductor nanowires 107 are formed vertically to the surface of the substrate 101. The semiconductor nanowire 107 has a lower end portion 107a, an upper end portion 107b, and a middle portion 107c between the lower end portion 107a and the upper end portion 107b. The lower end portion 107a has an N-type conductivity and is electrically connected to the impurity region 103. The upper end portion 107b has an N-type conductivity. The middle portion 107c has an N-type conductivity or is non-doped. On a side surface of the upper end portion 107b, a sidewall 108 of an insulating film is formed. Incidentally, the lower end portion 107a and the upper end portion 107b may have an N type and the middle portion 107c may have an N-type conductivity and have an impurity concentration lower than the lower end portion 107a and the upper end portion 107b. Further, like the VNW transistor, the lower end portion 107a and the upper end portion 107b may have a P type and the middle portion 107c may have an N type or may be non-doped. Further, in the case of the substrate 101 being a P-type semiconductor substrate, the formation of the P-type well 102 may be omitted. A planar shape of the semiconductor nanowire 107 may be, for example, a circular shape, an elliptical shape, a quadrangular shape, or a shape extending in one direction.

On the surfaces of the silicide layer 105 and the STI element isolation regions 106, an interlayer insulating film 109 that covers side surfaces of the lower end portions 17a of the semiconductor nanowires 107 is formed.

The semiconductor nanowire 107 is formed in a manner that an N-type impurity is ion-implanted into the lower end portion 107a and the upper end portion 107b, and an N-type impurity having an impurity concentration lower than that of the lower end portion 107a and the upper end portion 107b is ion-implanted into the middle portion 107c. As the N-type impurity, one kind or plural kinds selected from As, P, Sb, and N are used.

The sidewall 108 is formed by using, as a material, an insulating material such as SiO₂, SiN, SiON, SiC, SiCN, or SiOCN.

The interlayer insulating film 109 is formed by using, as a material, an insulating material such as, for example, SiO₂, TEOS, PSG, BPSG, FSG, SiOC, SOG, SOP (Spin on Polymers), or SiC.

On the side surfaces of the semiconductor nanowires 107, a gate electrode 112 is formed via a gate insulating film 111. In this embodiment, the resistance element 100 includes a conductive pattern 120 using the gate electrodes 112 arranged on the side surfaces of the semiconductor nanowires 107 of the VNW structures 110. Concretely, as illustrated in FIG. 3B, out of, for example, 32 VNW structures 110 forming the first group 110A and the second group 110B, the gate electrode 112 extending in the X direction is provided in common for each four VNW structures 110 aligned along the X direction. As will be described later, these gate electrodes 112 are electrically connected to form the single conductive pattern 120 practically. This conductive pattern 120 is used as an electrical resistance body of the resistance element 100.

The gate insulating film 111 is formed by using, as a material, an insulating material having a dielectric constant k of 7 or more, for example, such as SiN, Ta₂O₅, Al₂O₃, or HfO₂, for example. The gate electrode 112 is formed by using, as a material, TiN, TaN, TiAl, TaAl, Ti-containing metal, Al-containing metal, W-containing metal, TiSi, NiSi, PtSi, polycrystalline silicon having silicide, or the like.

In the resistance element 100, a plurality of contact plugs, for example, contact plugs 113, 114 are arranged. As illustrated in FIG. 3B and FIG. 4A, the contact plug 113 is electrically connected to one end of each of the gate electrodes 112, and the contact plug 114 is electrically connected to the other end of each of the gate electrodes 112.

The contact plugs 113, 114 each are formed of a base film formed so as to cover an inner wall surface of each opening, and a conductive material that fills the inside of each of the openings through the base film. As a material of the base film, for example, Ti, TiN, Ta, TaN, or the like is used. As the conductive material, for example, Cu, a Cu alloy, W, Ag, Au, Ni, Al, Co, Ru, or the like is used. Incidentally, in the case where the conductive material is Co or Ru, the formation of the base film may be omitted.

A silicide layer 115 is formed on the VNW structure 110. In this embodiment, the silicide layer 115 is provided in common for each two VNW structures 110 aligned along the X direction. The silicide layer 115 is electrically connected to the upper end portion 107b of the semiconductor nanowire 107. The silicide layer 115 is formed in a manner that a semiconductor material and a metal film are formed on the VNW structure 110 and are subjected to a heat treatment to turn the semiconductor material into silicide. As a material of the metal film, for example, Ni, Co, Mo, W, Pt, Ti, or the like is used.

In the arrangement region of the resistance element 100, a plurality of local wirings, for example, local wirings 116, 117, 118, 119, and 121 are arranged. The local wiring 116 is electrically connected to a top surface of the contact plug 113. The local wiring 117 is electrically connected to a top surface of the contact plug 114. The local wiring 118 is electrically connected to a top surface of the silicide layer 115 on one side. The local wiring 119 is electrically connected to a top surface of the silicide layer 115 on the other side.

As illustrated in FIG. 3C, the local wirings 116, 117, 118, 119, and 121 are arranged side by side along the X direction above the respective gate electrodes 112. Between the local wirings 116 and 118, between the local wirings 118 and 121, between the local wirings 121 and 119, and between the local wirings 119 and 117 each are separated from each other. As a result, the local wirings 118, 119 are electrically separated from each other, and are not electrically connected to other conductors above. As a result, the respective semiconductor nanowires 107 are in a floating state electrically.

The local wirings 116, 117, 118, 119, and 121 each are formed of a base film formed so as to cover an inner wall surface of each opening, and a conductive material that fills the inside of each of the openings through the base film. As a material of the base film, for example, Ti, TiN, Ta, TaN, or the like is used. As the conductive material, for example, Cu, a Cu alloy, W, Ag, Au, Ni, Al, Co, Ru, or the like is used. Incidentally, in the case where the conductive material is Co or Ru, the formation of the base film may be omitted.

In the arrangement region of the resistance element 100, a plurality of wirings, for example, M1-layer wirings 122, 123 are arranged. The respective M1-layer wirings are arranged on the respective local wirings. The wiring 122 is electrically connected to a top surface of the local wiring 116. The wiring 123 is electrically connected to a top surface of the local wiring 117.

The arrangement of the wirings 122, 123 is explained while using FIG. 3B and FIG. 3C. The respective wirings 122 are aligned extending in the Y direction in a plane view so that each wiring 122 corresponds to the two adjacent gate electrodes 112. The respective wirings 123 are aligned extending in the Y direction in a plane view so that each wiring 123 corresponds to the two adjacent gate electrodes 112. The wirings 122, 123 are arranged to be displaced from each other by one gate electrode 112 with respect to a plurality of the gate electrodes 112 aligned along the Y direction in a plane view. The wirings 122, 123 are arranged as above and are electrically connected to the respective gate electrodes 112 through the local wirings 116, 117 and the contact plugs 113, 114. The respective gate electrodes 112 extending in the X direction are electrically connected in a zigzag shape by the wirings 122, 123 extending in the Y direction. As above, a plurality of the gate electrodes 122 are arranged in a zigzag shape together with the wirings 122, 123 to form practically the single conductive pattern 120 that serves as an electrical resistance body of the resistance element 100. The gate electrodes 112 and the wirings 122, 123 are connected as above, thereby making it possible to fabricate the single conductive pattern 120 practically with excellent area efficiency.

The connection of the gate electrodes 112 forming the conductive pattern 120 is not limited to the wirings 122, 123, and the local wirings 116, 117, for example, may be used.

In the arrangement region of the resistance element 100, M2-layer wirings 124a, 124b, 124c, 124d, 124e, and 124f, which function as a power supply line Vss, for example, are arranged. These M2-layer wirings are formed above the M1-layer wirings. As illustrated in FIG. 3A, between the wiring 124a and the wiring 124b, between the wiring 124b and the wiring 124c, between the wiring 124c and the wiring 124d, between the wiring 124d and the wiring 124e, and between the wiring 124e and the wiring 124f each are electrically connected. One end of the wiring 124a becomes one terminal IN1 of the conductive pattern 120. One end of the wiring 124f becomes the other terminal IN2 of the conductive pattern 120.

Incidentally, the respective terminals IN1, IN2 of the conductive pattern 120 may be arranged at another wiring, for example, a power supply line Vdd, in place of being arranged at the wirings 124a, 124f.

The wiring 122, the wiring 123, and the wirings 124a to 124f each have a dual damascene structure with a wiring portion being an upper portion and a via portion being a lower portion formed integrally. The via portion is in contact with the local wiring. The wiring 122, the wiring 123, and the wirings 124a to 124f are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

On the interlayer insulating film 109, interlayer insulating films 125 to 129 are formed in layers.

The VNW structures 110 and the contact plugs 113, 114 are formed in the interlayer insulating films 125, 126. The silicide layer 115 and the local wirings 116, 117, 118, 119, and 121 are formed in the interlayer insulating film 127. The wirings 122, 123 are formed in the interlayer insulating film 128. The wirings 124a to 124f are formed in the interlayer insulating film 129.

The interlayer insulating films 125 to 129 are formed by using, as a material, an insulating material such as SiO₂, TEOS, PSG, BPSG, FSG, SiOC, SOG, SOP (Spin on Polymers), or SiC.

In this embodiment, the conductive pattern 120 using the gate electrodes 112 of the VNW structures 110 is used as the electrical resistance body of the resistance element 100. In the VNW structure 110, the thin gate electrode 112 is used. The thin gate electrode 112 has a high resistance value. This gate electrode 112 is applied to the conductive pattern 120 of the resistance element 100. This makes it possible to obtain the conductive pattern 120 in the resistance element 100.

Further, in this embodiment, as illustrated in FIG. 4A and FIG. 4B, the local wirings 116, 117, 118, 119, and 121 that are aligned along the X direction are separated and electrically isolated from each other. The local wirings 118, 119 are not electrically connected to other conductors above. Each two semiconductor nanowires 107 are electrically connected to the local wirings 118 and 119. These semiconductor nanowires 107 are electrically in a floating state due to the electrical separation of the local wirings 118, 119. As a result, by the conductive pattern 120 to be the electrical resistance body in the resistance element 100, the effect of parasitic resistance generated in the substrate 101 and the semiconductor nanowires 107 is suppressed.

Incidentally, the lower end portions 107a of the respective semiconductor nanowires 107 are electrically connected by the impurity region 103, but the semiconductor nanowires 107 may be electrically separated at the lower end portions 107a. For example, the impurity region 103, which is located under the adjacent semiconductor nanowires 107, is divided to electrically separate the adjacent semiconductor nanowires 107. In this case, the portions each indicated by a circle C in FIG. 4B, namely, between the local wirings 116 and 118 and between the local wirings 119 and 117, may be connected because the local wirings 118 and 119 are electrically separated.

### Modified Example

Hereinafter, there will be explained a modified example of the semiconductor device in the second embodiment. In this example, there is disclosed a semiconductor device including a resistance element to which the VNW technique is applied similarly to the second embodiment, but this example is different in the arrangement aspect of the VNW structures from the second embodiment.

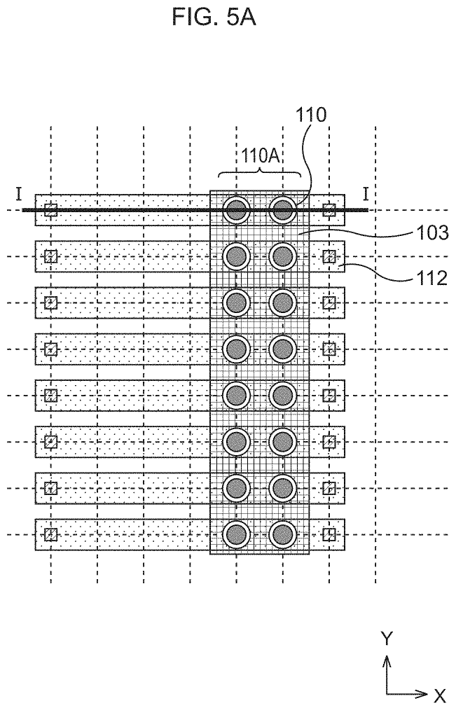

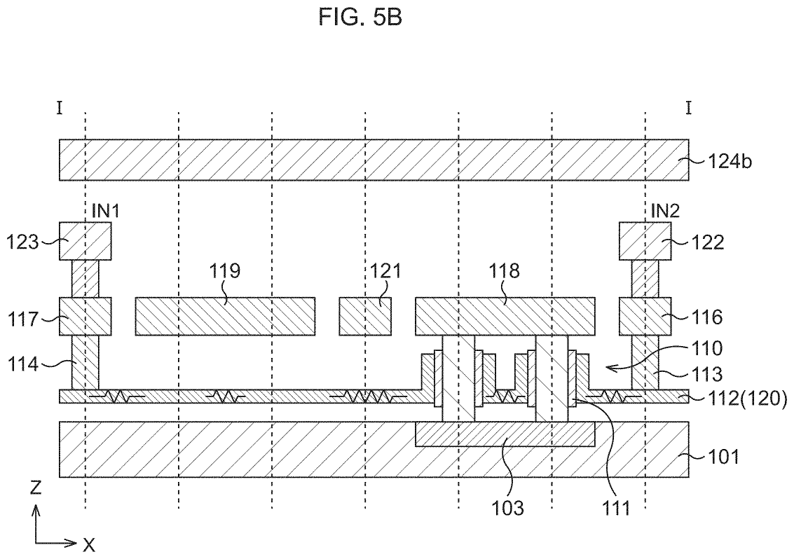

FIG. 5A is a plan view illustrating a schematic configuration of the semiconductor device according to the modified example in the second embodiment. FIG. 5B is a simple cross-sectional view illustrating a cross section taken along I-I in FIG. 5A. Incidentally, the same reference numerals and symbols are added to the same component members and so on as those in the semiconductor device according to the second embodiment, and their detailed explanations are omitted.

This semiconductor device includes the resistance element 100 above the substrate 101. The resistance element 100 includes the VNW structures 110 grouped and arranged in a matrix in a plane view, for example, as illustrated in FIG. 5A. In FIG. 5A and FIG. 5B, unlike FIG. 3B and the like in the second embodiment, the resistance element 100 includes only the first group 110A on the right in FIG. 3B without including the second group 110B on the left. The first group 110A includes a total of 16 VNW structures 110, for example, two in the X direction and eight in the Y direction, arranged similarly to FIG. 3B and the like. In this case, on the left of the first group 110A, the semiconductor nanowires 107 in the VNW structures are not provided, and as in the first embodiment, the gate electrodes 112 are provided. Incidentally, the number and the arrangement form of VNW structures 110 are not limited to those in FIG. 5A and FIG. 5B and the VNW structures 110 are sometimes arranged in a number and an arrangement form different from those in FIG. 5A and FIG. 5B.

In this example, in addition to the various effects that the semiconductor device according to the second embodiment has, the following effects are exhibited. In the resistance element, aspects such as the thickness and the width of the gate electrode change due to the presence or absence of the semiconductor nanowire in the VNW structure. Therefore, the resistance value per unit area in the resistance element varies. For example, in the case where the semiconductor nanowires project sufficiently from the interlayer insulating film, the resistance value decreases as compared to the case where no semiconductor nanowires are present because the gate electrode extends also along the direction vertical to the side surface of the semiconductor nanowire (Z direction). Using the above makes it possible to appropriately adjust the resistance value of the resistance element. In this example, the resistance value of the resistance element 100 is adjusted by arranging the VNW structures 110 only on the right side, not on the left side, for example, in place of arranging the VNW structures 110 uniformly.

### Third Embodiment

In this embodiment, there is disclosed a basic configuration of a semiconductor device including a resistance element to which the VNW technique is applied, similarly to the first and second embodiments, but this embodiment is different from the first and second embodiments in that in the resistance element, VNW structures are provided and at the same time, a plurality of VNW transistors are provided.

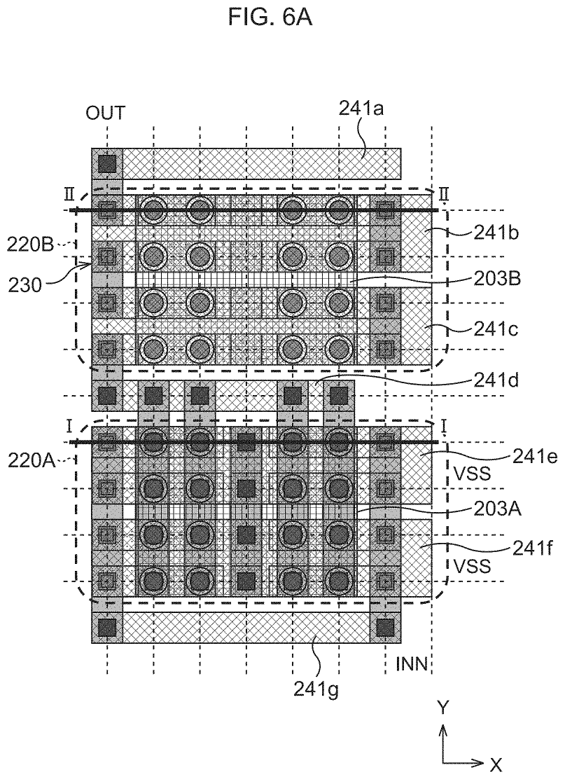

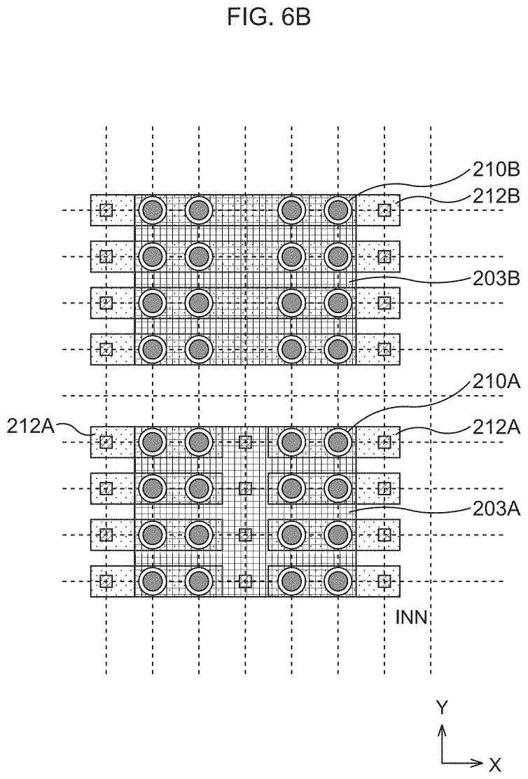

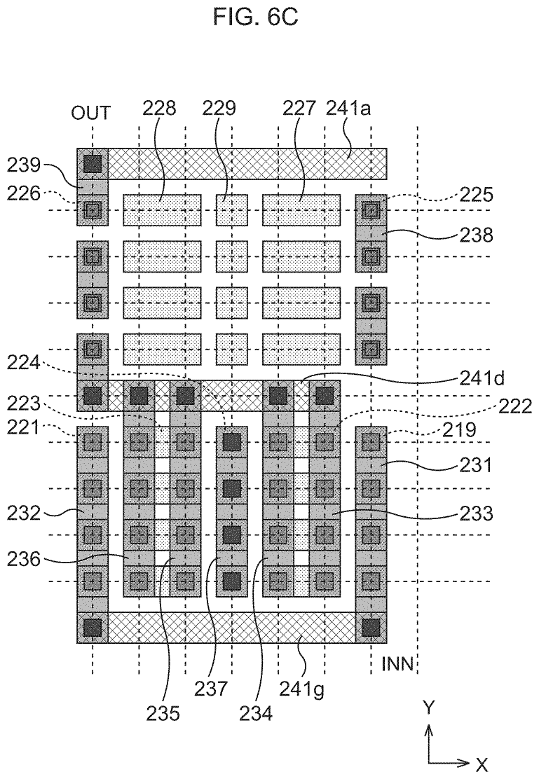

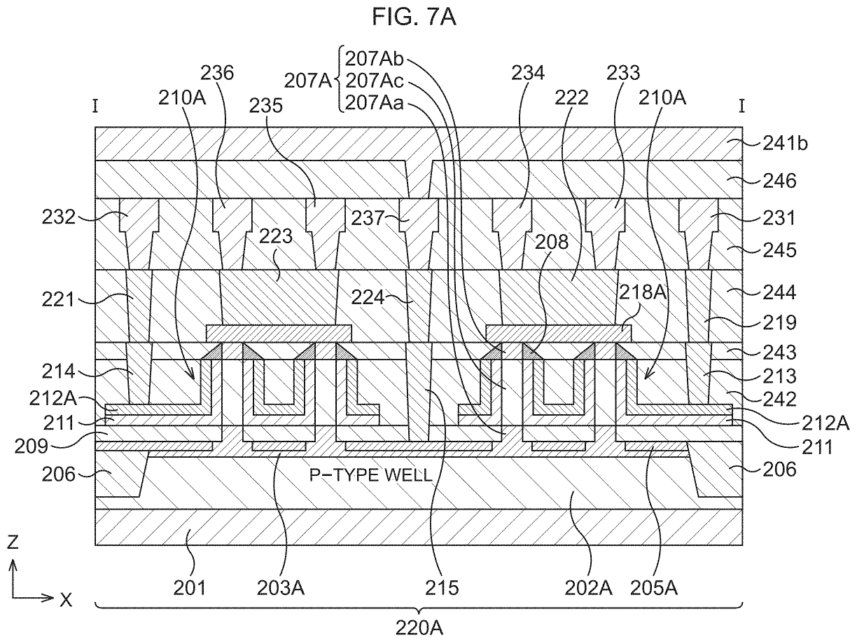

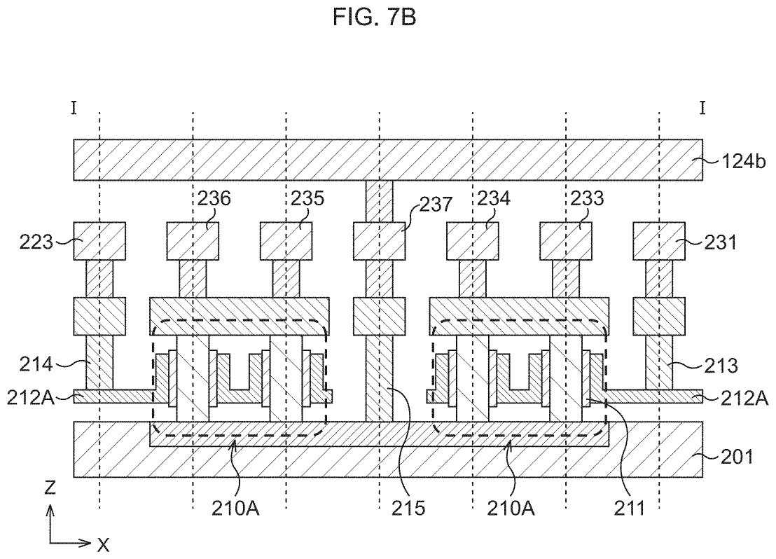

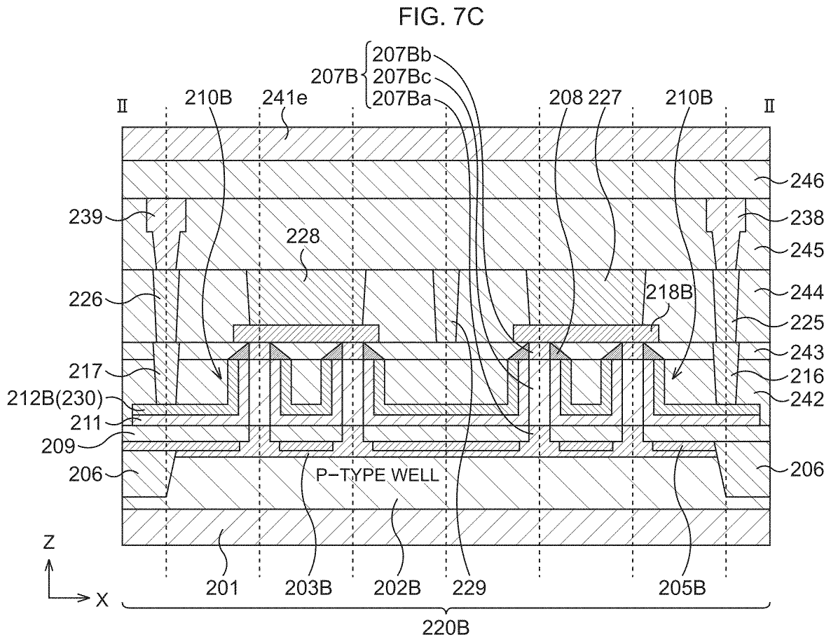

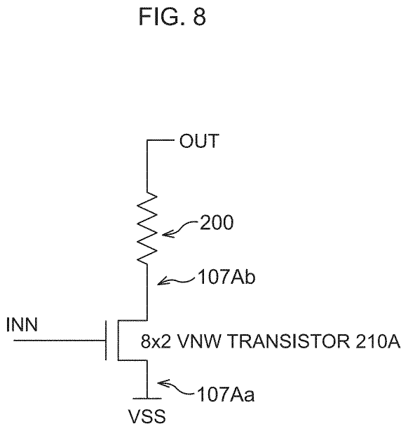

FIG. 6A is a plan view illustrating a schematic configuration of a semiconductor device according to a third embodiment. FIG. 6B is a plan view illustrating a schematic configuration of FIG. 6A excluding a configuration above VNW structures. FIG. 6C is a plan view illustrating a schematic configuration of local wirings and wirings thereon in a partial region in FIG. 6A. FIG. 7A is a cross-sectional view illustrating a cross section taken along I-I in FIG. 6A. FIG. 7B is a simple cross-sectional view corresponding to FIG. 7A. FIG. 7C is a cross-sectional view illustrating a cross section taken along II-II in FIG. 6A. FIG. 8 is an equivalent circuit diagram illustrating a connection state of the semiconductor device according to the third embodiment.

This semiconductor device includes a VNW transistor arrangement region 220A and a resistance element arrangement region 220B. In each of the VNW transistor arrangement region 220A and the resistance element arrangement region 220B, a plurality of VNW elements are arranged in a matrix, for example. A plurality of the VNW elements in the VNW transistor arrangement region 220A are VNW transistors 210A. A plurality of the VNW elements in the resistance element arrangement region 220B are VNW structures 210B to be a part of a resistance element 200. In this embodiment, the VNW transistors 210A in the VNW transistor arrangement region 220A and the VNW structures 210B in the resistance element arrangement region 220B are the same in the arrangement number and arrangement in a plane view. For example, in the VNW transistor arrangement region 220A, a first group 210A1 and a second group 210A2, each of which includes a total of 8 VNW transistors 210A, two in the X direction and four in the Y direction, are arranged side by side at predetermined intervals. Similarly, in the resistance element arrangement region 220B, a first group 210B1 and a second group 210B2, each of which includes a total of 8 VNW structures 210B, two in the X direction and four in the Y direction, are arranged side by side at predetermined intervals. Incidentally, the number and the arrangement form of VNW transistors 210A and VNW structures 210B are not limited to those in FIG. 6B, and the VNW transistors 210A and the VNW structures 210B are sometimes arranged in a number and an arrangement form different from those in FIG. 6B. Further, in place of the VNW transistors, VNW diodes may be used.

A substrate 201 is a substrate of a compound or an alloy of bulk Si, germanium (Ge), Si, or Ge, or a substrate of one kind selected from SiC, SiP, SiPC, GaAs, GaP, InP, InAs, In, Sb, SiGe, GaAcP, AlInAs, GaInAs, GaInP, and GaInAsP, a combination of these, or the like, for example. An SOI substrate can also be used.

The VNW transistor arrangement region 220A is demarcated by STI element isolation regions 206. The resistance element arrangement region 220B is demarcated by STI element isolation regions 206.

The STI element isolation region 206 is formed in a manner that an insulating material is filled in an opening formed in the substrate 201. The insulating material may be, for example, SiO, PSG (phosphorus silicate glass), BSG (boron silicate glass), BPSG (boron-phosphorus silicate glass), USG (undoped silicate glass), or a combination of these.

In the VNW transistor arrangement region 220A, a well 202A having a P-type conductivity, for example, is formed. In the resistance element arrangement region 220B, a well 202B having a P-type conductivity, for example, is formed.

The wells 202A, 202B are formed in a manner that a P-type impurity is ion-implanted into the substrate 201. As the P-type impurity, one kind or plural kinds selected from B, BF₂, In, and N are used.

An impurity region 203A having a conductivity type opposite to that of the well 202A, such as an N type, for example, is formed on the top of the well 202A. On the surface of the substrate 201, which is also the top of the impurity region 203A, a silicide layer 205A is formed.

An impurity region 203B having a conductivity type opposite to that of the well 202B, such as an N type, for example, is formed on the top of the well 202B. On the surface of the substrate 201, which is also the top of the impurity region 203B, a silicide layer 205B is formed.

The impurity regions 203A, 203B are formed in a manner that an N-type impurity is ion-implanted into the substrate 201. As the N-type impurity, one kind or plural kinds selected from As, P, Sb, and N are used.

The silicide layers 205A, 205B are formed in a manner that a metal film is formed on the surfaces of the impurity regions 203A, 203B and is subjected to a heat treatment to turn the surfaces of the impurity regions 203A, 203B into silicide. As a material of the metal film, for example, Ni, Co, Mo, W, Pt, Ti, or the like is used.

In the VNW transistor arrangement region 220A, on the substrate 201, a plurality of projecting semiconductor nanowires 207A are formed vertically to the surface of the substrate 201. The semiconductor nanowire 207A has a lower end portion 207Aa, an upper end portion 207Ab, and a middle portion 207Ac between the lower end portion 207Aa and the upper end portion 207Ab. The lower end portion 207Aa has an N-type conductivity and is electrically connected to the impurity region 203A. The upper end portion 207Ab has an N-type conductivity. The middle portion 207Ac has a P-type conductivity or is non-doped and serves as a channel region of the transistor. One of the lower end portion 207Aa and the upper end portion 207Ab is a source electrode and the other is a drain electrode. On a side surface of the upper end portion 207Ab, a sidewall 208 of an insulating film is formed. Incidentally, the lower end portion 207Aa and the upper end portion 207Ab may have a P type and the middle portion 207Ac may have an N type or may be non-doped.

In the resistance element arrangement region 220B, on the substrate 201, a plurality of projecting semiconductor nanowires 207B are formed vertically to the surface of the substrate 201. The semiconductor nanowire 207B has a lower end portion 207Ba, an upper end portion 207Bb, and a middle portion 207Bc between the lower end portion 207Ba and the upper end portion 207Bb. The lower end portion 207Ba has an N-type conductivity and is electrically connected to the impurity region 203B. The upper end portion 207Bb has an N-type conductivity. The middle portion 207Bc has an N-type conductivity or is non-doped. On a side surface of the upper end portion 207Bb, a sidewall 208 of an insulating film is formed. Incidentally, the lower end portion 207Ba and the upper end portion 207Bb may have a P type and the middle portion 207Bc may have a P type or may be non-doped.

In the case of the substrate 201 being a P-type semiconductor substrate, the formations of the P-type wells 202A, 202B may be omitted. A planar shape of the semiconductor nanowires 207A, 207B may be, for example, a circular shape, an elliptical shape, a quadrangular shape, or a shape extending in one direction. On the surfaces of the silicide layers 205A, 205B and the STI element isolation regions 206, an interlayer insulating film 209 that covers side surfaces of the lower end portions 207Aa of the semiconductor nanowires 207A is formed.

The semiconductor nanowire 207A is formed in a manner that an N-type impurity is ion-implanted into the lower end portion 207Aa and the upper end portion 207Ab, and a P-type impurity is ion-implanted into the middle portion 207Ac. The semiconductor nanowire 207B is formed in a manner that an N-type impurity is ion-implanted into the lower end portion 207Ba and the upper end portion 207Bb, and an N-type impurity is ion-implanted into the middle portion 207Bc so as to have an impurity concentration lower than the lower end portion 207Ba and the upper end portion 207Bb. As the P-type impurity, one kind or plural kinds selected from B, BF₂, In, and N are used. As the N-type impurity, one kind or plural kinds selected from As, P, Sb, and N are used.

The sidewall 208 is formed by using, as a material, an insulating material such as SiO₂, SiN, SiON, SiC, SiCN, or SiOCN.

The interlayer insulating film 209 is formed by using, as a material, an insulating material such as, for example, SiO₂, TEOS, PSG, BPSG, FSG, SiOC, SOG, SOP (Spin on Polymers), or SiC.

In the VNW transistor arrangement region 220A, a gate electrode 212A is formed on the side surface of the semiconductor nanowire 207A via a gate insulating film 211. The VNW transistor 210A includes the semiconductor nanowire 207A, the gate insulating film 211, and the gate electrode 212A. In this embodiment, the gate electrodes 212A, a part of which is formed on the side surface of each of a plurality of the semiconductor nanowires 207A, which are two, for example, aligned in the X direction, are formed as a single-layer conductive film as a whole.

In the resistance element arrangement region 220B, a conductive pattern 212B is formed on the side surface of the semiconductor nanowire 207B via the gate insulating film 211. The VNW structure 210B includes the semiconductor nanowire 207B, the gate insulating film 211, and the conductive pattern 212B. In this embodiment, the conductive patterns 212B, a part of which is formed on the side surface of each of a plurality of semiconductor nanowires 207B, which are four, for example, aligned in the X direction, are formed as a single-layer conductive film as a whole.

In this embodiment, in the resistance element 200, the conductive pattern 212B of the VNW structure 210B is formed by using the gate electrode 212A of the VNW transistor 210A. Concretely, the gate electrode 212A of the VNW transistor 210A and the conductive pattern 212B of the VNW structure 210B are formed by a single-layer conductor film being processed in the same step.

The gate insulating film 211 is formed by using, as a material, an insulating material having a dielectric constant k of 7 or more, for example, such as SiN, Ta₂O₅, Al₂O₃, or HfO₂, for example. The gate electrode 212A and the conductive pattern 212B are formed by using, as a material, TiN, TaN, TiAl, TaAl, Ti-containing metal, Al-containing metal, W-containing metal, TiSi, NiSi, PtSi, polycrystalline silicon having silicide, or the like.

In the VNW transistor arrangement region 220A, a plurality of contact plugs, for example, contact plugs 213, 214, and 215 are arranged. As illustrated in FIG. 6B and FIG. 7A, the contact plug 213 is electrically connected to one end of the gate electrode 212A on the right and the contact plug 214 is electrically connected to one end of the gate electrode 212A on the left. The contact plug 215 is electrically connected to the surface of the silicide layer 205A between the gate electrodes 212A adjacent along the X direction.

In the resistance element arrangement region 220B, a plurality of contact plugs, for example, contact plugs 216, 217 are arranged. As illustrated in FIG. 6B and FIG. 7C, the contact plug 216 is electrically connected to one end of each of the conductive patterns 212B and the contact plug 217 is electrically connected to the other end of each of the conductive patterns 212B.

The contact plugs 213 to 217 each are formed of a base film formed so as to cover an inner wall surface of each opening, and a conductive material that fills the inside of each of the openings through the base film. As a material of the base film, for example, Ti, TiN, Ta, TaN, or the like is used. As the conductive material, for example, Cu, a Cu alloy, W, Ag, Au, Ni, Al, Co, Ru, or the like is used. Incidentally, in the case where the conductive material is Co or Ru, the formation of the base film may be omitted.

A silicide layer 218A is formed on the VNW transistor 210A. In this embodiment, the silicide layer 218A is provided in common for each two VNW transistors 210A aligned along the X direction. The silicide layer 218A is electrically connected to the upper end portion 207Ab of the semiconductor nanowire 207A.

A silicide layer 218B is formed on the VNW structure 210B. In this embodiment, the silicide layer 218B is provided in common for each two VNW structures 210B aligned along the X direction. The silicide layer 218B is electrically connected to the upper end portion 207Bb of the semiconductor nanowire 207B.

The silicide layers 218A, 218B are formed in a manner that a semiconductor material and a metal film are formed on the VNW transistor 210A and the VNW structure 210B and are subjected to a heat treatment to turn the semiconductor material into silicide. As a material of the metal film, for example, Ni, Co, Mo, W, Pt, Ti, or the like is used.

In the VNW transistor arrangement region 220A, a plurality of local wirings, for example, local wirings 219, 221, 222, 223, and 224 are arranged. The local wiring 219 is electrically connected to a top surface of the contact plug 213. The local wiring 221 is electrically connected to a top surface of the contact plug 214. The local wiring 222 is electrically connected to a top surface of the silicide layer 218A on one side. The local wiring 223 is electrically connected to a top surface of the silicide layer 218A on the other side. The local wiring 224 is electrically connected to a top surface of the contact plug 215.

A plurality of local wirings, for example, local wirings 225, 226, 227, 228, and 229 are arranged on the VNW structures 210B. The local wiring 225 is electrically connected to a top surface of the contact plug 216. The local wiring 226 is electrically connected to a top surface of the contact plug 217. The local wiring 227 is electrically connected to a top surface of the silicide layer 218B on one side. The local wiring 228 is electrically connected to a top surface of the silicide layer 218B on the other side.

As illustrated in FIG. 6C, the local wirings 225 to 229 are arranged side by side along the X direction above the respective conductive patterns 212B. Between the local wirings 225 and 227, between the local wirings 227 and 229, between the local wirings 229 and 228, and between the local wirings 228 and 226 each are separated from each other. The local wirings 227, 228 are electrically separated from each other, and are not electrically connected to other conductors above. As a result, the respective semiconductor nanowires 207B are in a floating state electrically.

The local wirings 219, 221, 222, 223, 224, 225, 226, 227, 228, and 229 each are formed of a base film formed so as to cover an inner wall surface of each opening, and a conductive material that fills the inside of each of the openings through the base film. As a material of the base film, for example, Ti, TiN, Ta, TaN, or the like is used. As the conductive material, for example, Cu, a Cu alloy, W, Ag, Au, Ni, Al, Co, Ru, or the like is used. Incidentally, in the case where the conductive material is Co or Ru, the formation of the base film may be omitted.

In the VNW transistor arrangement region 220A, a plurality of wirings, for example, M1-layer wirings 231 to 237 are arranged. The respective M1-layer wirings are arranged on the respective local wirings. The wiring 231 extends in the Y direction and is electrically connected to top surfaces of a plurality of the local wirings 219, which are four here, aligned along the Y direction. The wiring 232 extends in the Y direction and is electrically connected to top surfaces of a plurality of the local wirings 221, which are four here, aligned along the Y direction. The wiring 233 extends in the Y direction and is electrically connected to one end of top surfaces of a plurality of the local wirings 222, which are four here, aligned along the Y direction. The wiring 234 extends in the Y direction and is electrically connected to the other end of the top surfaces of a plurality of the local wirings 222, which are four here, aligned along the Y direction. The wiring 235 is electrically connected to one end of top surfaces of a plurality of the local wirings 223, which are four here, aligned along the Y direction. The wiring 236 is electrically connected to the other end of the top surfaces of a plurality of the local wirings 223, which are four here, aligned along the Y direction. The wiring 237 is electrically connected to top surfaces of a plurality of the local wirings 224, which are four here, aligned along the Y direction.

In the resistance element arrangement region 220B, a plurality of wirings, for example, M1-layer wirings 238, 239 are arranged. The wiring 238 is electrically connected to a top surface of the local wiring 225. The wiring 239 is electrically connected to a top surface of the local wiring 226.

The arrangement of the wirings 238, 239 is explained while using FIG. 6B and FIG. 6C. The respective wirings 238 are aligned extending in the Y direction in a plane view so that each wiring 238 corresponds to the two adjacent conductive patterns 212B. The respective wirings 239 are aligned extending in the Y direction in a plane view so that each wiring 239 corresponds to the two adjacent conductive patterns 212B. The wirings 238, 239 are arranged to be displaced by one conductive pattern 212B from each other with respect to a plurality of the conductive patterns 212B aligned along the Y direction in a plane view. The wirings 238, 239 are arranged as above and are electrically connected to the respective conductive patterns 212B through the local wirings 225, 226 and the contact plugs 216, 217. The respective conductive patterns 212B extending in the X direction are electrically connected in a zigzag shape by the wirings 238, 239 extending in the Y direction. As above, a plurality of the conductive patterns 212B are arranged in a zigzag shape together with the wirings 238, 239 to form a single conductive pattern 230 practically that serves as an electrical resistance body of the resistance element 200. The conductive patterns 212B and the wirings 238, 239 are connected as above, thereby making it possible to fabricate the single conductive pattern 230 practically with excellent area efficiency.

The connection of the conductive patterns 212B forming the conductive pattern 230 is not limited to the wirings 238, 239 and the local wirings 235, 236, for example, may be used.

M2-layer wirings 241a, 241b, 241c, 241d, 241e, 241f, and 241g, which function as a power supply line Vss, for example, are arranged above the substrate 201. The wiring 241a is arranged side by side with the VNW transistor arrangement region 220A. The wirings 241b, 241c are arranged side by side with the VNW transistor arrangement region 220A. The wiring 241d is arranged between the VNW transistor arrangement region 220A and the resistance element arrangement region 220B. The wirings 241e, 241f are arranged side by side with the resistance element arrangement region 220B. The wiring 241g is arranged side by side with the resistance element arrangement region 220B. The wirings 241a, 241b, 241c, and 241d are electrically connected to each other. Between the wiring 241d and the wiring 241e, between the wiring 241e and the wiring 241f, and between the wiring 241f and the wiring 241g each are electrically connected to each other. As illustrated in FIG. 6A and FIG. 8, in the semiconductor device according to this embodiment, one end of the wiring 241g becomes an input terminal INN and one end of the wiring 241a becomes an output terminal OUT.

On the interlayer insulating film 209, interlayer insulating films 242 to 246 are formed in layers.

The VNW transistor 210A, the VNW structure 210B, and the contact plugs 213, 214, 216, and 217 are formed in the interlayer insulating films 242, 243. The silicide layers 218A, 218B and the local wirings 219, 221, 222, 223, 224, 225, 226, 227, 228, and 229 are formed in the interlayer insulating film 244. The wirings 213 to 239 are formed in the interlayer insulating film 245. The wirings 241a to 241g are formed in the interlayer insulating film 246.

The interlayer insulating films 242 to 246 are formed by using, as a material, an insulating material such as SiO₂, TEOS, PSG, BPSG, FSG, SiOC, SOG, SOP (Spin on Polymers), or SiC.

In this embodiment, the gate electrode 212A of the VNW transistor 210A and the conductive pattern 212B of the resistance element 210B are formed by a single-layer conductor film being processed. In the resistance element 200, the conductive pattern 212B is used as the electrical resistance body. In the VNW transistor 210A, as the gate electrode 212A, a thin conductor film is used. The thin conductor film has a high resistance value. This conductor film is applied to the conductive pattern 212B of the resistance element 200 as well as to the gate electrode 212A of the VNW transistor 210A. This makes it possible to reduce the manufacturing steps and obtain the conductive pattern 212B in the resistance element 200 together with the gate electrode 212A.

Further, in this embodiment, the semiconductor nanowires 207B are electrically in a floating state in the resistance element 200. As a result, by the conductive pattern 230 to be the electrical resistance body in the resistance element 200, the effect of parasitic resistance generated in the substrate 201 and the semiconductor nanowires 207B is suppressed.

Further, in this embodiment, in addition to the VNW transistors 210A in the VNW transistor arrangement region 220A, the VNW structures 210B are provided in the resistance element arrangement region 220B. The VNW structures 210B are provided, together with the VNW transistors 210A, thereby making it possible to ensure manufacturing uniformity. Further, in this embodiment, the arrangement number and the arrangement of the VNW transistors 210A and the VNW structures 210B are adjusted, and the VNW transistors 210A and the VNW structures 210B are the same in for example, the arrangement number and arrangement. This can suppress the dimensional variation caused by process variation during the formation of these VNW elements.

### Fourth Embodiment

In this embodiment, there is disclosed a semiconductor device with VNW structures provided in a resistance element, similarly to the second embodiment, but this embodiment is different from the second embodiment in that the VNW structure includes an electric capacity.

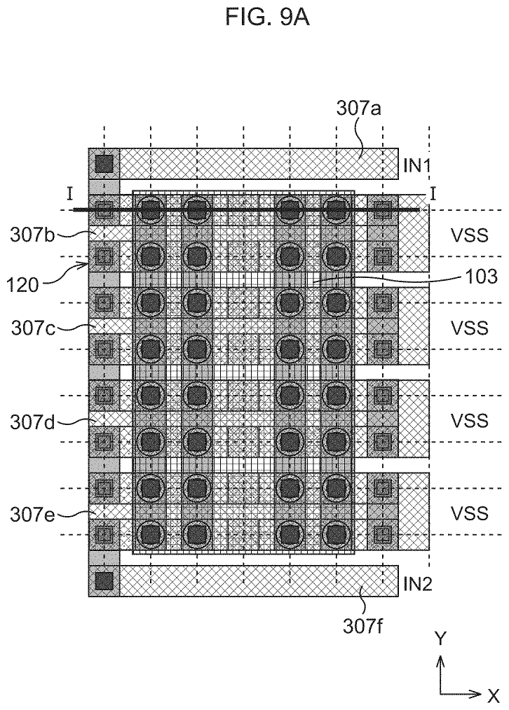

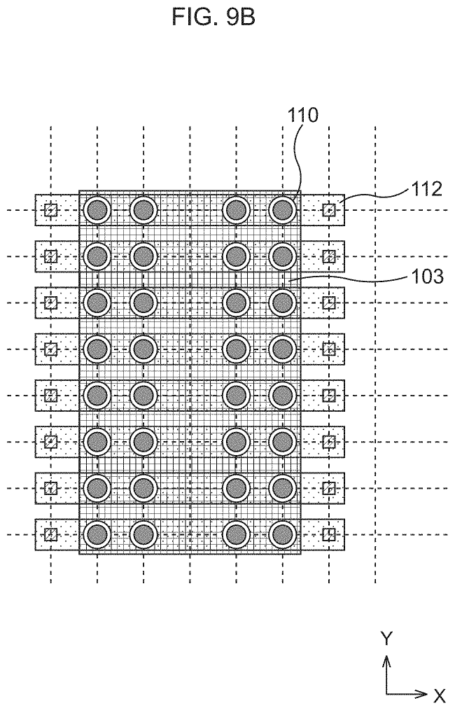

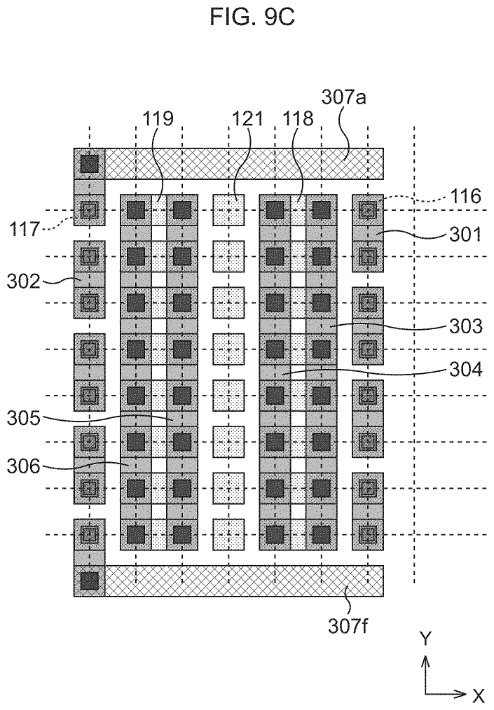

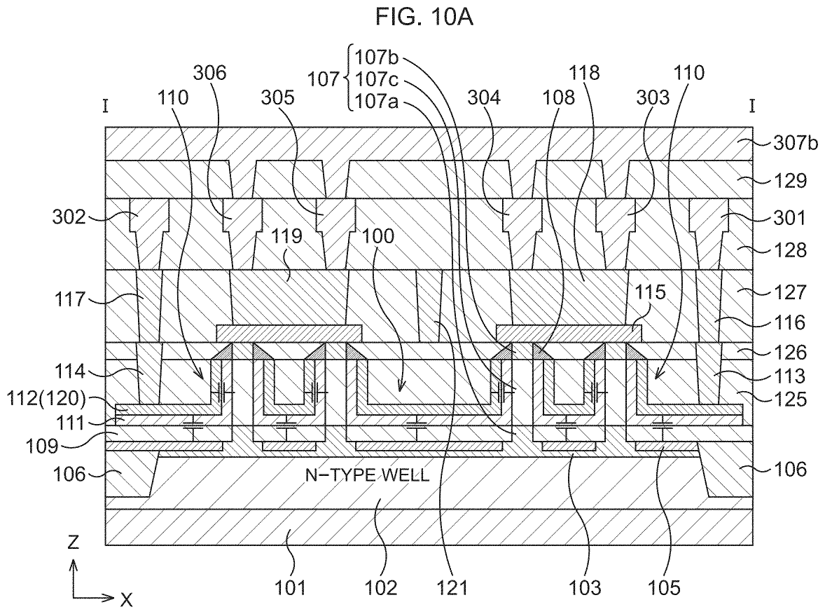

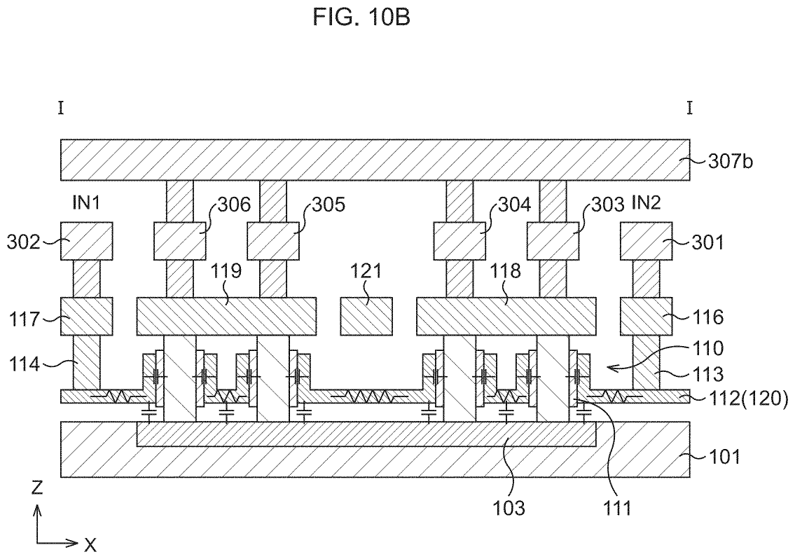

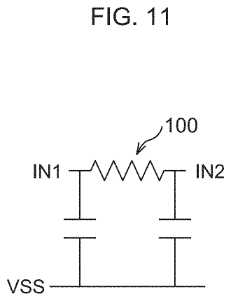

FIG. 9A is a plan view illustrating a schematic configuration of a semiconductor device according to a fourth embodiment. FIG. 9B is a plan view illustrating a schematic configuration of FIG. 9A excluding a configuration above VNW structures. FIG. 9C is a plan view illustrating a schematic configuration of local wirings and wirings thereon in a partial region in FIG. 9A. FIG. 10A is a cross-sectional view illustrating a cross section taken along I-I in FIG. 9A. FIG. 10B is a simple cross-sectional view corresponding to FIG. 10A. FIG. 11 is an equivalent circuit diagram illustrating how capacitive coupling is formed between a resistance element and a power supply line Vss. Incidentally, the same reference numerals and symbols are added to the same component members as those in the semiconductor device according to the second embodiment, and their detailed explanations are omitted.

In this semiconductor device, similarly to the second embodiment, the resistance element 100 including the VNW structures 110 grouped and arranged in a matrix in a plane view, for example, is provided. The VNW structure 110 includes the semiconductor nanowire 107 standing vertically from the surface of, for example, the P-type impurity region 103 formed in the substrate 101 and the gate electrode 112 via the gate insulating film 111 on the side surface of the semiconductor nanowire 107. In this embodiment, the lower end portion 107a, the upper end portion 107b, and the middle portion 107c of the semiconductor nanowire 107 all have the same conductivity type, for example, a P type. Incidentally, the impurity region 103, the lower end portion 107a, the upper end portion 107b, and the middle portion 107c all may have an N type. The middle portion 107c may have an impurity concentration lower than the lower end portion 107a and the upper end portion 107b.

In this embodiment, the configuration under the local wirings 116, 117, 118, 119, and 121 is the same as that in the second embodiment.

In the arrangement region of the resistance element 100, a plurality of wirings, for example, M1-layer wirings 301 to 306 are arranged. The respective M1-layer wirings are arranged on the respective local wirings. The wiring 301 is electrically connected to a top surface of the local wiring 116. The wiring 302 is electrically connected to a top surface of the local wiring 117. The respective wirings 301 are aligned extending in the Y direction in a plane view so that each wiring 301 corresponds to the two adjacent gate electrodes 112. The respective wirings 302 are aligned extending in the Y direction in a plane view so that each wiring 302 corresponds to the two adjacent gate electrodes 112. The wirings 301, 302 are arranged to be displaced by one gate electrode 112 from each other with respect to a plurality of the gate electrodes 112 aligned along the Y direction in a plane view. The wirings 301, 302 are arranged as above and are electrically connected to the respective gate electrodes 112 through the local wirings 116, 117 and the contact plugs 113, 114. The respective gate electrodes 112 extending in the X direction are electrically connected in a zigzag shape by the wirings 301, 302 extending in the Y direction. As above, a plurality of the gate electrodes 112 are arranged in a zigzag shape together with the wirings 301, 302 to form the single conductive pattern 120 practically that serves as the electrical resistance body of the resistance element 100.

The wiring 301 extends in the Y direction and is electrically connected to top surfaces of a plurality of the local wirings 118, which are eight here, aligned along the Y direction. The wiring 304 extends in the Y direction and is electrically connected to the top surfaces of a plurality of the local wirings 118, which are eight here, aligned along the Y direction. The wiring 305 extends in the Y direction and is electrically connected to top surfaces of a plurality of the local wirings 119, which are eight here, aligned along the Y direction. The wiring 306 extends in the Y direction and is electrically connected to the top surfaces of a plurality of the local wirings 119, which are eight here, aligned along the Y direction.

In the arrangement region of the resistance element 100, M2-layer wirings 307a, 307b, 307c, 307d, 307e, and 307f, which function as a power supply line Vss, for example, are arranged. As illustrated in FIG. 9A, between the wiring 307a and the wiring 307b, between the wiring 307b and the wiring 307c, between the wiring 307c and wiring 307d, between the wiring 307d and the wiring 307e, and between the wiring 307e and the wiring 307f each are electrically connected to each other. One end of the wiring 307a becomes one terminal IN1 of the conductive pattern 120. One end of the wiring 307f becomes the other terminal IN2 of the conductive pattern 120. Under the wiring 307b, the wiring 307b is electrically connected to the wirings 303, 304, 305, and 306. Under the wiring 307c, the wiring 307c is electrically connected to the wirings 303, 304, 305, and 306. Under the wiring 307d, the wiring 307d is electrically connected to the wirings 303, 304, 305, and 306. Under the wiring 307e, the wiring 307e is electrically connected to the wirings 303, 304, 305, and 306.

Incidentally, the wirings 303 to 306 may be connected to wirings that function as a power supply line Vdd in place of to the wirings 307b to 307e that function as the power supply line Vss.

The wirings 301 to 306 and 307a to 307f each have a dual damascene structure with a wiring portion being an upper portion and a via portion being a lower portion formed integrally. The via portion is in contact with the local wiring. The wirings 301 to 306 and 307a to 307f are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In this embodiment, the conductive pattern 120 using the gate electrodes 112 of the VNW structures 110 is used as the electrical resistance body of the resistance element 100. In the VNW structure 110, the thin gate electrode 112 is used. The thin gate electrode 112 has a high resistance value. This gate electrode 112 is applied to the conductive pattern 120 of the resistance element 100. This makes it possible to obtain the conductive pattern 120 in the resistance element 100.

Further, in this embodiment, as illustrated in FIG. 10A and FIG. 10B, the wirings 307a to 307e, which function as the power supply line Vss, are electrically connected to the well 103 in the substrate 101 via the semiconductor nanowires 107 and the like of the VNW structures 110. The gate insulating film 111 is interposed between the gate electrode 112 and the semiconductor nanowire 107. The gate insulating film 111 becomes a capacitive insulating film, and as illustrated in FIG. 11, capacitive coupling is formed between the gate electrode 112 and the semiconductor nanowire 107. Between the gate electrode 112 and the silicide layer 105, the gate insulating film 111 and the interlayer insulating film 109 are interposed. The gate insulating film 111 and the interlayer insulating film 109 become a capacitive insulating film, and as illustrated in FIG. 11, capacitive coupling is formed between the gate electrode 112 (power supply line Vss) and the silicide layer 105 (well 103). In this embodiment, with the well 103 and the VNW structure 110, it is possible to obtain a predetermined electrical resistance and electric capacity with excellent area efficiency in the same region in a plane view. Incidentally, the presence of the silicide layer 105 can lower the resistance value on the power supply line Vss side of the above-described capacitive couplings.

### Fifth Embodiment

In this embodiment, there is disclosed a semiconductor device with VNW structures provided and a plurality of VNW transistors provided in a resistance element, similarly to the third embodiment, but this embodiment is different from the third embodiment in that the VNW structure includes an electric capacity.

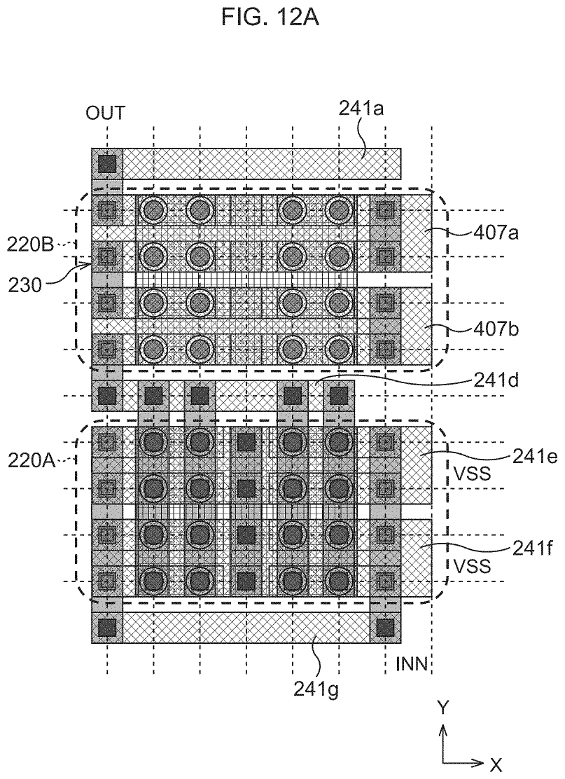

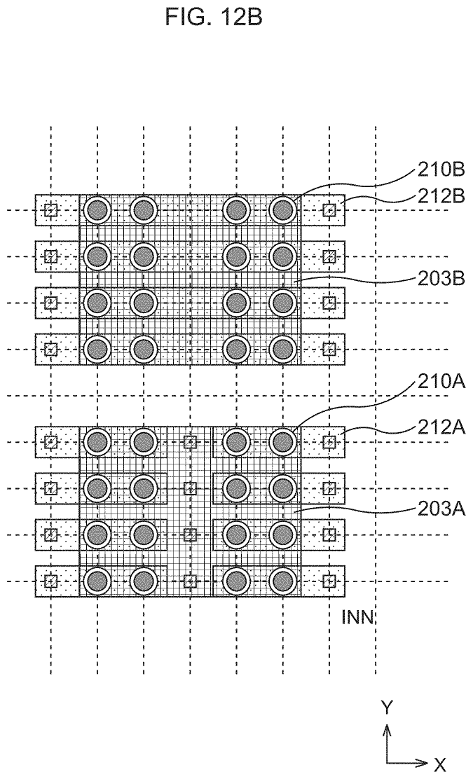

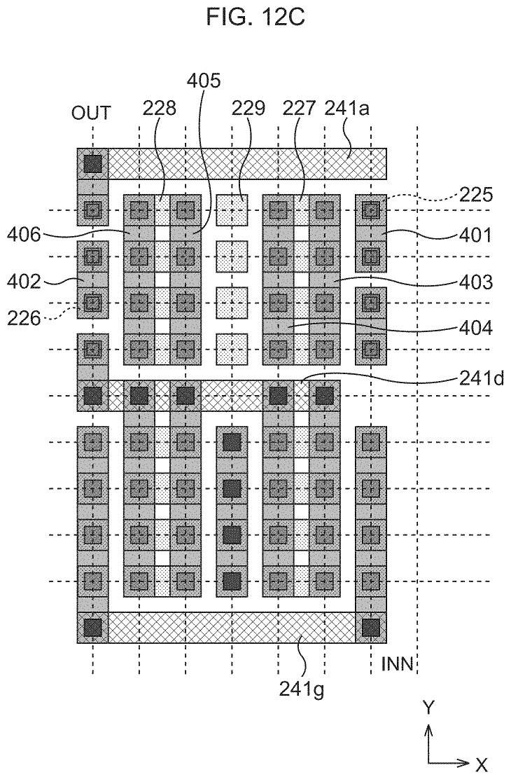

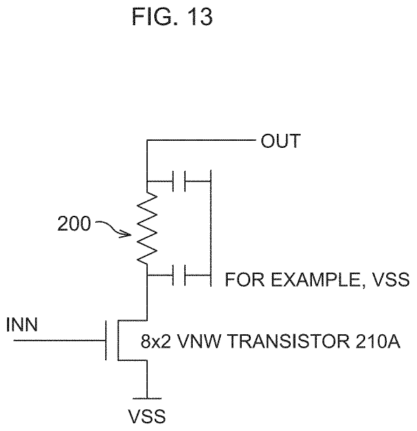

FIG. 12A is a plan view illustrating a schematic configuration of a semiconductor device according to a fifth embodiment. FIG. 12B is a plan view illustrating a schematic configuration of FIG. 12A excluding a configuration above VNW structures. FIG. 12C is a plan view illustrating a schematic configuration of local wirings and wirings thereon in a partial region in FIG. 12A. FIG. 13 is an equivalent circuit diagram illustrating a connection state of the semiconductor device according to the fifth embodiment. Incidentally, the same reference numerals and symbols are added to the same component members as those in the semiconductor device according to the third embodiment, and their detailed explanations are omitted.

In this semiconductor device, in the VNW transistor arrangement region 220A, a plurality of the VNW transistors 210A are arranged in a matrix, and in the resistance element arrangement region 220B, a plurality of the VNW structures 210B are arranged in a matrix. The components in the VNW transistor arrangement region 220A are the same as those in the third embodiment.

In the resistance element arrangement region 220B, similarly to the third embodiment, the VNW structure 210B includes the semiconductor nanowire 207B standing vertically from the surface of the substrate 201 and the conductive pattern 212B via the gate insulating film 211 on the side surface of the semiconductor nanowire 207B. In this embodiment, the lower end portion 207Ba, the upper end portion 207Bb, and the middle portion 207Bc of the semiconductor nanowire 207B all have the same conductivity type, for example, a P type. Incidentally, the lower end portion 207Ba, the upper end portion 207Bb, and the middle portion 207Bc all may have an N type. The middle portion 207Bc may have an impurity concentration lower than the lower end portion 207Ba and the upper end portion 207Bb.

In this embodiment, in the resistance element arrangement region 220B, the configuration under the local wirings 225, 226, 227, 228, and 229 is the same as that in the third embodiment.

In the resistance element arrangement region 220B, a plurality of wirings, for example, M1-layer wirings 401 to 406 are arranged. The respective M1-layer wirings are arranged on the respective local wirings. The wiring 401 is electrically connected to a top surface of the local wiring 225. The wiring 402 is electrically connected to a top surface of the local wiring 226. The respective wirings 401 are aligned extending in the Y direction in a plane view so that each wiring 401 corresponds to the two adjacent conductive patterns 212B. The respective wirings 402 are aligned extending in the Y direction in a plane view so that each wiring 402 corresponds to the two adjacent conductive patterns 212B. The wirings 401, 402 are arranged to be displaced by one conductive pattern 212B from each other with respect to a plurality of the conductive patterns 212B aligned along the Y direction in a plane view. The wirings 401, 402 are arranged as above and are electrically connected to the respective conductive patterns 212B through the local wirings 225, 226 and the contact plugs 216, 217. The respective conductive patterns 212B extending in the X direction are electrically connected in a zigzag shape by the wirings 401, 402 extending in the Y direction. As above, a plurality of the conductive patterns 212B are arranged in a zigzag shape together with the wirings 401, 402 to form the single conductive pattern 230 practically that serves as an electrical resistance body of the resistance element 200.

The wiring 403 extends in the Y direction and is electrically connected to top surfaces of a plurality of the local wirings 227, which are four here, aligned along the Y direction. The wiring 404 extends in the Y direction and is electrically connected to the top surfaces of a plurality of the local wirings 227, which are four here, aligned along the Y direction. The wiring 405 extends in the Y direction and is electrically connected to top surfaces of a plurality of the local wirings 228, which are eight here, aligned along the Y direction. The wiring 406 extends in the Y direction and is electrically connected to the top surfaces of a plurality of the local wirings 228, which are eight here, aligned along the Y direction.

In the resistance element arrangement region 220B, the M2-layer wirings 241a, 407a, 407b, 241d, 241e, 241f, and 241g, which function as a power supply line Vss, for example, are arranged. The respective M2-layer wirings are arranged above the respective M1-layer wirings. As illustrated in FIG. 12A, between the wiring 241a and the wiring 407a, between the wiring 407a and the wiring 407b, between the wiring 407b and the wiring 241d, between the wiring 241d and the wiring 241e, between the wiring 241e and the wiring 241f, and between the 241f and the wiring 241g each are electrically connected to each other. One end of the wiring 241a becomes one terminal IN1 of the conductive pattern 230. As illustrated in FIG. 12A and FIG. 13, in the semiconductor device according to this embodiment, one end of the wiring 241g becomes the input terminal INN and one end of the wiring 241a becomes the output terminal OUT.

Under the wiring 407a, the wiring 407a is electrically connected to the wirings 403, 404, 405, and 406. Under the wiring 407b, the wiring 407b is electrically connected to the wirings 403, 404, 405, and 406.

Incidentally, the wirings 403 to 406 may be connected to wirings that function as a power supply line Vdd in place of to the wirings 407a, 407b that function as the power supply line Vss.

The wirings 407a, 407b each have a dual damascene structure with a wiring portion being an upper portion and a via portion being a lower portion formed integrally. The via portion is in contact with the local wiring. The wirings 407a, 407b are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In this embodiment, the gate electrode 212A of the VNW transistor 210A and the conductive pattern 212B of the resistance element 210B are formed by a single-layer conductor film being processed. In the resistance element 200, the conductive pattern 212B is used as the electrical resistance body. In the VNW transistor 210A, as the gate electrode 212A, a thin conductor film is used. The thin conductor film has a high resistance value. This conductor film is applied to the conductive pattern 212B of the resistance element 200 as well as to the gate electrode 212A of the VNW transistor 210A. This makes it possible to reduce the manufacturing steps and obtain the conductive pattern 212B in the resistance element 200 together with the gate electrode 212A.

Further, in this embodiment, in the resistance element arrangement region 220B, the wirings 407a, 407b, which function as the power supply line Vss, are electrically connected to the well 202B in the substrate 201 via the semiconductor nanowires 207B and the like of the VNW structures 2108. The gate insulating film 211 is interposed between the conductive pattern 212B and the semiconductor nanowire 207B. The gate insulating film 211 becomes a capacitive insulating film, and as illustrated in FIG. 13, a capacity element is formed between the conductive pattern 212B and the semiconductor nanowire 207B. Between the conductive pattern 212B and the silicide layer 205B, the gate insulating film 211 and the interlayer insulating film 209 are interposed. The gate insulating film 211 and the interlayer insulating film 209 become a capacitive insulating film, and as illustrated in FIG. 13, a capacity element is formed between the conductive pattern 212B (power supply line Vss) and the silicide layer 205 (well 202B). Incidentally, the presence of the silicide layer 205B can lower the resistance value on the power supply line Vss side of the above-described capacity elements.

### Sixth Embodiment

In this embodiment, there is disclosed a semiconductor device with VNW structures provided and a plurality of VNW transistors provided in a resistance element, similarly to the third embodiment. In the semiconductor device according to this embodiment, the resistance element is an input protective resistance of the VNW transistors.

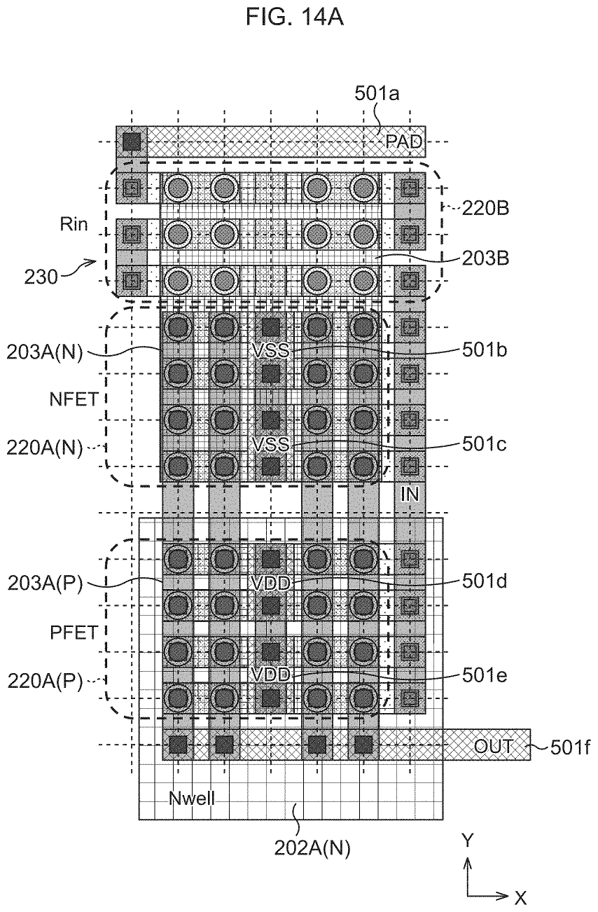

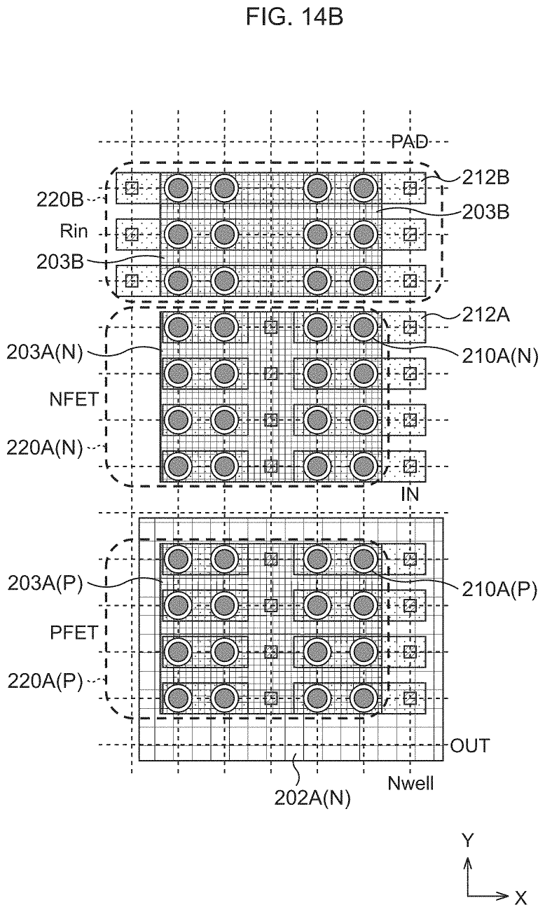

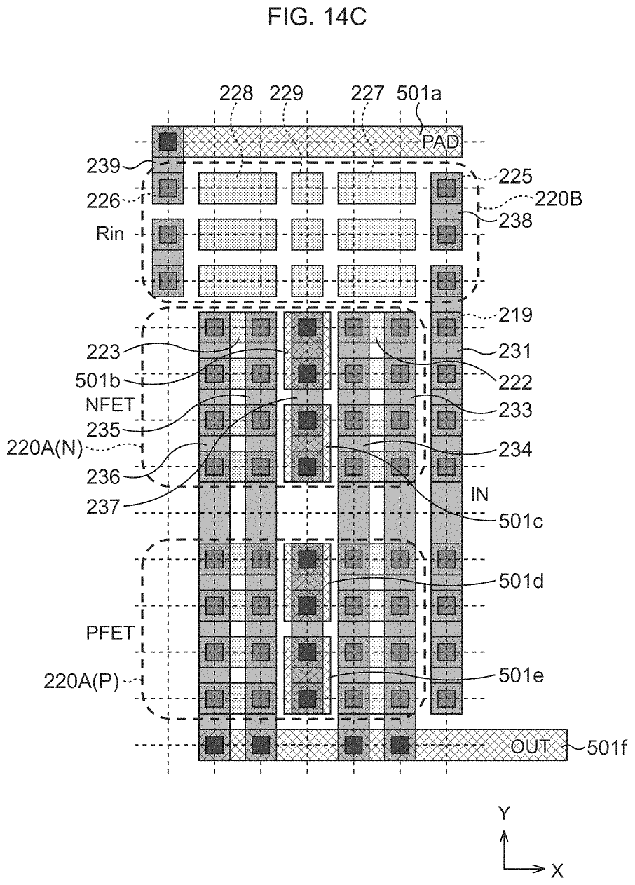

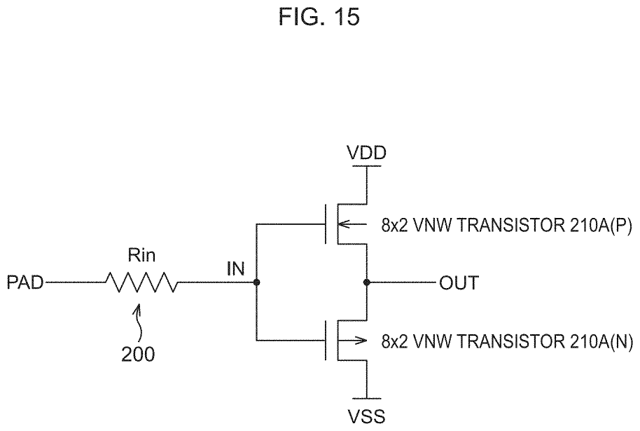

FIG. 14A is a plan view illustrating a schematic configuration of a semiconductor device according to a sixth embodiment. FIG. 14B is a plan view illustrating a schematic configuration of FIG. 14A excluding a configuration above VNW structures. FIG. 14C is a plan view illustrating a schematic configuration of local wirings and wirings thereon in a partial region in FIG. 14A. FIG. 15 is an equivalent circuit diagram illustrating a connection state of the semiconductor device according to the sixth embodiment. Incidentally, the same reference numerals and symbols are added to the same component members as those in the semiconductor device according to the third embodiment, and their detailed explanations are omitted.

In this semiconductor device, a P-type VNW transistor arrangement region 220A(P), an N-type VNW transistor arrangement region 220A(N), and a resistance element arrangement region 220B are provided side by side. In the P-type VNW transistor arrangement region 220A(P), a plurality of P-type VNW transistors 210A(P) are arranged in a matrix, in the N-type VNW transistor arrangement region 220A(N), a plurality of N-type VNW transistors 210A(N) are arranged in a matrix, and in the resistance element arrangement region 220B, a plurality of VNW structures 210B are arranged in a matrix. The P-type VNW transistors 210A(P) and the N-type VNW transistor arrangement region 220A(N) are electrically connected to form an inverter circuit.

Similarly to the third embodiment, in the P-type VNW transistor arrangement region 220A(P), on the substrate 201, a plurality of projecting semiconductor nanowires 207A(P) are formed vertically to an impurity region 203A(P). The impurity region 203A(P) is formed above an N-type well 202A(N) in the substrate 201. The semiconductor nanowire 207A(P) has a lower end portion 207Aa, an upper end portion 207Ab, and a middle portion 207Ac between the lower end portion 207Aa and the upper end portion 207Ab. The lower end portion 207Aa has a P-type conductivity and is electrically connected to the impurity region 203A(P). The upper end portion 207Ab has a P-type conductivity. The middle portion 207Ac has an N-type conductivity or is non-doped and serves as a channel region of the transistor. One of the lower end portion 207Aa and the upper end portion 207Ab is a source electrode and the other is a drain electrode.

Similarly to the third embodiment, in the N-type VNW transistor arrangement region 220A(N), on the substrate 201, a plurality of projecting semiconductor nanowires 207A(N) are formed vertically to an N-type impurity region 203A(N). The semiconductor nanowire 207A(N) has a lower end portion 207Aa, an upper end portion 207Ab, and a middle portion 207Ac between the lower end portion 207Aa and the upper end portion 207Ab. The lower end portion 207Aa has an N-type conductivity and is electrically connected to the impurity region 203A(N). The upper end portion 207Ab has an N-type conductivity. The middle portion 207Ac has a P-type conductivity or is non-doped and serves as a channel region of the transistor. One of the lower end portion 207Aa and the upper end portion 207Ab is a source electrode and the other is a drain electrode.

Similarly to the third embodiment, in the resistance element arrangement region 220B, on the substrate 201, a plurality of projecting semiconductor nanowires 207B are formed vertically to an N-type impurity region 203B. Of the semiconductor nanowire 207B, a lower end portion 207Ba, an upper end portion 207Bb, and a middle portion 207Bc all have the same conductivity type, which is a P type, for example. Incidentally, the lower end portion 207Ba, the upper end portion 207Bb, and the middle portion 207Bc all may have an N type. The middle portion 207Bc may have an impurity concentration lower than the lower end portion 207Ba and the upper end portion 207Bb.

In each of the P-type VNW transistor arrangement region 220A(P) and the N-type VNW transistor arrangement region 220A(N), a gate electrode 212A is formed on a side surface of the semiconductor nanowire 207A via a gate insulating film 211. In this embodiment, the gate electrodes 212A on a plurality of the semiconductor nanowires 207A, which are two, for example, aligned in the X direction are formed as a single-layer conductive film as a whole.

In the resistance element arrangement region 220B, a conductive pattern 212B is formed on a side surface of the semiconductor nanowire 207B via the gate insulating film 211. In this embodiment, the conductive patterns 212B on a plurality of the semiconductor nanowires 207B, which are four, for example, aligned in the X direction are formed as a single-layer conductive film as a while.

In this embodiment, in the resistance element 200, the conductive pattern 212B of the VNW structure 210B is formed by using the P-type VNW transistor 210A(P) and the gate electrode 212A in the N-type VNW transistor arrangement region 220A(N). Concretely, the P-type VNW transistor 210A(P), the gate electrode 212A of the N-type VNW transistor 210A(N), and the conductive pattern 212B of the VNW structure 210B are formed by a single-layer conductor film being processed in the same step.

A wiring 231 is electrically connected to a plurality of local wirings 219 in the P-type VNW transistor arrangement region 220A(P), a plurality of local wirings 219 in the N-type VNW transistor arrangement region 220A(N), and a local wiring 225 at one end of the resistance element arrangement region 220B. Wirings 233, 234 are electrically connected to a plurality of local wirings 222 in the P-type VNW transistor arrangement region 220A(P) and a plurality of local wirings 222 in the N-type VNW transistor arrangement region 220A(N). Wirings 235, 236 are electrically connected to a plurality of local wirings 223 in the P-type VNW transistor arrangement region 220A(P) and a plurality of local wirings 223 in the N-type VNW transistor arrangement region 220A(N). A wiring 237 is electrically connected to a plurality of local wirings 224 in each of the P-type VNW transistor arrangement region 220A(P) and the N-type VNW transistor arrangement region 220A(N).

In the resistance element arrangement region 220B, a wiring 238 is electrically connected to a top surface of the local wiring 225. A wiring 239 is electrically connected to a top surface of a local wiring 226. The respective wirings 238 are aligned extending in the Y direction in a plane view so that each wiring 238 corresponds to the two adjacent conductive patterns 212B. The respective wirings 239 are aligned extending in the Y direction in a plane view so that each wiring 239 corresponds to the two adjacent conductive patterns 212B. The wirings 238, 239 are arranged to be displaced by one conductive pattern 212B from each other with respect to a plurality of the conductive patterns 212B aligned along the Y direction in a plane view. The wirings 238, 239 are arranged as above and are electrically connected to the respective conductive patterns 212B through the local wirings 225, 226 and contact plugs 216, 217. The conductive patterns 212B extending in the X direction are electrically connected in a zigzag shape by the wirings 238, 239 extending in the Y direction. As above, a plurality of the conductive patterns 212B are arranged in a zigzag shape together with the wirings 238, 239 to form the single conductive pattern 230 practically that serves as an electrical resistance body of the resistance element 200.

Above the respective M1-layer wirings, for example, M2-layer wirings 501a, 501b, 501c, 501d, 501e, and 501f are arranged. The wiring 501a is to be electrically connected to a pad of an external connection terminal or the like, and is electrically connected to one end of the wiring 239 in the resistance element arrangement region 220B. The wirings 501b, 501c are to function as a power supply line Vss, and are electrically connected to the wiring 237 in the N-type VNW transistor arrangement region 220A(N). The wirings 501d, 501e are to function as a power supply line Vdd, and are electrically connected to the wiring 237 in the P-type VNW transistor arrangement region 220A(P). The wiring 501f is to function as an output terminal, and is electrically connected to the wirings 233, 234, 235, and 236 in the P-type VNW transistor arrangement region 220A(P).

The wirings 501a to 501f each have a dual damascene structure with a wiring portion being an upper portion and a via portion being a lower portion formed integrally. The via portion is in contact with the local wiring. The wirings 501a to 501f are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In the semiconductor device in this embodiment, as illustrated in FIG. 15, the resistance element 200, which is to be Rin, is electrically connected to the respective gate electrodes 212A that are to be input portions of the P-type VNW transistor 210A(P) and the N-type VNW transistor 210A(N) of the inverter circuit. Connecting Rin between the pad and inverter circuit suppresses the destruction of the inverter circuit when an ESD (Electro Static Discharge) current is generated in the pad.

In this embodiment, the gate electrodes 212A of the P-type VNW transistor 210A(P) and the N-type VNW transistor 210A(N) and the conductive pattern 212B of the resistance element 210B are formed by a single-layer conductor film being processed. In the resistance element 200, the conductive pattern 212B is used as the electrical resistance body. In the P-type VNW transistor 210A(P) and the N-type VNW transistor 210A(N), as the gate electrode 212A, a thin conductor film is used. The thin conductor film has a high resistance value. This conductor film is applied to the conductive patterns 212B of the resistance element 200 as well as to the gate electrodes 212A of the P-type VNW transistor 210A(P) and the N-type VNW transistor 210A(N). This makes it possible to reduce the manufacturing steps and obtain the conductive patterns 212B in the resistance element 200 together with the gate electrodes 212A.

### Modified Example

Hereinafter, there will be explained various modified examples of the semiconductor device in the sixth embodiment.

### Modified Example 1

In this example, there is disclosed a semiconductor device in which a resistance element is an input protective resistance of VNW transistors, but this example is different in a connection aspect of the resistance element from the sixth embodiment.

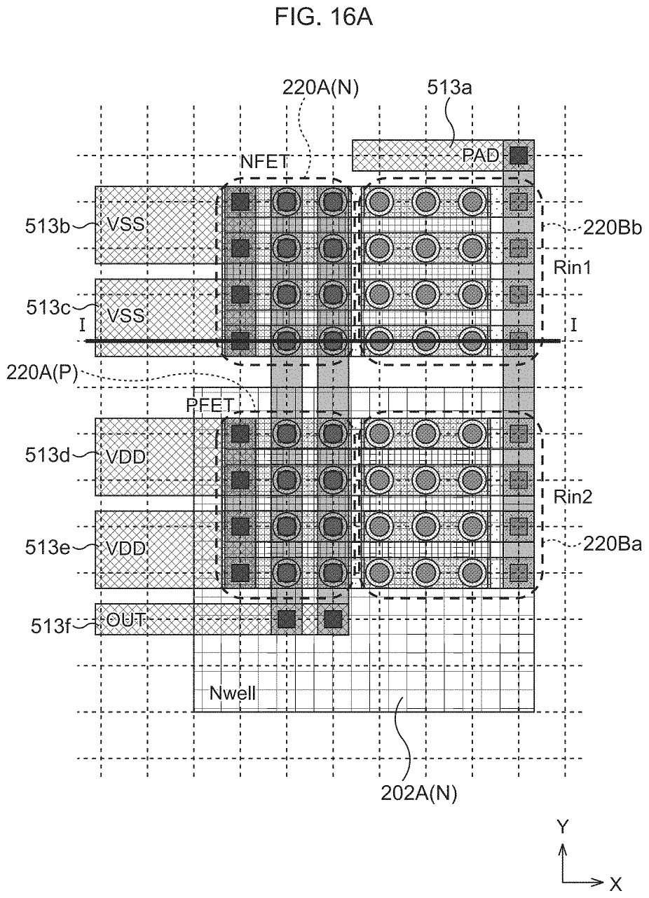

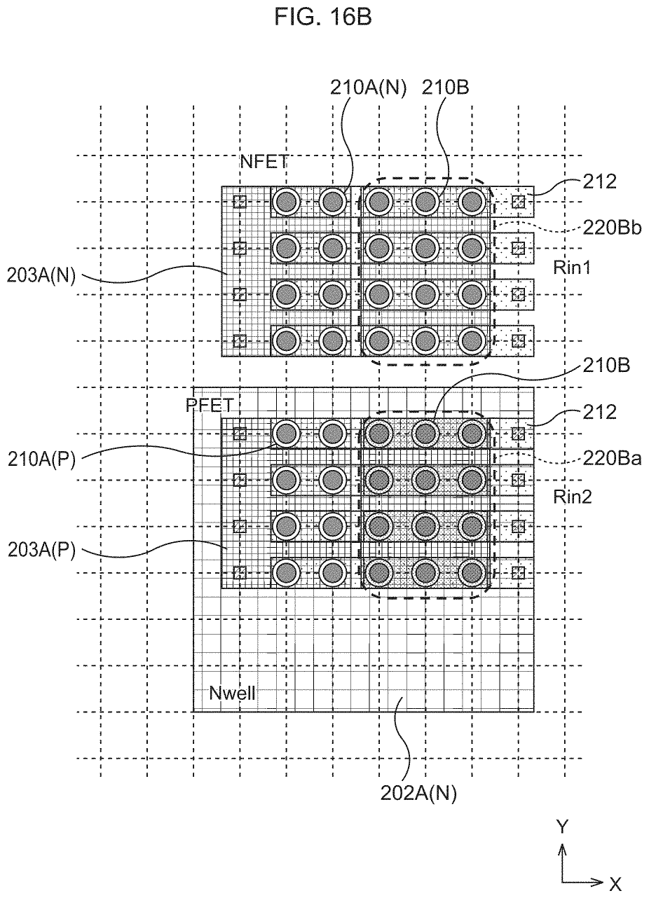

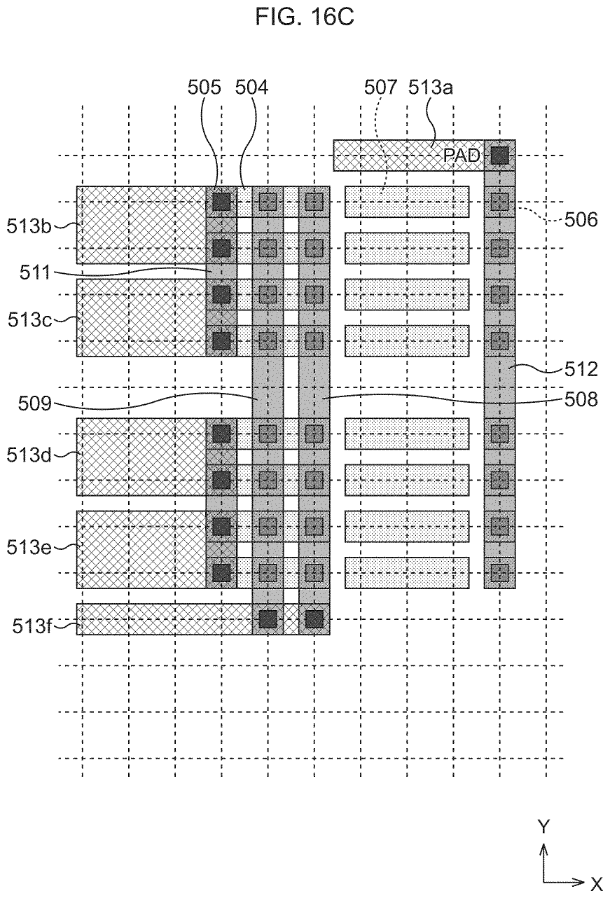

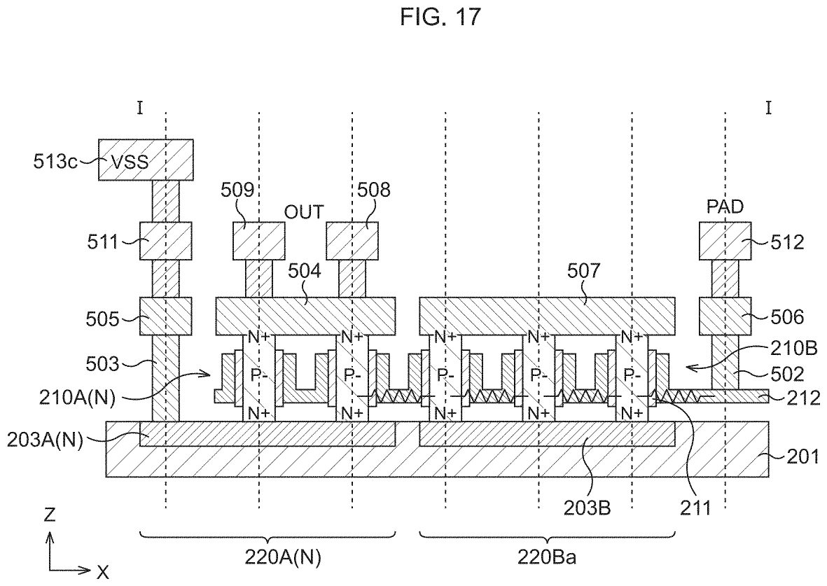

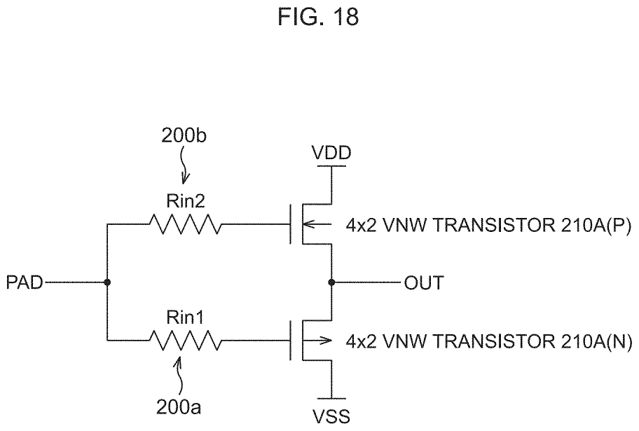

FIG. 16A is a plan view illustrating a schematic configuration of a semiconductor device according to a modified example 1 of the sixth embodiment. FIG. 16B is a plan view illustrating a schematic configuration of FIG. 16A excluding a configuration above VNW elements. FIG. 16C is a plan view illustrating a schematic configuration of local wirings and wirings thereon in a partial region in FIG. 16A. FIG. 17 is a simple cross-sectional view illustrating a cross section taken along I-I in FIG. 16A. FIG. 18 is an equivalent circuit diagram of the semiconductor device according to the modified example 1 in the sixth embodiment. Incidentally, the same reference numerals and symbols are added to the same component members as those in the semiconductor device according to the third embodiment, and their detailed explanations are omitted.

In this semiconductor device, the P-type VNW transistor arrangement region 220A(P), the N-type VNW transistor arrangement region 220A(N), a resistance element arrangement region 220Ba, and a resistance element arrangement region 220Bb are provided. In the P-type VNW transistor arrangement region 220A(P), a plurality of the P-type VNW transistors 210A(P) are arranged in a matrix, in the N-type VNW transistor arrangement region 220A(N), a plurality of the N-type VNW transistors 210A(N) are arranged in a matrix, in the resistance element arrangement region 220Ba, a plurality of the VNW structures 210B are arranged in a matrix, and in the resistance element arrangement region 220Bb, a plurality of the VNW structures 210B are arranged in a matrix. The P-type VNW transistors 210A(P) and the N-type VNW transistor arrangement region 220A(N) are electrically connected to form an inverter circuit.

In the P-type VNW transistor arrangement region 220A(P), on the substrate 201, a plurality of the projecting semiconductor nanowires 207A(P) are formed vertically to the impurity region 203A(P). The impurity region 203A(P) is formed on the N-type well 202A(N) in the substrate 201. The semiconductor nanowire 207A(P) has a lower end portion 207Aa, an upper end portion 207Ab, and a middle portion 207Ac between the lower end portion 207Aa and the upper end portion 207Ab. The lower end portion 207Aa has a P-type conductivity and is electrically connected to the impurity region 203A(P). The upper end portion 207Ab has a P-type conductivity. The middle portion 207Ac has an N-type conductivity or is non-doped and serves as a channel region of the transistor. One of the lower end portion 207Aa and the upper end portion 207Ab is a source electrode and the other is a drain electrode.

Similarly to the sixth embodiment, in the N-type VNW transistor arrangement region 220A(N), on the substrate 201, a plurality of the projecting semiconductor nanowires 207A(N) are formed vertically to the N-type impurity region 203A(N). The semiconductor nanowire 207A(N) has a lower end portion 207Aa, an upper end portion 207Ab, and a middle portion 207Ac between the lower end portion 207Aa and the upper end portion 207Ab. The lower end portion 207Aa has an N-type conductivity and is electrically connected to the impurity region 203A(N). The upper end portion 207Ab has an N-type conductivity. The middle portion 207Ac has a P-type conductivity or is non-doped and serves as a channel region of the transistor. One of the lower end portion 207Aa and the upper end portion 207Ab is a source electrode and the other is a drain electrode.

In the resistance element arrangement regions 220Ba, 220Bb, on the substrate 201, a plurality of the projecting semiconductor nanowires 207B are formed vertically to the N-type impurity region 203B. Of the semiconductor nanowire 207B, a lower end portion 207Ba, an upper end portion 207Bb, and a middle portion 207Bc all have the same conductivity type, which is a P type, for example. Incidentally, the lower end portion 207Ba, the upper end portion 207Bb, and the middle portion 207Bc all may have an N type. The middle portion 207Bc may have an impurity concentration lower than the lower end portion 207Ba and the upper end portion 207Bb.

In the P-type VNW transistor arrangement region 220A(P) and the resistance element arrangement region 220Ba that are aligned in the X direction, the gate electrode 212 is formed on the side surfaces of the semiconductor nanowires 207A(P), 207B via the gate insulating film 211. In this example, the gate electrodes 212, some of which are formed on the side surfaces of a plurality of the semiconductor nanowires 207A(P) and a plurality of the semiconductor nanowires 207B, each of which are three, for example, aligned in the X direction, are formed as a single-layer conductive film as a whole.

In the N-type VNW transistor arrangement region 220A(N) and the resistance element arrangement region 220Bb that are aligned in the X direction, the gate electrode 212 is formed on the side surfaces of the semiconductor nanowires 207A(N), 207B via the gate insulating film 211. In this example, the gate electrodes 212 on a plurality of the semiconductor nanowires 207A(N) and a plurality of the semiconductor nanowires 207B, each of which are three, for example, aligned in the X direction are formed as a single-layer conductive film as a whole.

In this example, the gate electrode 212 common to the P-type VNW transistor arrangement region 220A(P) and the resistance element arrangement region 220Ba and the gate electrode 212 common to the N-type VNW transistor arrangement region 220A(N) and the resistance element arrangement region 220Bb are formed by a single-layer conductor film being processed in the same step.

As illustrated in FIG. 17, in the resistance element arrangement region 220Bb, a connection plug 502 is electrically connected on one end of the gate electrode 212. A connection plug 503 is electrically connected on one end of the gate electrode 212 in the N-type VNW transistor arrangement region 220A(N). Similarly, in the resistance element arrangement region 220Ba, a connection plug 502 is electrically connected on one end of the gate electrode 212. A connection plug 503 is electrically connected on one end of the gate electrode 212 in the P-type VNW transistor arrangement region 220A(P).

As illustrated in FIG. 17, in the N-type VNW transistor arrangement region 220A(N), local wirings 504, 505 are provided. The local wiring 504 is electrically connected to the semiconductor nanowires 207A(N) of the two N-type VNW transistors 210A(N) aligned in the X direction. The local wiring 505 is electrically connected to the connection plug 503. In the resistance element arrangement region 220Bb, local wirings 506, 507 are provided. The local wiring 506 is electrically connected to the connection plug 502. The local wiring 507 is electrically connected to the semiconductor nanowires 207B of the three VNW structures 210B aligned in the X direction. Similarly, in the P-type VNW transistor arrangement region 220A(P), local wirings 504, 505 are provided. The local wiring 504 is electrically connected to the semiconductor nanowires 207A(P) of the two P-type VNW transistors 210A(P) aligned in the X direction. The local wiring 505 is electrically connected to the connection plug 503. In the resistance element arrangement region 220Ba, local wirings 506, 507 are provided. The local wiring 506 is electrically connected to the connection plug 502. The local wiring 507 is electrically connected to the semiconductor nanowires 207B of the three VNW structures 210B aligned in the X direction.

Above the respective local wirings, for example, M1-layer wirings 508, 509, 511, and 512 are arranged. The wirings 508, 509 are electrically connected to a plurality of the local wirings 504 in the N-type VNW transistor arrangement region 220A(N) and a plurality of the local wirings 504 in the P-type VNW transistor arrangement region 220A(P). The wiring 511 in the N-type VNW transistor arrangement region 220A(N) is electrically connected to a plurality of the local wirings 505 in the N-type VNW transistor arrangement region 220A(N). The wiring 511 in the P-type VNW transistor arrangement region 220A(P) is electrically connected to a plurality of the local wirings 505 in the P-type VNW transistor arrangement region 220A(P). The wiring 512 is electrically connected to a plurality of the local wirings 506 in the resistance element arrangement region 220Ba and a plurality of the local wirings 506 in the resistance element arrangement region 220Bb.

Above the respective M1-layer wirings, for example, M2-layer wirings 513a, 513b, 513c, 513d, 513e, and 513f are arranged. The wiring 513a is to be electrically connected to a pad of an external connection terminal or the like, and is electrically connected to one end of the wiring 512. The wirings 513b, 513c are to function as a power supply line Vss, and are electrically connected to the wiring 511 in the N-type VNW transistor arrangement region 220A(N). The wirings 513d, 513e are to function as a power supply line Vdd, and are electrically connected to the wiring 511 in the P-type VNW transistor arrangement region 220A(P). The wiring 513f is to function as an output terminal, and is electrically connected to the wirings 508, 509.

The wirings 508 to 513f each have a dual damascene structure with a wiring portion being an upper portion and a via portion being a lower portion formed integrally. The via portion is in contact with the local wiring. The wirings 508 to 513f are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In the semiconductor device according to this example, as illustrated in FIG. 18, a resistance element 200a to be Rin1 and a resistance element 200b to be Rin2 are connected in parallel between a pad and an inverter circuit. Concretely, the resistance element 200a is electrically connected to the respective gate electrodes 212 to be input portions of the N-type VNW transistors 210A(N) of the inverter circuit, and the resistance element 200b is electrically connected to the respective gate electrodes 212 to be input portions of the P-type VNW transistors 210A of the inverter circuit. Connecting Rin1 and Rin2 between the pad and the inverter circuit suppresses the destruction of the inverter circuit when an ESD current is generated in the pad.

In this embodiment, the gate electrodes 212 of the P-type VNW transistor 210A(P), the N-type VNW transistor 210A(N), and the VNW structure 210B are formed by a single-layer conductor film being processed. In the resistance element arrangement regions 220Ba, 220Bb, the gate electrode 212 is used as an electrical resistance body. Concretely, the gate electrodes 212 in the resistance element arrangement region 220Ba are used as the resistance element 200a, and the gate electrodes 212 in the resistance element arrangement region 220B 220Bb are used as the resistance element 200b. This makes it possible to reduce the manufacturing steps and obtain the gate electrodes 212 of the resistance elements 200a and 200b together with the gate electrodes 212 of the P-type VNW transistor 210A(P) and the N-type VNW transistor 210A(N).

### Modified Example 2

In this example, there is disclosed a semiconductor device including a circuit including VNW transistors and a pull resistance (a pull-up circuit) in addition to an input protective resistance using the VNW transistors.

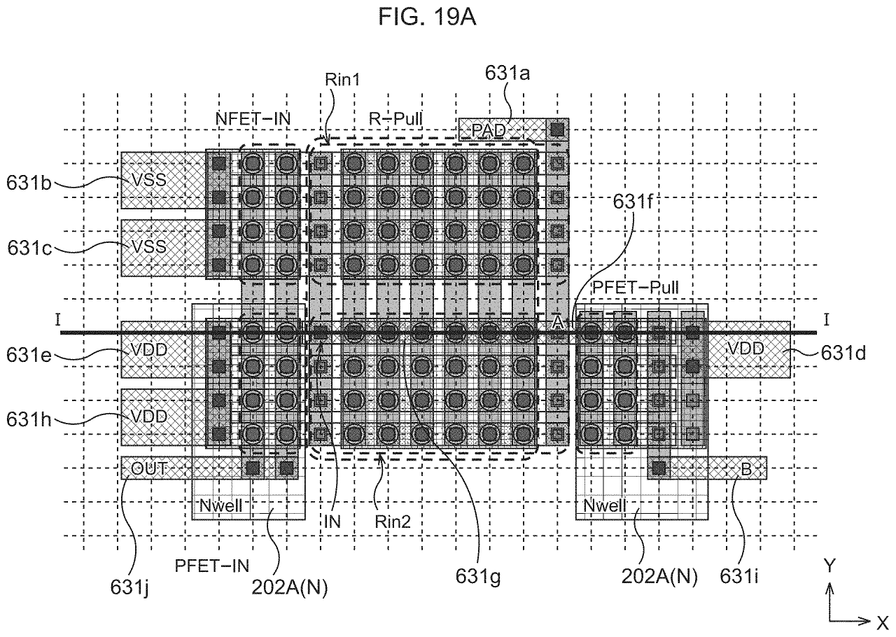

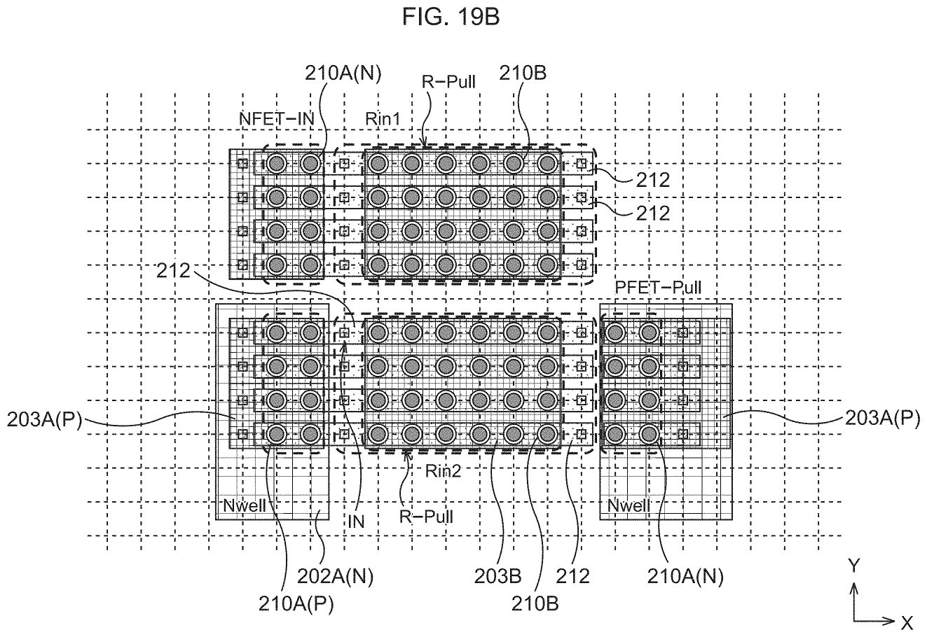

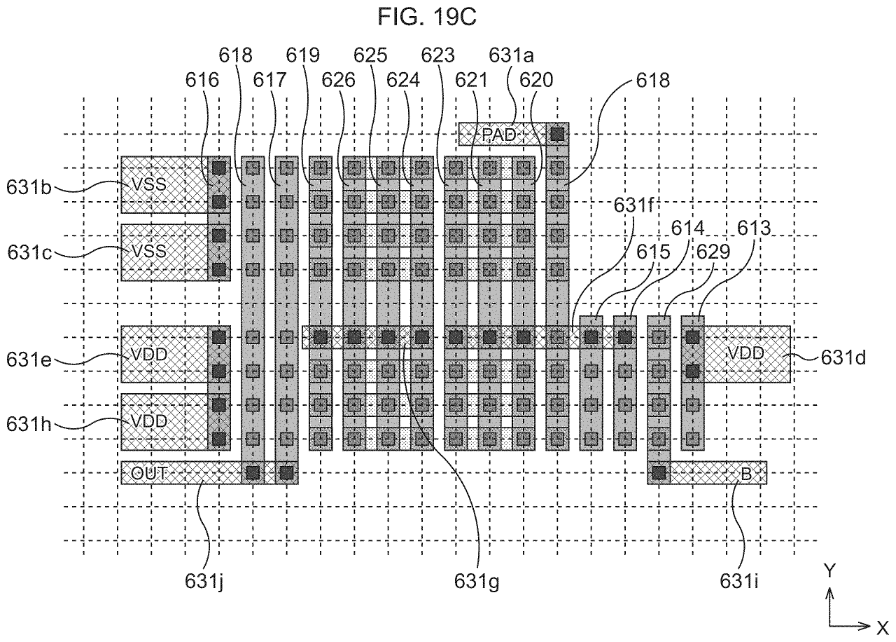

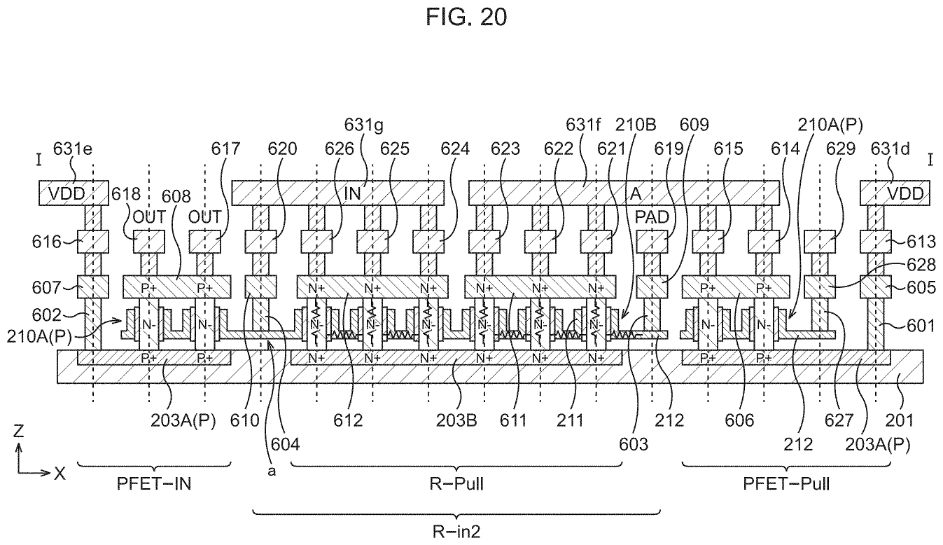

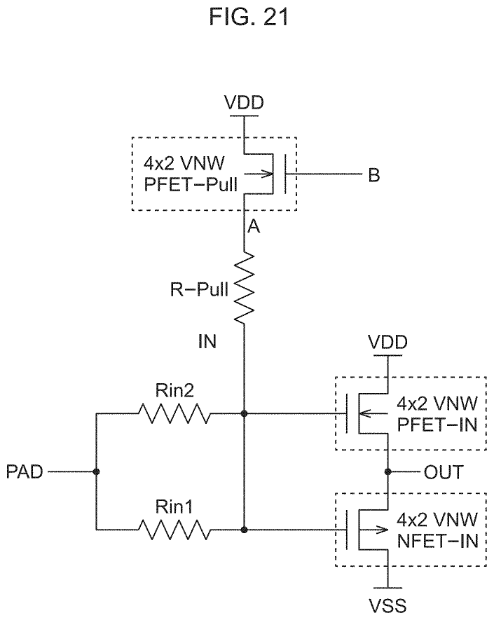

FIG. 19A is a plan view illustrating a schematic configuration of a semiconductor device according to a modified example 2 of the sixth embodiment. FIG. 19B is a plan view illustrating a schematic configuration of FIG. 19A excluding a configuration above VNW elements. FIG. 19C is a plan view illustrating a schematic configuration of local wirings and wirings thereon in a partial region in FIG. 19A. FIG. 20 is a simple cross-sectional view illustrating a cross section taken along I-I in FIG. 19A. FIG. 21 is an equivalent circuit diagram of the semiconductor device according to the modified example 2 in the sixth embodiment. Incidentally, the same reference numerals and symbols are added to the same component members as those in the semiconductor device according to the third embodiment, and their detailed explanations are omitted.

In this semiconductor device, a P-type VNW transistor arrangement region of PFET-IN, a P-type VNW transistor arrangement region of PFET-PULL, an N-type VNW transistor arrangement region of NFET-IN, a resistance element arrangement region of Rin1, a resistance element arrangement region of Rin2, and a resistance element arrangement region of R-PULL overlapping Rin1 and Rin2 are provided. In the P type VNW transistor arrangement regions of PFET-IN and PFET-PULL, a plurality of the VNW transistors 210A(P) are arranged in a matrix, in the N-type VNW transistor arrangement region of NFET-IN, a plurality of the VNW transistors 210A(N) are arranged in a matrix, and in the resistance element arrangement regions of Rin1 and Rin2, a plurality of the VNW structures 210B are arranged in a matrix. PFET-IN and NFET-IN are electrically connected to form an inverter circuit. Incidentally, as for Rin, only one of Rin1 and Rin2 may be applied. R-PULL is formed so as to overlap both Rin1 and Rin2, but R-PULL may be formed so as to overlap only one of Rin1 and Rin2.

In the P-type VNW transistor arrangement regions of PFET-IN and PFET-PULL, a plurality of the projecting semiconductor nanowires 207A(P) are formed vertically to the impurity region 203A(P) formed on the surface of the N-type well 202A(N). The semiconductor nanowire 207A(P) has a lower end portion 207Aa, an upper end portion 207Ab, and a middle portion 207Ac between the lower end portion 207Aa and the upper end portion 207Ab. The lower end portion 207Aa has a P-type conductivity and is electrically connected to the impurity region 203A(P). The upper end portion 207Ab has a P-type conductivity. The middle portion 207Ac has an N-type conductivity or is non-doped and serves as a channel region of the transistor. One of the lower end portion 207Aa and the upper end portion 207Ab is a source electrode and the other is a drain electrode.

In the N-type VNW transistor arrangement region of NFET-IN, a plurality of the projecting semiconductor nanowires 207A(N) are formed vertically to the N-type impurity region 203A(N). The semiconductor nanowire 207A(N) has a lower end portion 207Aa, an upper end portion 207Ab, and a middle portion 207Ac between the lower end portion 207Aa and the upper end portion 207Ab. The lower end portion 207Aa has an N-type conductivity and is electrically connected to the impurity region 203A(N). The upper end portion 207Ab has an N-type conductivity. The middle portion 207Ac has a P-type conductivity or is non-doped and serves as a channel region of the transistor. One of the lower end portion 207Aa and the upper end portion 207Ab is a source electrode and the other is a drain electrode.

In the resistance element arrangement regions of Rin1, Rin2, a plurality of the projecting semiconductor nanowires 207B are formed vertically to the N-type impurity region 203B. Of the semiconductor nanowire 207B, a lower end portion 207Ba, an upper end portion 207Bb, and a middle portion 207Bc all have the same conductivity type, which is a P type, for example. Incidentally, the lower end portion 207Ba, the upper end portion 207Bb, and the middle portion 207Bc all may have an N type. The middle portion 207Bc may have an impurity concentration lower than the lower end portion 207Ba and the upper end portion 207Bb.

R-PULL includes the semiconductor nanowires 207B of Rin1 and Rin2 and the impurity region 203B in the substrate 201.

In the N-type VNW transistor arrangement region of NFET-IN and the resistance element arrangement region of Rin1 that are aligned in the X direction, the gate electrode 212 is formed on the side surfaces of the semiconductor nanowires 207A(N), 207B via the gate insulating film 211. In this example, the gate electrodes 212 on a plurality of the semiconductor nanowires 207A(N), which are two, and a plurality of the semiconductor nanowires 207B, which are six, for example, aligned in the X direction are formed as a single-layer conductive film as a whole. In this example, as the gate electrode 212 common to NFET-IN and Rin1, four layers extending in the X direction are described as an example, but one layer to three layers may be applied, or five or more layers may also be applied.

In the P-type VNW transistor arrangement region of PFET-IN and the resistance element arrangement region of Rin2 that are aligned in the X direction, the gate electrode 212 is formed on the side surfaces of the semiconductor nanowires 207A(P), 207B via the gate insulating film 211. In this example, the gate electrodes 212 on a plurality of the semiconductor nanowires 207A(P), which are two, and a plurality of the semiconductor nanowires 207B, which are six, for example, aligned in the X direction are formed as a single-layer conductive film as a whole. In this example, as the gate electrode 212 common to PFET-IN and Rin2, four layers extending in the X direction are described as an example, but one layer to three layers may be applied, or five or more layers may also be applied.

In the P-type VNW transistor arrangement region of PFET-PULL aligned in the X direction, the gate electrode 212 is formed on the side surface of the semiconductor nanowire 207A(P) via the gate insulating film 211. In this example, the gate electrodes 212 on a plurality of the semiconductor nanowires 207A(P), which are two, for example, aligned in the X direction are formed as a single-layer conductive film as a whole.

In this example, the gate electrode 212 common to NFET-IN and Rin1, the gate electrode 212 common to PFET-IN and Rin2, and the gate electrode 212 in PFET-PULL are formed by a single-layer conductor film being processed in the same step.

As illustrated in FIG. 20, in the P-type VNW transistor arrangement region of PFET-PULL, a connection plug 601 is electrically connected to the impurity region 203A(P). In the P-type VNW transistor arrangement region of PFET-IN, a connection plug 602 is electrically connected to the impurity region 203A(P). In the P-type VNW transistor arrangement region of PFET-PULL, a connection plug 627 is electrically connected on one end of the gate electrode 212. In the resistance element arrangement region of Ring, a connection plug 603 is electrically connected on one end of the gate electrode 212. A connection plug 604 is electrically connected on the other end of the gate electrode 212. Similarly, in the N-type VNW transistor arrangement region of NFET-IN, a connection plug 602 is electrically connected to the impurity region 203A(N). In the resistance element arrangement region of Rin1, a connection plug 603 is electrically connected on one end of the gate electrode 212. A connection plug 604 is electrically connected on the other end of the gate electrode 212.

As illustrated in FIG. 20, in the P-type VNW transistor arrangement region of PFET-PULL, local wirings 605, 606, and 628 are provided. The local wiring 605 is electrically connected to the connection plug 601. The local wiring 628 is electrically connected to the connection plug 627. The local wiring 606 is electrically connected to the two semiconductor nanowires 207A(P) aligned in the X direction. In the P-type VNW transistor arrangement region of PFET-IN, local wirings 607, 608 are provided. The local wiring 607 is electrically connected to the connection plug 602. The local wiring 608 is electrically connected to the semiconductor nanowires 207A(P) of the two P-type VNW transistors 210A(P) aligned in the X direction. In the resistance element arrangement region of Rin2, local wirings 609, 610, 611, and 612 are provided. The local wiring 609 is electrically connected to the connection plug 603. The local wiring 610 is electrically connected to the connection plug 604. The local wiring 611 is electrically connected to the semiconductor nanowires 207B of the three VNW structures 210B aligned in the X direction. The local wiring 612 is electrically connected to the semiconductor nanowires 207B of the three VNW structures 210B aligned in the X direction. Similarly, in the N-type VNW transistor arrangement region of NFET-IN, local wirings 607, 608 are provided. The local wiring 607 is electrically connected to the connection plug 602. The local wiring 608 is electrically connected to the semiconductor nanowires 207A(N) of the two N-type VNW transistors 210A(N) aligned in the X direction. In the resistance element arrangement region of R-PULL, local wirings 609, 610, 611, and 612 are provided. The local wiring 611 is electrically connected to the semiconductor nanowires 207B of the three VNW structures 210B aligned in the X direction. The local wiring 612 is electrically connected to the semiconductor nanowires 207B of the three VNW structures 210B aligned in the X direction.

Above the respective local wirings, for example, M1-layer wirings 613 to 626 and 629 are arranged. The wiring 613 is electrically connected to a plurality of the local wirings 605 in PFET-PULL. The wiring 629 is electrically connected to a plurality of the local wirings 628 in PFET-PULL. The wirings 614, 615 are electrically connected to a plurality of the local wirings 606 in PFET-PULL. The local wiring 616 is electrically connected to a plurality of the local wirings 607 in PFET-IN. The wirings 617, 618 are electrically connected to a plurality of the local wirings 608 in PFET-IN. The wiring 619 is electrically connected to a plurality of the local wirings 609 in Rin1 and a plurality of the local wirings 609 in Rin2. The wiring 620 is electrically connected to a plurality of the local wirings 610 in Rin1 and a plurality of the local wirings 610 in Rin2. The wirings 621, 622, and 623 are electrically connected to a plurality of the local wirings 611 in Rin1 and a plurality of the local wirings 611 in Rin2. The wirings 624, 625, and 626 are electrically connected to a plurality of the local wirings 612 in Rin1 and a plurality of the local wirings 612 in Rin2.

Above the respective M1-layer wirings, for example, M2-layer wirings 631a, 631b, 631c, 631d, 631e, 631f, 631g, 631h, 631i, and 631j are arranged. The wiring 631a is to be electrically connected to a pad of an external connection terminal or the like, and is electrically connected to one end of the wiring 619. The wirings 631b, 631c are to function as a power supply line Vss, and are electrically connected to the wiring 616 on the NFET-IN side. The wiring 631d is to function as a power supply line Vdd, and is electrically connected to the wiring 613 on the PFET-PULL side. The wirings 631e, 631h are to function as a power supply line Vdd, and are electrically connected to the wiring 616 on the PFET-IN side. The wiring 631f is electrically connected to the wirings 614, 615 in PFET-PULL and the wirings 621 to 623 in Rin2. The wiring 631g is electrically connected to the wirings 620 and 624 to 626 in Rin2. The wiring 631i is electrically connected to the wiring 629. The wiring 631j is to function as an output terminal, and is electrically connected to the wirings 617, 618.

The wirings 613 to 626, 627, 628, and 631a to 631j each have a dual damascene structure with a wiring portion being an upper portion and a via portion being a lower portion formed integrally. The via portion is in contact with the local wiring. The wirings 613 to 626, 627, 628, and 631a to 631j are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In the semiconductor device according to this example, as illustrated in FIG. 21, between the pad and the inverter circuit, Rin1 and Rin2 whose gate electrodes 212 function as an electrical resistance are connected in parallel. Rin1 and Rin2 become the input protective resistance of the inverter circuit, similarly to the modified example 1 of the sixth embodiment. Further, between Rin1, Rin2 and PFET-PULL, R-PULL in which the semiconductor nanowires 207B and the impurity regions 203B in the substrate 201 of Rin1, Rin2 function as an electrical resistance is connected.

In this example, the gate electrode 212 common to NFET-IN and Rin1, the gate electrode 212 common to PFET-IN and Rin2, and the gate electrode 212 in PFET-PULL are formed by a single-layer conductor film being processed. In each of Rin1 and Rin2, the gate electrode 212 is used as an electrical resistance body. This makes it possible to reduce the manufacturing steps and obtain the gate electrodes 212 in Rin1, Rin2 together with the gate electrodes 212 in NFET-IN, PFET-IN, and PFET-PULL. Incidentally, in this example, in place of PFET-PULL, N-type VNW transistors may be provided, and in place of the power supply line Vdd, the power supply line Vss may be provided and a pull-down circuit may be arranged.

In this example, Rin1, Rin2 and R-PULL are formed in the same overlapping region, and thus a circuit area can be reduced. Further, as indicated by an arrow a in FIG. 20, in a boundary region between the impurity region 203A(P) and the impurity region 203B, a lead-out portion of the gate electrode 212 is provided. This can improve the efficiency of the circuit area.

### Modified Example 3

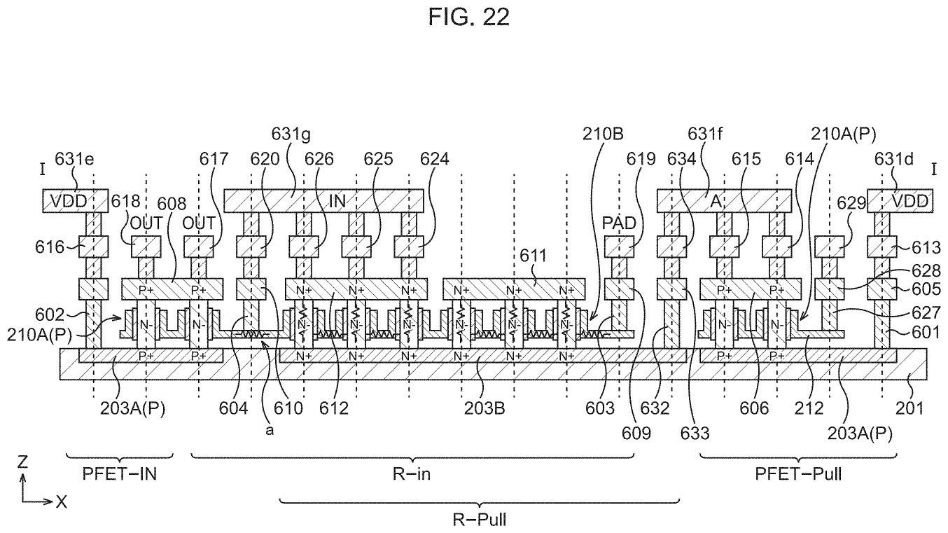

In this example, similarly to the modified example 2 of the sixth embodiment, there is disclosed a semiconductor device that includes a pull resistance using VNW transistors in addition to an input protective resistance using the VNW transistors, but this example is different from the modified example 2 in that its layout is partially different. FIG. 22 is a simple cross-sectional view in a modified example 3 of the sixth embodiment, which corresponds to the cross section taken along I-I in FIG. 19A in the modified example 2. Incidentally, the same reference numerals and symbols are added to the same component members as those in the semiconductor device according to the modified example 2, and their detailed explanations are omitted.

In the modified example 3, the arrangement of Rin1 and Rin2 and the arrangement of R-PULL in the X direction coincide with each other. In contrast to this, in this example, the arrangement is made in such a manner that Rin1 and Rin2 extend in the X direction and R-PULL overlaps a part of Rin1 and Rin2 in the modified example 2.

Concretely, as illustrated in FIG. 22, no wirings are connected on the local wiring 611. In this example, in R-PULL, a connection plug 632 is electrically connected to the impurity region 203B. A local wiring 633 is electrically connected to the connection plug 632. A wiring 634 is electrically connected to the local wiring 633. The wiring 634 is electrically connected to the wiring 631f via a via. This example is different from the modified example 2 in that a terminal A of the resistance element R-PULL is electrically connected to the impurity region 203B not via the VNW structures 210B but via the connection plug 632. Here, the VNW structures 210B that are not used as the electrical resistance of R-PULL may be a dummy, and their arrangement may be omitted. The wiring 631f is electrically connected also to the wiring 634 together with the wirings 614, 615, unlike the modified example 2. Incidentally, a terminal IN of the resistance element R-PULL and the impurity region 203B may be electrically connected by a connection plug not via the VNW structures 210B.

### Seventh Embodiment

In this embodiment, there is disclosed a semiconductor device with VNW structures provided in a resistance element similarly to the second embodiment, but this embodiment is different from the second embodiment in that not only the gate electrode of the VNW structure but also the semiconductor nanowire functions as the electrical resistance.

(First Aspect)

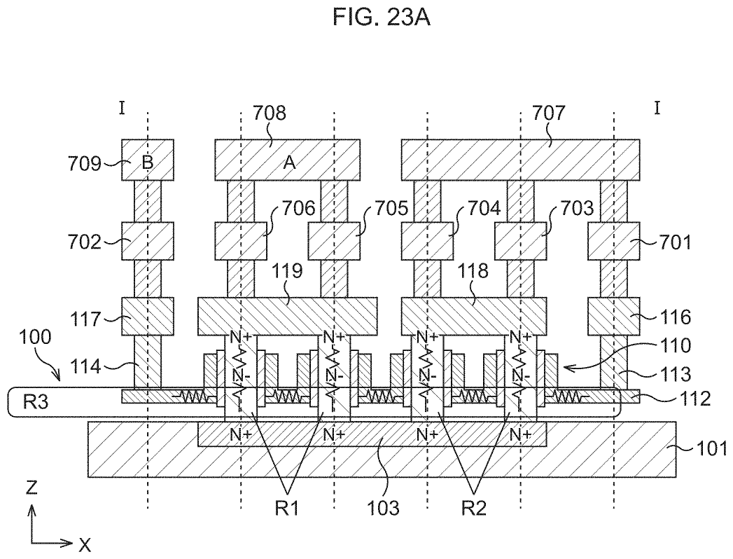

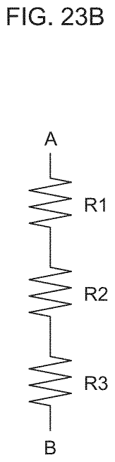

Hereinafter, there is explained a first aspect of this embodiment. FIG. 23A is a simple cross-sectional view of a semiconductor device according to the first aspect in a seventh embodiment, which corresponds to FIG. 4B in the second embodiment. FIG. 23B is an equivalent circuit diagram of a resistance element in the first aspect. Incidentally, the same reference numerals and symbols are added to the same component members as those in the semiconductor device according to the second embodiment, and their detailed explanations are omitted.

In this semiconductor device, similarly to the second embodiment, the resistance element 100 including the VNW structures 110 grouped and arranged in a matrix in a plane view, for example, is provided. The VNW structure 110 includes the semiconductor nanowire 107 standing vertically from the surface of the impurity region 103 formed in the substrate 101 and the gate electrode 112 via the gate insulating film 111 on the side surface of the semiconductor nanowire 107. In this embodiment, the impurity region 103 and the lower end portion 107a, the upper end portion 107b, and the middle portion 107c of the semiconductor nanowire 107 all have the same conductivity type, for example, an N type. Incidentally, the impurity region 103, the lower end portion 107a, the upper end portion 107b, and the middle portion 107c all may have a P type. The middle portion 107c may have an impurity concentration lower than the lower end portion 107a and the upper end portion 107b.

In this aspect, the configuration under the local wirings 116, 117, 118, 119, and 121 is the same as that in the second embodiment.

In the arrangement region of the resistance element 100, a plurality of wirings, for example, M1-layer wirings 701 to 706 are arranged. The respective M1-layer wirings are arranged above the respective local wirings. The wiring 701 is electrically connected to a top surface of the local wiring 116. The wiring 702 is electrically connected to a top surface of the local wiring 117.

The wiring 703 extends in the Y direction, and is electrically connected to top surfaces of a plurality of the local wirings 118 aligned along the Y direction. The wiring 704 extends in the Y direction, and is electrically connected to top surfaces of a plurality of the local wirings 118 aligned along the Y direction. The wiring 705 extends in the Y direction, and is electrically connected to top surfaces of a plurality of the local wirings 119 aligned along the Y direction. The wiring 706 extends in the Y direction, and is electrically connected to top surfaces of a plurality of the local wirings 119 aligned along the Y direction.

In the arrangement region of the resistance element 100, for example, M2-layer wirings 707, 708, and 709 are arranged. The respective M2-layer wirings are arranged above the respective M1-layer wirings. The wiring 707 is electrically connected to top surfaces of the wirings 701, 703, and 704. The wiring 708 is electrically connected to top surfaces of the wirings 705, 706. The wiring 709 is electrically connected to a top surface of the wiring 702.

The wirings 707 to 709 each have a dual damascene structure with a wiring portion being an upper portion and a via portion being a lower portion formed integrally. The via portion is in contact with the local wiring. The wirings 707 to 709 are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In the resistance element 100 of the semiconductor device according to this aspect, as illustrated in FIG. 23A, the semiconductor nanowires 107 in the VNW structures 110 connected to the local wiring 119 function as an electrical resistance R1. The semiconductor nanowires 107 in the VNW structures 110 connected to the local wiring 118 function as an electrical resistance R2. A plurality of the gate electrodes 112 function as an electrical resistance R3. As illustrated in FIG. 23B, the electrical resistances R1 to R3 in the resistance element 100 are connected in series with the wiring 708 set to an A end and the wiring 709 set to a B end.

In this aspect, the conductive pattern 120 using the gate electrodes 112 in the VNW structures 110 is used as a part of the electrical resistance (R3) of the resistance element 100. In the VNW structure 110, the thin gate electrode 112 is used. The thin gate electrode 112 has a high resistance value. This gate electrode 112 is applied to the resistance element 100. Further, in the aspect, the electrical resistances R1, R2 in the resistance element 100 are fabricated by the semiconductor nanowires 107, and the electrical resistance R3 in the resistance element 100 is fabricated by the gate electrodes 112. Therefore, the electrical resistances R1 to R3 are formed at the same position in a plane view, enabling a reduction in the circuit area.

(Second Aspect)

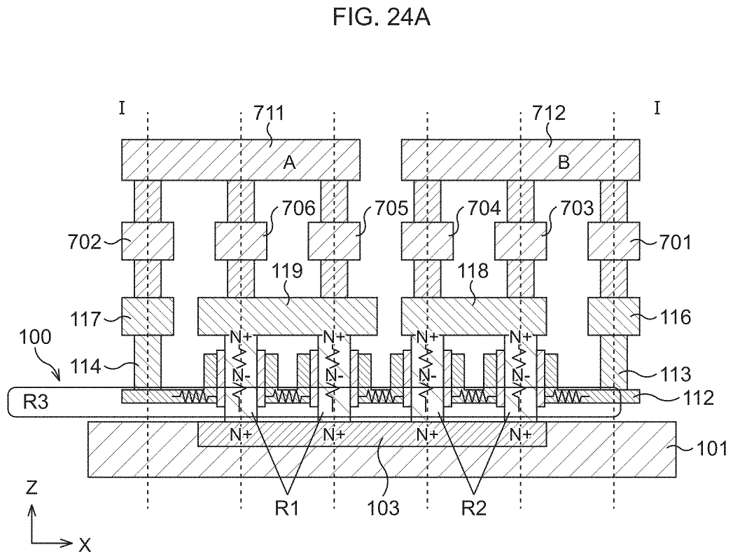

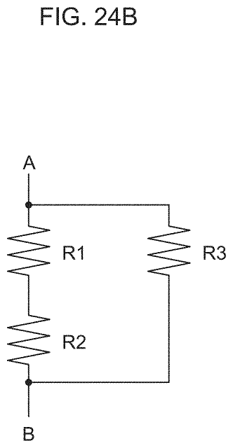

Hereinafter, there is explained a second aspect in this embodiment. FIG. 24A is a simple cross-sectional view of a semiconductor device according to the second aspect in the seventh embodiment, which corresponds to FIG. 4B in the second embodiment. FIG. 24B is an equivalent circuit diagram of a resistance element in the second aspect. Incidentally, the same reference numerals and symbols are added to the same component members as those in the semiconductor device according to the second embodiment, and their detailed explanations are omitted.

In this semiconductor device, similarly to the first aspect, the resistance element 100 including the VNW structures 110 grouped and arranged in a matrix in a plane view, for example, is provided. The VNW structure 110 includes the semiconductor nanowire 107 standing vertically from the surface of the substrate 101 and the gate electrode 112 via the gate insulating film 111 on the side surface of the semiconductor nanowire 107.

In this aspect, the configuration under the wirings 701 to 706 is the same as that in the first aspect.

In the arrangement region of the resistance element 100, for example, wirings 711, 712 are arranged. The wiring 711 is electrically connected to top surfaces of the wirings 702, 705, and 706. The wiring 712 is electrically connected to top surfaces of the wirings 701, 703, and 704.

The wirings 711, 712 each have a dual damascene structure with a wiring portion being an upper portion and a via portion being a lower portion formed integrally. The via portion is in contact with the local wiring. The wirings 711, 712 are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In the resistance element 100 of the semiconductor device according to this aspect, as illustrated in FIG. 24A, the semiconductor nanowires 107 in the VNW structures 110 connected to the local wiring 119 function as the electrical resistance R1 of the resistance element 100. The semiconductor nanowires 107 in the VNW structures 110 connected to the local wiring 118 function as the electrical resistance R2 of the resistance element 100. A plurality of the gate electrodes 112 function as the electrical resistance R3 of the resistance element 100. As illustrated in FIG. 24B, the electrical resistances R1, R2 are connected in series and the electrical resistances R1, R2 and the electrical resistance R3 are connected in parallel with the wiring 711 set to an A end and the wiring 712 set to a B end.

In this aspect, the conductive pattern 120 using the gate electrodes 112 in the VNW structures 110 is used as a part of the electrical resistance (R3) of the resistance element 100. In the VNW structure 110, the thin gate electrode 112 is used. The thin gate electrode 112 has a high resistance value. This gate electrode 112 is applied to the resistance element 100. Further, in the aspect, the electrical resistances R1, R2 are fabricated by the semiconductor nanowires 107, and the electrical resistance R3 is fabricated by the gate electrodes 112. Therefore, the electrical resistances R1 to R3 in the resistance element 100 are formed at the same position in a plane view, enabling a reduction in the circuit area.

### Eight Embodiment

In this embodiment, there is disclosed a semiconductor device with VNW structures provided in a resistance element similarly to the second embodiment. The semiconductor device according to this embodiment is a CR timer circuit using an electrical resistance and an electric capacity in VNW structures.

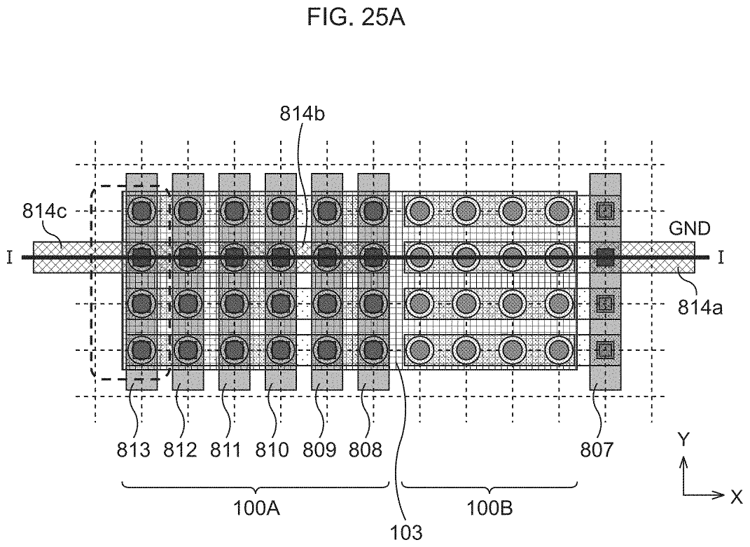

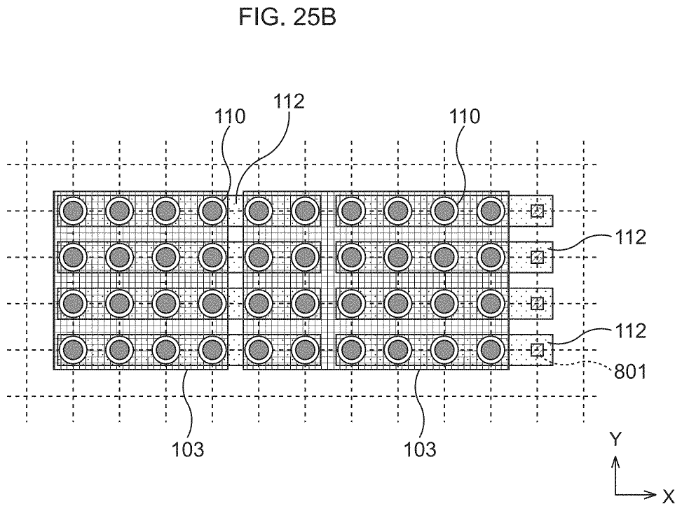

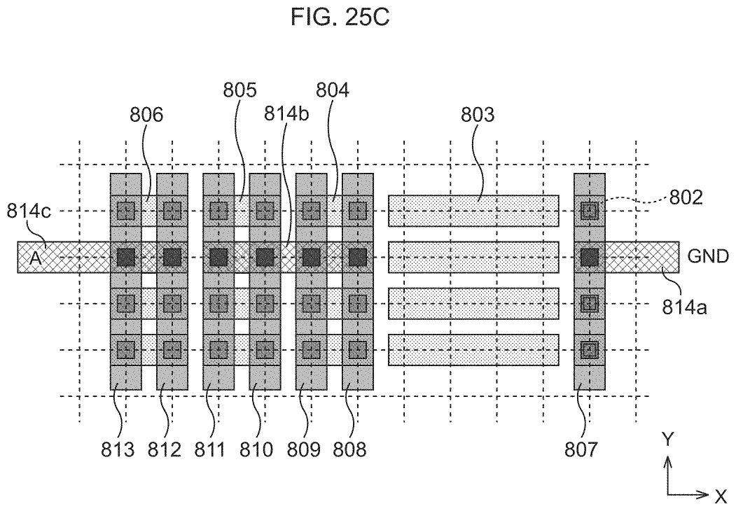

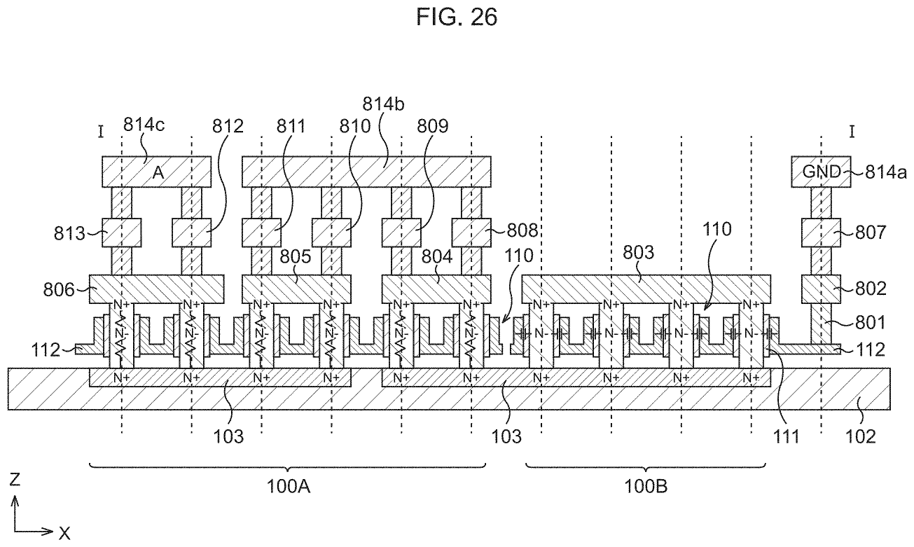

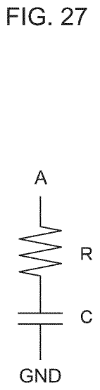

FIG. 25A is a plan view illustrating a schematic configuration of a semiconductor device according to an eighth embodiment. FIG. 25B is a plan view illustrating a schematic configuration of FIG. 25A excluding a configuration above VNW structures. FIG. 25C is a plan view illustrating a schematic configuration of local wirings and wirings thereon in a partial region in FIG. 25A. FIG. 26 is a simple cross-sectional view illustrating a cross section taken along I-I in FIG. 25A. FIG. 27 is an equivalent circuit diagram of a CR timer circuit according to the eighth embodiment. Incidentally, the same reference numerals and symbols are added to the same component members as those in the semiconductor device according to the second embodiment, and their detailed explanations are omitted.

In this semiconductor device, similarly to the second embodiment, a resistance element 100A including the VNW structures 110 grouped and arranged in a matrix in a plane view, for example, is provided. In this embodiment, a capacity element 100B including the VNW structures 110 grouped and arranged in a matrix in a plane view, for example, is provided adjacently to the resistance element 100A. The VNW structure 110 includes the semiconductor nanowire 107 standing vertically from the surface of, for example, the N-type impurity region 103 formed in the substrate 101 and the gate electrode 112 via the gate insulating film 111 on the side surface of the semiconductor nanowire 107. In this embodiment, the lower end portion 107a, the upper end portion 107b, and the middle portion 107c of the semiconductor nanowire 107 all have the same conductivity type, for example, an N type. Incidentally, the impurity region 103, the lower end portion 107a, the upper end portion 107b, and the middle portion 107c all may have a P type. The middle portion 107c may have an impurity concentration lower than the lower end portion 107a and the upper end portion 107b.

In the resistance element 100A, the gate electrodes 112 each are formed in a shape extending in the X direction in common with a plurality of the semiconductor nanowires 107, which are six here, aligned in the X direction. In the capacity element 100B, the gate electrodes 112 each are formed in a shape extending in the X direction in common with a plurality of the semiconductor nanowires 107, which are four here, aligned in the X direction.

At a right end of the capacity element 100B, a connection plug 801 is provided side by side with the respective VNW structures 110. The connection plug 801 is electrically connected on one end of the gate electrode 112 in the capacity element 100B.

Above the semiconductor substrate 101, local wirings 802 to 806 are provided. The local wiring 802 is electrically connected to the connection plug 801. The local wiring 803 extends in the X direction adjacently to the local wiring 802 in the X direction, and is electrically connected to the four semiconductor nanowires 107 aligned in the X direction in the arrangement region of the capacity element 100B. The local wiring 804 extends in the X direction adjacently to the local wiring 803 in the X direction, and is electrically connected to the two semiconductor nanowires 107 aligned in the X direction in the arrangement region of the resistance element 100A. The local wiring 805 extends in the X direction adjacently to the local wiring 804 in the X direction, and is electrically connected to the two semiconductor nanowires 107 aligned in the X direction in the arrangement region of the resistance element 100A. The local wiring 806 extends in the X direction adjacently to the local wiring 805 in the X direction, and is electrically connected to the two semiconductor nanowires 107 aligned in the X direction in the arrangement region of the resistance 100A.

Above the respective local wirings, for example, M1-layer wirings 807 to 813 are provided. The wiring 807 extends in the Y direction and is electrically connected to the four local wirings 802. The wiring 808 extends in the Y direction and is electrically connected to the four local wirings 804. The wiring 809 extends in the Y direction side by side with the wiring 808 and is electrically connected to the four local wirings 804. The wiring 810 extends in the Y direction side by side with the wiring 809 and is electrically connected to the four local wirings 805. The wiring 811 extends in the Y direction side by side with the wiring 810 and is electrically connected to the four local wirings 805. The wiring 812 extends in the Y direction side by side with the wiring 811 and is electrically connected to the four local wirings 806. The wiring 813 extends in the Y direction side by side with the wiring 812 and is electrically connected to the four local wirings 806.

Above the respective M1-layer wirings, for example, M2-layer wirings 814a, 814b, and 814c are arranged. The wiring 814a extends in the X direction and is electrically connected to the wiring 807. The wiring 814b extends in the X direction and is electrically connected to the wirings 808, 809, 810, and 811. The wiring 814c extends in the X direction and is electrically connected to the wirings 812, 813. The wiring 814c becomes a terminal A, for example. The terminal A is electrically connected to, for example, a power supply line (VDD) or a signal line. The wiring 814a becomes a terminal GND, for example. The terminal GND is electrically connected to a ground line (VSS), for example. Incidentally, the electrical connection between the local wiring 804 and the local wiring 805 may be achieved by connecting (uniting) the local wirings 804 and 805 in place of achieving the electrical connection with the wiring 814b.

The wirings 807 to 813 and 814a to 814c each have a dual damascene structure with a wiring portion being an upper portion and a via portion being a lower portion formed integrally. The via portion is in contact with the local wiring. The wirings 807 to 813 and 814a to 814c are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In this embodiment, as illustrated in FIG. 26, in the resistance element 100A, the semiconductor nanowires 107 in the VNW structures 110 have an electrical resistance between the impurity region 103 and the local wirings 804 to 806. In the capacity element 100B, the semiconductor nanowires 107 and the gate electrodes 112 in the VNW structures 110 are capacitively coupled via the gate insulating film 111. At this time, the capacity element 100B is arranged at a position where it overlaps the impurity region 103, which is a part of the resistance element 100A, in a plane view, thus enabling suppression of the increase in circuit area. As illustrated in FIG. 27, the CR timer circuit in which the resistance element 100A (indicated as R in the drawing) and the capacity element 100B (indicated as C in the drawing) are connected is fabricated.

In this embodiment, the resistance element 100A and the capacity element 100B can be fabricated efficiently using a plurality of the VNW structures 110 having the same configuration. Further, the VNW structures 110 having the same configuration are arranged, thereby making it possible to ensure manufacturing uniformity.

### Modified Example

Hereinafter, there is explained a modified example of the semiconductor device in the eighth embodiment. In this example, similarly to the eighth embodiment, there is disclosed a CR timer circuit using an electrical resistance and an electric capacity in VNW structures, but this example is different from the eighth embodiment in that the electrical resistance is partially different.

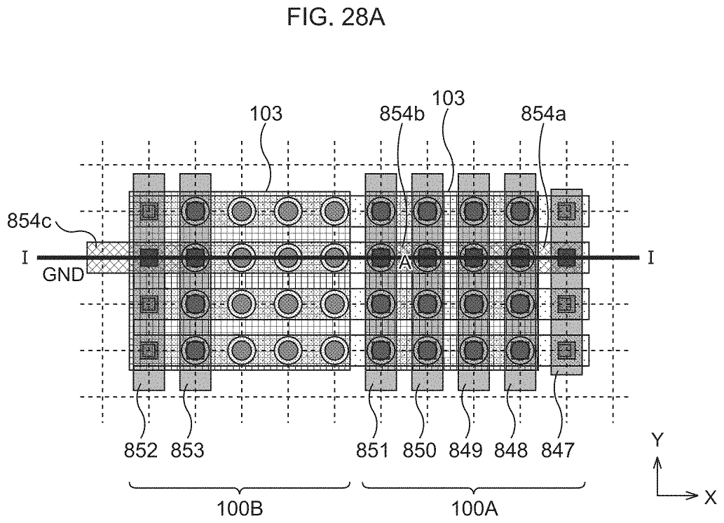

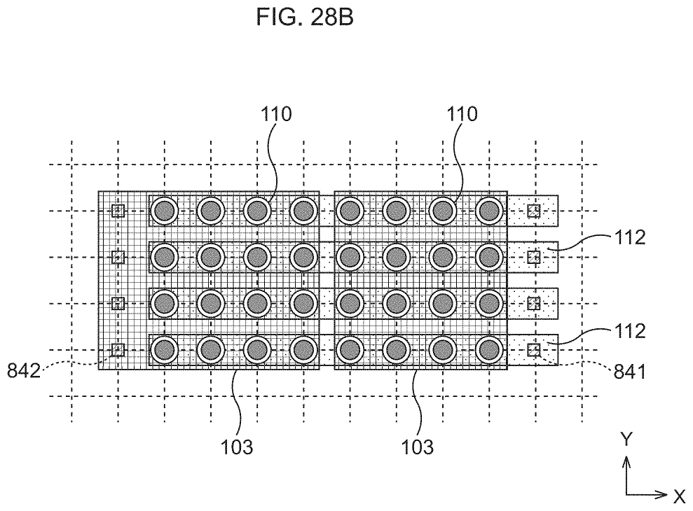

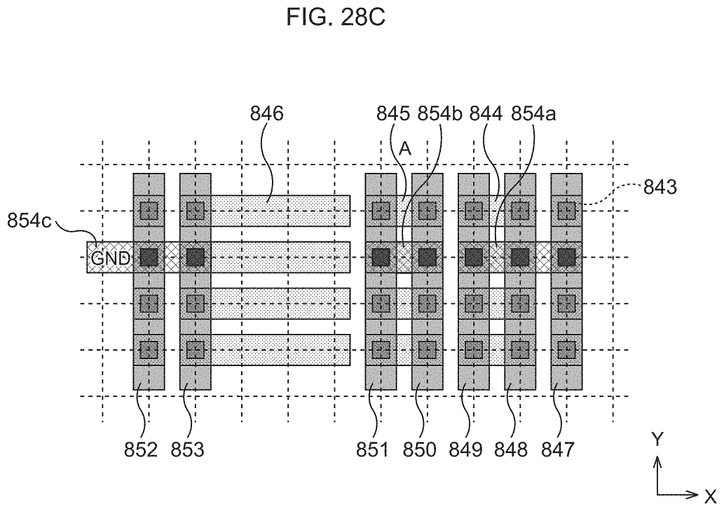

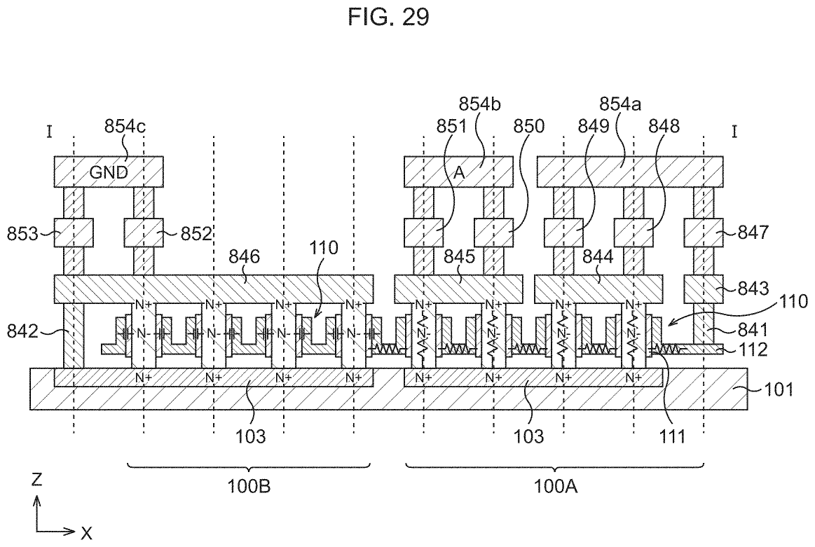

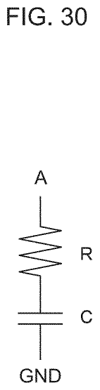

FIG. 28A is a plan view illustrating a schematic configuration of a semiconductor device according to the modified example of the eighth embodiment. FIG. 28B is a plan view illustrating a schematic configuration of FIG. 28A excluding a configuration above VNW structures. FIG. 28C is a plan view illustrating a schematic configuration of local wirings and wirings thereon in a partial region in FIG. 28A. FIG. 29 is a simple cross-sectional view illustrating a cross section taken along I-I in FIG. 28A. FIG. 30 is an equivalent circuit diagram of a CR timer circuit according to the modified example of the eighth embodiment. Incidentally, the same reference numerals and symbols are added to the same component members as those in the semiconductor device according to the second embodiment, and their detailed explanations are omitted.

In this semiconductor device, similarly to the second embodiment, the resistance element 100A including the VNW structures 110 grouped and arranged in a matrix in a plane view, for example, is provided. In this example, the capacity element 100B including the VNW structures 110 grouped and arranged in a matrix in a plane view, for example, is further provided adjacently to the resistance element 100A. The VNW structure 110 includes the semiconductor nanowire 107 standing vertically from the surface of, for example, the N-type impurity region 103 formed in the substrate 101 and the gate electrode 112 via the gate insulating film 111 on the side surface of the semiconductor nanowire 107. In this embodiment, the lower end portion 107a, the upper end portion 107b, and the middle portion 107c of the semiconductor nanowire 107 all have the same conductivity type, for example, an N type. Incidentally, the impurity region 103, the lower end portion 107a, the upper end portion 107b, and the middle portion 107c all may have a P type. The middle portion 107c may have an impurity concentration lower than the lower end portion 107a and the upper end portion 107b.

The gate electrodes 112 each are formed in a shape extending in the X direction in common with a plurality of the semiconductor nanowires 107, which are four here, aligned in the X direction in the arrangement region of the resistance element 100A and a plurality of the semiconductor nanowires 107, which are four here, aligned in the X direction in the arrangement region of the capacity element 100B.

At a right end of the resistance element 100A, a connection plug 841 is provided side by side with the respective VNW structures 110. The connection plug 841 is electrically connected on one end of the gate electrode 112 in the resistance element 100A. At a left end of the capacity element 100B, a connection plug 842 is provided side by side with the respective VNW structures 110. The connection plug 842 is electrically connected on one end of the gate electrode 112 in the capacity element 100B.

Above the semiconductor substrate 101, local wirings 843 to 846 are provided. The local wiring 843 is electrically connected to the connection plug 841. The local wiring 844 extends in the X direction adjacently to the local wiring 843 in the X direction, and is electrically connected to the two semiconductor nanowires 107 aligned in the X direction in the arrangement region of the resistance element 100A. The local wiring 845 extends in the X direction adjacently to the local wiring 844 in the X direction, and is electrically connected to the two semiconductor nanowires 107 aligned in the X direction in the arrangement region of the resistance element 100A. The local wiring 846 extends in the X direction adjacently to the local wiring 845 in the X direction, and is electrically connected to the four semiconductor nanowires 107 aligned in the X direction in the arrangement region of the capacity element 100B and the connection plug 842.

Above the respective local wirings, for example, M1-layer wirings 847 to 853 are provided. The wiring 847 extends in the Y direction and is electrically connected to the four local wirings 843. The wiring 848 extends in the Y direction and is electrically connected to the four local wirings 844. The wiring 849 extends in the Y direction side by side with the wiring 848 and is electrically connected to the four local wirings 844. The wiring 850 extends in the Y direction side by side with the wiring 849 and is electrically connected to the four local wirings 845. The wiring 851 extends in the Y direction side by side with the wiring 850 and is electrically connected to the four local wirings 845. The wiring 852 extends in the Y direction and is electrically connected to the four local wirings 846. The wiring 853 extends in the Y direction side by side with the wiring 852 and is electrically connected to the four local wirings 846.

Above the respective M1-layer wirings, for example, M2-layer wirings 854a, 854b, and 854c are arranged. The wiring 854a extends in the X direction and is electrically connected to the wirings 847, 848, and 849. The wiring 854b extends in the X direction and is electrically connected to the wirings 850, 851. The wiring 854c extends in the X direction and is electrically connected to the wirings 852, 853. The wiring 854b becomes a terminal A, for example. The terminal A is electrically connected to a power supply line (VDD) or a signal line. The wiring 854c becomes a terminal GND, for example. The terminal GND is electrically connected to a ground line (VSS).

The wirings 847 to 853 and 854a to 854c each have a dual damascene structure with a wiring portion being an upper portion and a via portion being a lower portion formed integrally. The via portion is in contact with the local wiring. The wirings 847 to 853 and 854a to 854c are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In this embodiment, as illustrated in FIG. 29, in the resistance element 100A, the gate electrodes 112 in the VNW structures 110 have an electrical resistance and the semiconductor nanowires 107 in the VNW structures 110 have another electrical resistance between the impurity region 103 and the local wirings 844 and 845. At this time, the VNW structures 110, which are a part of the resistance element 100A, and the impurity region 103, which is a part of the resistance element 100A, are arranged in an overlapping manner in a plane view, thus enabling suppression of an increase in circuit area. In the capacity element 100B, the semiconductor nanowires 107 and the gate electrodes 112 in the VNW structures 110 are capacitively coupled via the gate insulating film 111. As illustrated in FIG. 30, the CR timer circuit in which the resistance element 100A (indicated as R in the drawing) and the capacity element 100B (indicated as C in the drawing) are connected is fabricated.

In this embodiment, the resistance element 100A and the capacity element 100B can be fabricated efficiently using a plurality of the VNW structures 110 having the same configuration. Further, the VNW structures 110 having the same configuration are arranged, thereby making it possible to ensure manufacturing uniformity.

### Ninth Embodiment

In this embodiment, there is disclosed a semiconductor device with VNW structures provided in a resistance element similarly to the second embodiment. The semiconductor device according to this embodiment uses an electrical resistance and an electric capacity in VNW structures and an electrical resistance in a well.

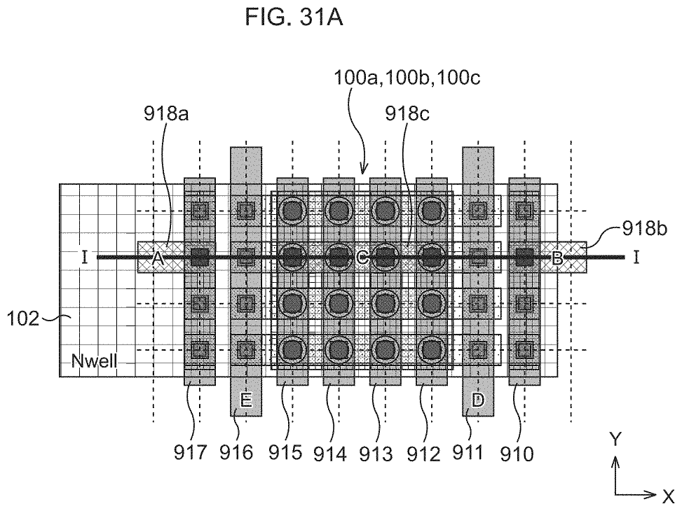

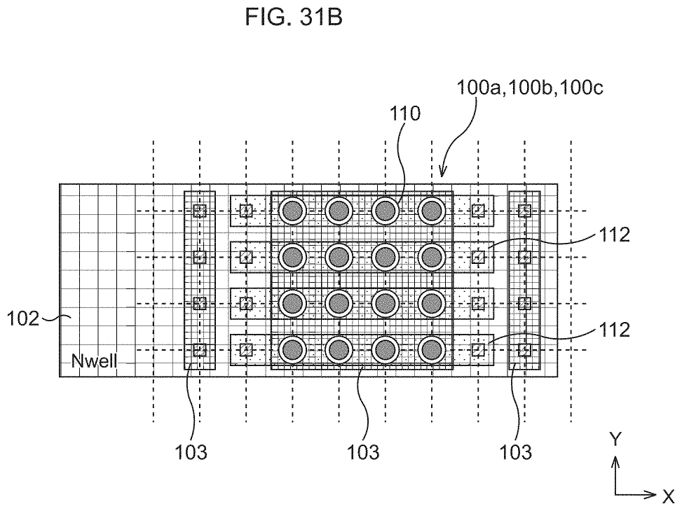

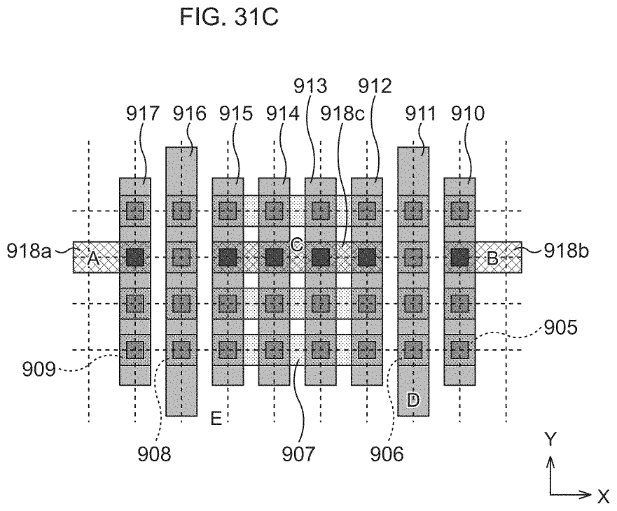

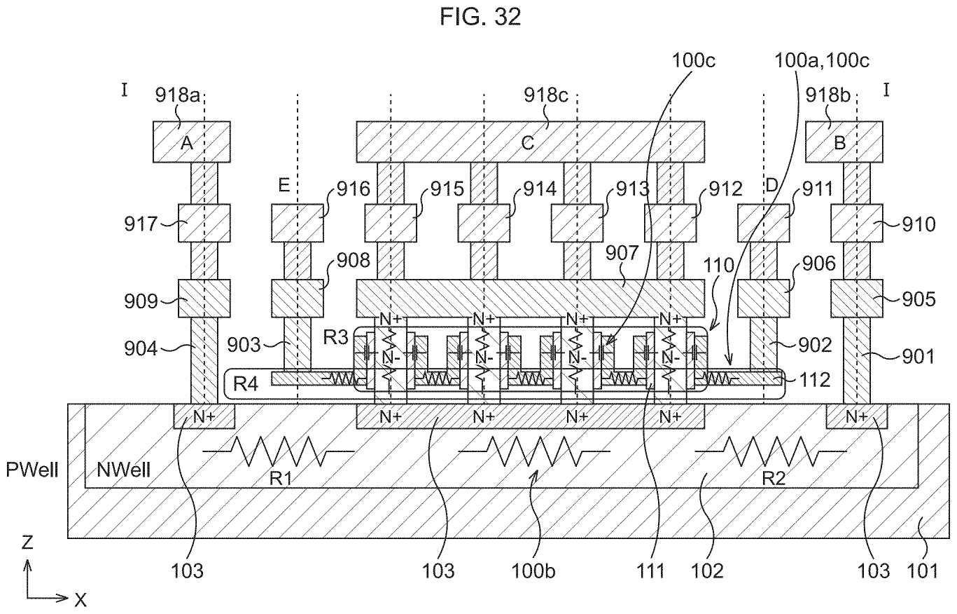

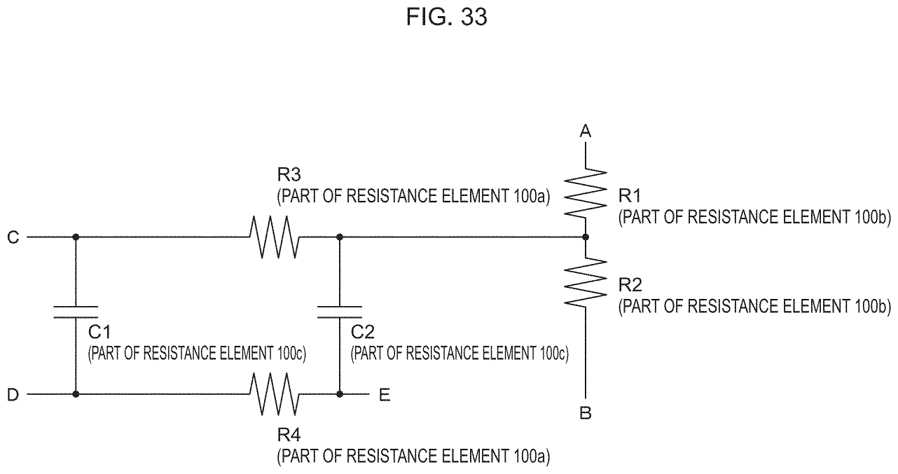

FIG. 31A is a plan view illustrating a schematic configuration of a semiconductor device according to a ninth embodiment. FIG. 31B is a plan view illustrating a schematic configuration of FIG. 31A excluding a configuration above VNW structures. FIG. 31C is a plan view illustrating a schematic configuration of local wirings and wirings thereon in a partial region in FIG. 31A. FIG. 32 is a simple cross-sectional view illustrating a cross section taken along I-I in FIG. 31A. FIG. 33 is an equivalent circuit diagram of the semiconductor device according to the ninth embodiment. Incidentally, the same reference numerals and symbols are added to the same component members as those in the semiconductor device according to the second embodiment, and their detailed explanations are omitted.

In this semiconductor device, similarly to the second embodiment, a resistance element 100a including the VNW structures 110 grouped and arranged in a matrix in a plane view, for example, is provided. In this example, a resistance element 100b using the well 102 is provided so as to overlap the resistance element 100a in a plane view. Further, in the VNW structures 110, a capacity element 100c is provided. The VNW structure 110 includes the semiconductor nanowire 107 standing vertically from the surface of, for example, the N-type impurity region 103 formed in the substrate 101 and the gate electrode 112 via the gate insulating film 111 on the side surface of the semiconductor nanowire 107. In this embodiment, the lower end portion 107a, the upper end portion 107b, and the middle portion 107c of the semiconductor nanowire 107 all have the same conductivity type, for example, an N type. Incidentally, the impurity region 103, the lower end portion 107a, the upper end portion 107b, and the middle portion 107c all may have a P type. The middle portion 107c may have an impurity concentration lower than the lower end portion 107a and the upper end portion 107b.

In the resistance element 100a, the gate electrodes 112 each are formed in a shape extending in the X direction in common with a plurality of the semiconductor nanowires 107, which are six here, aligned in the X direction. In a surface portion of the N-type well 102, a plurality of the N-type impurity regions 103 are formed. The impurity concentration of the impurity region 103 is higher than that of the well 102. The resistance element 100b is formed in the N-type well 102. The well 102 and the impurity region 103 both may have a P type. The capacity element 100c is formed in a manner that the semiconductor nanowires 107 and the gate electrodes 112 are capacitively coupled with the gate insulating film 111 interposed therebetween.

On the impurity region 103 at one end of the resistance element 100b, a connection plug 901 is electrically connected side by side with the VNW structures 110 in the resistance element 100a. On the impurity region 103 at the other end of the resistance element 100b, a connection plug 904 is electrically connected side by side with the VNW structures 110 in the resistance element 100a.

On one end of the gate electrode 112 in the VNW structure 110 in the resistance element 100a, a connection plug 902 is electrically connected. On the other end of this gate electrode 112, a connection plug 903 is electrically connected.

Above the semiconductor substrate 101, local wirings 905 to 909 are provided. The local wiring 905 is electrically connected to the connection plug 901. The local wiring 906 extends in the X direction adjacently to the local wiring 905 in the X direction, and is electrically connected to the four semiconductor nanowires 107 aligned in the X direction. The local wiring 908 is adjacent to the local wiring 907 in the X direction, and is electrically connected to the connection plug 903. The local wiring 909 is adjacent to the local wiring 908 in the X direction, and is electrically connected to the connection plug 904.

Above the respective local wirings, for example, M1-layer wirings 910 to 917 are provided. The wiring 910 extends in the Y direction and is electrically connected to the four local wirings 905. The wiring 911 extends in the Y direction side by side with the wiring 910 and is electrically connected to the four local wirings 906. The wiring 912 extends in the Y direction side by side with the wiring 911 and is electrically connected to the four local wirings 907. The wiring 913 extends in the Y direction side by side with the wiring 912 and is electrically connected to the four local wirings 907. The wiring 914 extends in the Y direction side by side with the wiring 913 and is electrically connected to the four local wirings 907. The wiring 915 extends in the Y direction side by side with the wiring 914 and is electrically connected to the four local wirings 907. The wiring 916 extends in the Y direction side by side with the wiring 915 and is electrically connected to the four local wirings 908. The wiring 917 extends in the Y direction side by side with the wiring 916 and is electrically connected to the four local wirings 909.

Above the respective M1-layer wirings, for example, M2-layer wirings 918a, 918b, and 918c are arranged. The wiring 918a extends in the X direction and is electrically connected to the wiring 917. The wiring 918b extends in the X direction and is electrically connected to the wiring 910. The wiring 918c extends in the X direction between the wiring 918a and the wiring 918b and is electrically connected to the wirings 912 to 915.

The wirings 910 to 917 and 918a to 918c each have a dual damascene structure with a wiring portion being an upper portion and a via portion being a lower portion formed integrally. The via portion is in contact with the local wiring. The wirings 910 to 917 and 918a to 918c are formed in a manner that wiring grooves and via holes are filled with a conductive material by a plating method. As the conductive material, Cu, a Cu alloy, Co, Ru, or the like is used. Incidentally, the wiring portion and the via portion may be formed separately to have a single damascene structure. In this case, the wiring portion and the via portion may be formed of materials different from each other.

In this embodiment, as illustrated in FIG. 33, between a terminal of the wiring 918a (indicated as A in the drawing) and a terminal of the wiring 918b (indicated as B in the drawing), electrical resistances R1, R2 of the resistance element 100b are formed. Between the electrical resistance R1 and the electrical resistance R2, electrical resistances R3, R4 and electric capacities C1, C2 are connected. The electrical resistances R3, R4 are connected in parallel, between one end of the electrical resistance R3 and one end of the electrical resistance R4, the electric capacity C1 is connected, and between the other end of the electrical resistance R3 and the other end of the electrical resistance R4, the electric capacity C2 is connected. a terminal of the wiring 918c corresponds to C in FIG. 33, a terminal of the wiring 912 corresponds to D in FIG. 33, and a terminal of the wiring 916 corresponds to E in FIG. 33. The terminals D and E can be connected as appropriate for the application. The electrical resistance R1 is a part of the resistance element 100b, and is formed between the impurity region 103 to which the lower ends of the semiconductor nanowires 107 in the VNW structures 110 are connected and the impurity region 103 to which a lower end of the connection plug 904 is connected. The electrical resistance R2 is a part of the resistance element 100b, and is formed between the impurity region 103 to which the lower ends of the semiconductor nanowires 107 in the VNW structures 110 are connected and the impurity region 103 to which a lower end of the connection plug 901 is connected. The electrical resistance R3 is a part of the resistance element 100a, and is formed in the semiconductor nanowires 107 connected between the impurity region 103 and the local wiring 907. The electrical resistance R4 is a part of the resistance element 100a, and is formed in the gate electrodes 112 of the VNW structures 110.

In this embodiment, the resistance element 100a and the capacity element 100c using a plurality of the VNW structures 110 having the same configuration and the resistance element 100b using the well 102 and the impurity region 113 having the same conductivity type are formed in a region where they overlap in a plane view. Therefore, the occupied area of the resistance elements 100a, 100b and the capacity element 100c can be kept small. Further, the VNW structures 110 having the same configuration are arranged, thereby making it possible to ensure manufacturing uniformity.

It should be noted that the first to ninth embodiments and the various modified examples thereof merely illustrate concrete examples of implementing the present invention, and the technical scope of the present invention is not to be construed in a restrictive manner by these embodiments. That is, the present invention may be implemented in various forms without departing from the technical spirit or main features thereof.

According to the above-described aspects, there are achieved a concrete structure and arrangement of a resistance element in a semiconductor device including a functional element provided with a projection of a semiconductor material and a manufacturing method of this semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device, comprising:
a semiconductor substrate;
a first projection that has a semiconductor material and is provided to project from the semiconductor substrate;
a first insulating film that is provided on a side surface of the first projection;
a first conductive pattern that is provided on the first insulating film; and
a resistance element that is provided above the semiconductor substrate and comprises a second conductive pattern having the same material as that of the first conductive pattern.

2. The semiconductor device according to claim 1, wherein
the second conductive pattern is arranged in a zigzag shape in a plane view.

3. The semiconductor device according to claim 1, further comprising:
a functional element that is provided above the semiconductor substrate, wherein
the functional element comprises the first projection, the first insulating film, and the first conductive pattern.

4. The semiconductor device according to claim 1, wherein
the first conductive pattern and the second conductive pattern are formed integrally, and
the resistance element comprises the first conductive pattern.

5. The semiconductor device according to claim 1, wherein
the resistance element comprises a first resistance portion and a second resistance portion,
at least the second conductive pattern is the first resistance portion, and
the first projection is the second resistance portion.

6. The semiconductor device according to claim 1, wherein
a second insulating film is provided between the semiconductor substrate and the second conductive pattern, and
a first capacity is formed between the semiconductor substrate under the second conductive pattern and the second conductive pattern.

7. The semiconductor device according to claim 1, wherein
a second capacity is formed between the first projection and the first conductive pattern of the resistance element.

8. The semiconductor device according to claim 3, further comprising:
a second projection that has a semiconductor material and is provided to project from the semiconductor substrate, wherein
the resistance element comprises the second projection, and
a part of the second conductive pattern is provided on a side surface of the second projection.

9. The semiconductor device according to claim 8, wherein
the first projection and the second projection are the same in the arrangement number and arrangement in a plane view.

10. The semiconductor device according to claim 3, wherein
the functional element comprises a first transistor, and
the first transistor is electrically connected to the resistance element.

11. The semiconductor device according to claim 3, further comprising:
a third projection that has a semiconductor material and is provided to project from the semiconductor substrate;
a third insulating film that is provided on a side surface of the third projection; and
a third conductive pattern that is provided on the third insulating film, wherein
the functional element comprises a first transistor and a second transistor,
the first transistor comprises the first projection, the first insulating film, and the first conductive pattern,
the second transistor comprises the third projection, the third insulating film, and the third conductive pattern, and
the resistance element is electrically connected to the first conductive pattern and the third conductive pattern.

12. The semiconductor device according to claim 3, further comprising:
a third projection that has a semiconductor material and is provided to project from the semiconductor substrate;
a third insulating film that is provided on a side surface of the third projection;
a third conductive pattern that is provided on the third insulating film; and
a fourth conductive pattern that is provided on the semiconductor substrate, wherein
the functional element comprises a first transistor and a second transistor,
the first transistor comprises the first projection, the first insulating film, and the first conductive pattern,
the second transistor comprises the third projection, the third insulating film, and the third conductive pattern,
the resistance element comprises a first resistance portion, the first resistance portion comprising the second conductive pattern, and a second resistance portion, the second resistance portion comprising the fourth conductive pattern, and
the first resistance portion is electrically connected to the first conductive pattern, and the second resistance portion is electrically connected to the third conductive pattern.

13. The semiconductor device according to claim 8, further comprising:
a third projection that has a semiconductor material and is provided to project from the semiconductor substrate;
a third insulating film that is provided on a side surface of the third projection;
a third conductive pattern that is provided on the third insulating film; and
a fourth conductive pattern that is provided on the semiconductor substrate, wherein
the functional element comprises a first transistor, a second transistor, and a third transistor,
the first transistor comprises the first projection, the first insulating film, and the first conductive pattern,
the second transistor comprises the third projection, the third insulating film, and the third conductive pattern,
the resistance element comprises a first resistance portion, the first resistance portion comprising the second conductive pattern, a second resistance portion, the second resistance portion comprising the fourth conductive pattern, and a third resistance portion, the third resistance portion comprising the second projection,
the first resistance portion is electrically connected to the first conductive pattern,
the second resistance portion is electrically connected to the third conductive pattern, and
the third resistance portion is connected between the first transistor and the second transistor and the third transistor.

14. The semiconductor device according to claim 1, further comprising:
a second projection that has a semiconductor material and is provided to project from the semiconductor substrate, wherein
the resistance element comprises the second projection as a resistance portion,
a part of the second conductive pattern is provided on a side surface of the second projection, the semiconductor device further comprising:
a capacity element with a capacity formed between the first projection and the first conductive pattern, wherein
one end of the capacity element and the resistance element are electrically connected.

15. The semiconductor device according to claim 1, further comprising:
a second projection that has a semiconductor material and is provided to project from the semiconductor substrate, wherein
the resistance element comprises the second projection and the second conductive pattern as a resistance portion,
a part of the second conductive pattern is provided on a side surface of the second projection, the semiconductor device further comprising:
a capacity element with a capacity formed between the first projection and the first conductive pattern, wherein
the resistance element comprises the second conductive pattern and the second projection that are each set as a resistance portion, and
one end of the capacity element and the resistance element are electrically connected.

16. The semiconductor device according to claim 1, wherein
the resistance element comprises a projection and the gate electrode film provided on a side surface of the projection,
the semiconductor substrate comprises a first well, a second well, and a third well containing the first well and the second well,
the projection is connected to the second well,
the third well comprises a first resistance portion between the first well and the second well,
the gate electrode film comprises a second resistance portion,
the projection comprises a third resistance portion, and
between the semiconductor substrate and the conductive pattern, a capacitive insulating film is provided to form a capacity.

17. A manufacturing method of a semiconductor device, comprising:
forming, on a semiconductor substrate, a first projection that has a semiconductor material and projects from the semiconductor substrate;
forming, on a side surface of the first projection and the semiconductor substrate, an insulating film and a conductor film on the insulating film; and
patterning the insulating film and the conductor film to form a gate insulating film and a gate electrode on the side surface of the first projection, and forming a conductive pattern of a resistance element above the semiconductor substrate.

18. The manufacturing method of the semiconductor device according to claim 17, wherein
the forming the first projection comprises forming a second projection that has a semiconductor material and projects from the semiconductor substrate,
the resistance element comprises the second projection, and
the conductive pattern covers a side surface of the second projection via the insulating film.
